(19) United States
(12) Patent Application Publication
(10) Pub. No.: US 2014/0306869 A1
(43) Pub. Date: Oct. 16, 2014

(54) TRANSITION METAL COMPLEX HAVING ALKOXY GROUP, ORGANIC LIGHT-EMITTING DEVICE USING SAME, COLOR CONVERSION LIGHT-EMITTING DEVICE USING SAME, LIGHT CONVERSION LIGHT-EMITTING DEVICE USING SAME, ORGANIC LASER DIODE LIGHT-EMITTING DEVICE USING SAME, DYE LASER USING SAME, DISPLAY SYSTEM USING SAME, LIGHTING SYSTEM USING SAME, AND ELECTRONIC EQUIPMENT USING SAME

(71) Applicants: Yoshimasa Fujita, Osaka-shi (JP); Masahito Ohe, Osaka-shi (JP); Makoto Yamada, Osaka-shi (JP); Tetsuji Itoh, Osaka-shi (JP); Ayataka Endo, Osaka-shi (JP)

(72) Inventors: Yoshimasa Fujita, Osaka-shi (JP); Masahito Ohe, Osaka-shi (JP); Makoto Yamada, Osaka-shi (JP); Tetsuji Itoh, Osaka-shi (JP); Ayataka Endo, Osaka-shi (JP)

(73) Assignee: Sharp Kabushiki Kaisha, Osaka-shi, Osaka (JP)

(21) Appl. No.: 14/345,936

(22) PCT Filed: Sep. 14, 2012
(86) PCT No.: PCT/JP2012/073607

§ 371 Date: May 6, 2014

(30) Foreign Application Priority Data
Sep. 21, 2011 (JP) 2011-206097

(51) Int. Cl. H01L 51/00; H01S 1/04; G09G 3/32; H01L 51/52

(52) U.S. Cl. CPC H01L 51/0085; H01L 51/52; H01S 1/04; G09G 3/3208
USPC 345/77; 546/4; 257/40; 372/53

(57) ABSTRACT

The transition metal complex is represented by Formula (1) [where M represents a transition metal element; K and L each represent a monodentate or bidentate ligand; m and o each represent an integer from 0 to 5; n represents an integer from 1 to 3; X, Y, R1, R2, and R4 each represent a hydrogen atom, alkyl, cycloalkyl, heterocycloalkyl, aryl, heteroaryl, aralkyl, alkenyl, alkynyl, or alkoxy; R3 represents a hydrogen atom, alkyl, cycloalkyl, heterocycloalkyl, aryl, aralkyl, heteroaryl, alkenyl, alkynyl, aryloxy, or alkoxy having two or more carbon atoms; and A represents alkyl, cycloalkyl, heterocycloalkyl, aryl, heteroaryl, aralkyl, alkenyl, alkynyl, or alkoxy].

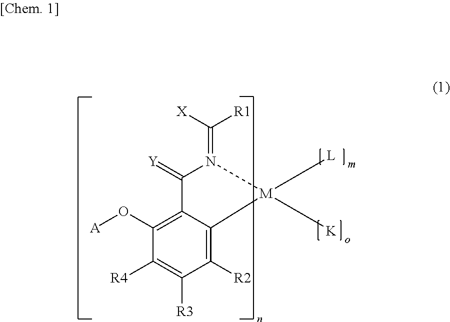

### TECHNICAL FIELD

The present invention relates to a transition metal complex having an alkoxy group, an organic light-emitting device using the same, a color conversion light-emitting device using the same, a light conversion light-emitting device using the same, an organic laser diode light-emitting device using the same, a dye laser using the same, a display system using the same, a lighting system using the same, and electronic equipment using the same.

This application claims the priority based on Japanese Patent Application No. 2011-206097 filed in the Japanese Patent Office on Sep. 21, 2011, and the entire content of which is hereby incorporated by reference.

### BACKGROUND ART

In order to reduce power consumption in organic EL (electroluminescence) devices, development of highly-efficient luminescent materials has been promoted. As compared with a fluorescent material in which only the fluorescence emission in the singlet excited state is utilized, a phosphorescent material in which light emission in the triplet excited state is utilized is expected to achieve higher luminous efficiency; hence, such a phosphorescent material has been developed (for example, see Patent Literature 1 and Non Patent Literature 1).

### CITATION LIST

### Patent Literature

PTL 1: Japanese Unexamined Patent Application Publication (Translation of PCT application) No. 2005-518081 Non Patent Literature
NPL 1: M. A. Baldo, et. al., Appl. Phys. Lett. 75, p. 4, 1999

### SUMMARY OF INVENTION

### Technical Problem

The internal quantum yield of a phosphorescent material is theoretically 100%, and the phosphorescent material is therefore four times more efficient than a fluorescent material of which the internal quantum yield is 25%. A phosphorescent material which enables both high color purity and high efficiency has been, however, still under study; hence, development of a novel phosphorescent material has been demanded.

In view of such a circumstance in the related art, aspects of the present invention provide a transition metal complex which can be applied to a luminescent material or another material, an organic light-emitting device using the same, a color conversion light-emitting device using the same, a light conversion light-emitting device using the same, an organic laser diode light-emitting device using the same, a dye laser using the same, a display system using the same, a lighting system using the same, and electronic equipment using the same.

### Solution to Problem

Some aspects of the present invention are as follows.

An aspect of the present invention provides a transition metal complex having an alkoxy group, the transition metal complex being represented by Formula (1):

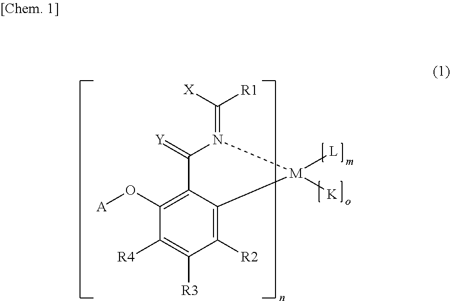

(where M represents a transition metal element belonging to Groups 8 to 12 on the periodic table, and the oxidation state of the transition metal element represented by M is not limited; K represents an uncharged monodentate or bidentate ligand; L represents a monoanionic or dianionic monodentate or bidentate ligand; m represents an integer from 0 to 5; o represents an integer from 0 to 5; n represents an integer from 1 to 3; m, o, and n depend on the oxidation state and coordination number of the transition metal element represented by M; X and Y each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these groups are optionally substituted or unsubstituted; X and Y are each independently optionally combined to each other by connection of parts thereof to form a saturated or unsaturated ring structure having at least one atom between carbon atoms, at least one atom of the ring structure is optionally substituted with an alkyl group or an aryl group (the substituent is optionally further substituted or unsubstituted), and the ring structure optionally has one or more ring structures; R1, R2, and R4 each independently represent a hydrogen atom, an alkyl group, a cycloalkyl group, a heterocycloalkyl group, an aryl group, an aralkyl group, a heteroaryl group, an alkenyl group, an alkynyl group, or an alkoxy group, and these groups are optionally substituted or unsubstituted; R3 represents a hydrogen atom, an alkyl group, a cycloalkyl group, a heterocycloalkyl group, an aryl group, an aralkyl group, a heteroaryl group, an alkenyl group, an alkynyl group, an aryloxy group, or an alkoxy group having two or more carbon atoms, and these groups are optionally substituted or unsubstituted; and A represents an alkyl group, a cycloalkyl group, a heterocycloalkyl group, an aryl group, a heteroaryl group, an aralkyl group, an alkenyl group, an alkynyl group, or an alkoxy group).

The transition metal complex having an alkoxy group according to an aspect of the present invention may be also represented by Formula (2):

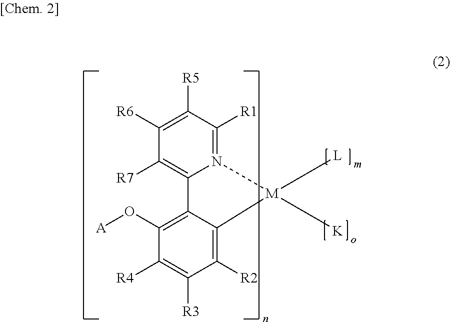

(where R5 to R7 each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these groups are optionally substituted or unsubstituted; R1, R5, R6, R2, and R3 are optionally independently combined with R5, R6, R7, R3, and R4 by connection of parts thereof, respectively, to form saturated or unsaturated ring structures, at least one atom of each ring structure is optionally substituted with an alkyl group or an aryl group (the substituent is optionally further substituted or unsubstituted), and each ring structure optionally has one or more rings; and R1 to R4, A, M, m, n, o, L, and K represent the same as R4, A, M, m, n, o, L, and K in Formula (1), respectively.

In the transition metal complex having an alkoxy group according to an aspect of the present invention, L represents a ligand having a structure represented by any of Formulae (3) to (7).

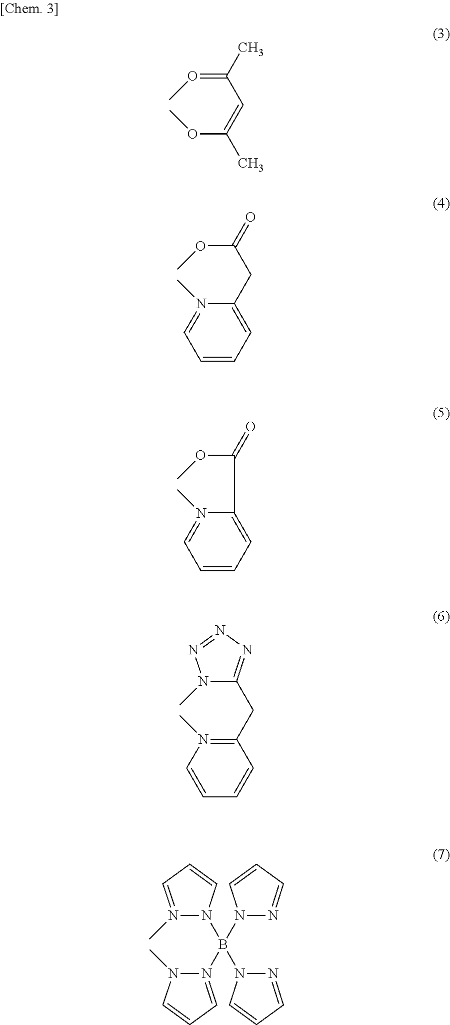

The transition metal complex having an alkoxy group according to an aspect of the present invention may be represented by Formula (8):

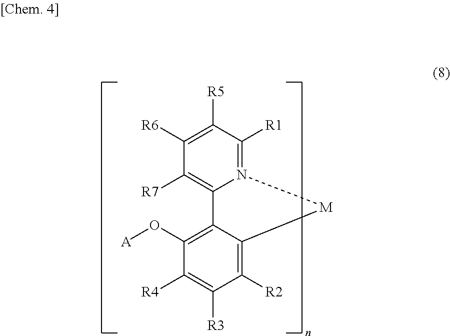

(where R5 to R7 each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these groups are optionally substituted or unsubstituted; R1, R5, R6, R2, and R3 are optionally independently combined with R5, R6, R7, R3, and R4 by connection of parts thereof, respectively, to form saturated or unsaturated ring structures, at least one atom of each ring structure is optionally substituted with an alkyl group or an aryl group (the substituent is optionally further substituted or unsubstituted), and each ring structure optionally has one or more rings; and R1 to R4, A, M, and n represent the same as R1 to R4, A, M, and n in Formula (1), respectively.

In the transition metal complex having an alkoxy group according to an aspect of the present invention, R1 to R7 may be each independently a hydrogen atom, a methyl group, or a phenyl group.

In the transition metal complex having an alkoxy group according to an aspect of the present invention, A may be a methyl group, an ethyl group, an isopropyl group, a phenyl group, or an n-octyl group.

In the transition metal complex having an alkoxy group according to an aspect of the present invention, M may be iridium, osmium, or platinum.

In the transition metal complex having an alkoxy group according to an aspect of the present invention, the transition metal complex may be a tris-complex in which three bidentate ligands are coordinated where n represents 3 and where m and o represent 0, and the fac (facial) isomer content may be higher than the mer (meridional) isomer content.

Another aspect of the present invention provides an organic light-emitting device including an organic layer having a mono- or multilayer structure including a light-emitting layer and a pair of electrodes placed such that the organic layer is disposed between the electrodes, wherein at least part of the organic layer contains the above-mentioned transition metal complex having an alkoxy group.

In the organic light-emitting device according to another aspect of the present invention, the transition metal complex having an alkoxy group may be used as a luminescent material.

In the organic light-emitting device according to another aspect of the present invention, the transition metal complex having an alkoxy group may be used as a host material.

In the organic light-emitting device according to another aspect of the present invention, the transition metal complex having an alkoxy group may be used as an exciton-blocking material.

Another aspect of the present invention provides a color conversion light-emitting device including the above-mentioned organic light-emitting device and a fluorescent layer disposed so as to face the light-extracted side of the organic light-emitting device, the fluorescent layer absorbing light emitted from the organic light-emitting device to emit light having a color different from the color of the absorbed light.

Another aspect of the present invention provides a color conversion light-emitting device including a light-emitting device and a fluorescent layer disposed so as to face the light-extracted side of the light-emitting device, the fluorescent layer absorbing light emitted from the light-emitting device to emit light having a color different from the color of the absorbed light, wherein the fluorescent layer contains the above-mentioned transition metal complex having an alkoxy group.

Another aspect of the present invention provides a light conversion light-emitting device including an organic layer having a mono- or multilayer structure including a light-emitting layer, a layer that amplifies electric current, and a pair of electrodes placed such that the organic layer and the layer that amplifies electric current are disposed between the electrodes, wherein the light-emitting layer contains the above-mentioned transition metal complex having an alkoxy group.

Another aspect of the present invention provides an organic laser diode light-emitting device including a continuous wave excitation light source and a resonator structure to which light is emitted from the continuous wave excitation light source, wherein the resonator structure includes an organic layer having a mono- or multilayer structure including a laser active layer and a pair of electrodes placed such that the organic layer is disposed between the electrodes, and the laser active layer contains a host material doped with the above-mentioned transition metal complex having an alkoxy group.

Another aspect of the present invention provides a dye laser including a laser medium containing the above-mentioned transition metal complex and an excitation light source that causes stimulated emission of phosphorescence from the organic light-emitting device material contained in the laser medium for laser oscillation.

Another aspect of the present invention provides a display system including an image signal output unit that generates an image signal, a driver that generates electric current or voltage on the basis of the signal generated in the image signal output unit, and a light-emitting unit that emits light on the basis of the electric current or voltage generated in the driver, wherein the light-emitting unit is the above-mentioned organic light-emitting device.

Another aspect of the present invention provides a display system including an image signal output unit that generates an image signal, a driver that generates electric current or voltage on the basis of the signal generated in the image signal output unit, and a light-emitting unit that emits light on the basis of the electric current or voltage generated in the driver, wherein the light-emitting unit is the above-mentioned color conversion light-emitting device.

In the display system according to another aspect of the present invention, an anode and cathode of the light-emitting unit may be arrayed in the form of a matrix.

In the display system according to another aspect of the present invention, the light-emitting unit may be driven by a thin film transistor.

Another aspect of the present invention provides a lighting system including a driver that generates electric current or voltage and a light-emitting unit that emits light on the basis of the electric current or voltage generated in the driver, wherein the light-emitting unit is the above-mentioned organic light-emitting device.

Another aspect of the present invention provides a lighting system including a driver that generates electric current or voltage and a light-emitting unit that emits light on the basis of the electric current or voltage generated in the driver, wherein the light-emitting unit is the above-mentioned color conversion light-emitting device.

Another aspect of the present invention provides electronic equipment including a display that is the above-mentioned display system.

### Advantageous Effects of Invention

Some aspects of the present invention can provide a transition metal complex which can be applied to a luminescent material or another material, an organic light-emitting device using the same, a color conversion light-emitting device using the same, a light conversion light-emitting device using the same, an organic laser diode light-emitting device using the same, a dye laser using the same, a display system using the same, a lighting system using the same, and electronic equipment using the same.

### BRIEF DESCRIPTION OF DRAWINGS

FIG. 1 is a schematic diagram illustrating a first embodiment of the organic light-emitting device of the present invention.

FIG. 2 is a schematic cross-sectional view illustrating a second embodiment of the organic light-emitting device of the present invention.

FIG. 3 is a schematic cross-sectional view illustrating an embodiment of the color conversion light-emitting device of the present invention.

FIG. 4 is a top view illustrating the color conversion light-emitting device illustrated in FIG. 3.

FIG. 5 is a schematic diagram illustrating an embodiment of the light conversion light-emitting device of the present invention.

FIG. 6 is a schematic diagram illustrating an embodiment of the organic laser diode light-emitting device of the present invention.

FIG. 7 is a schematic diagram illustrating an embodiment of the dye laser of the present invention.

FIG. 8 is a block diagram illustrating an example of connection of a wiring structure to a driving circuit in a display system according to the present invention.

FIG. 9 is a pixel circuit diagram illustrating the circuit of a pixel disposed in a display system in which the organic light-emitting device of the present invention is used.

FIG. 10 is a schematic perspective view illustrating a first embodiment of the lighting system of the present invention.

FIG. 11 is a schematic perspective view illustrating another embodiment of the lighting system of the present invention.

FIG. 12 is a schematic perspective view illustrating another embodiment of the lighting system of the present invention.

FIG. 13 is a schematic perspective view illustrating an embodiment of the electronic equipment of the present invention.

FIG. 14 is a schematic perspective view illustrating an embodiment of the electronic equipment of the present invention.

FIG. 15 is a schematic perspective view illustrating an embodiment of the electronic equipment of the present invention.

FIG. 16 is a schematic perspective view illustrating an embodiment of the electronic equipment of the present invention.

FIG. 17 is a ¹H-NMR chart of a ligand 1 synthesized in Examples.

FIG. 18 is a ¹H-NMR chart of a ligand 2 synthesized in Examples.

FIG. 19 is a ¹H-NMR chart of a ligand 3 synthesized in Examples.

FIG. 20 is a PL spectrum of a compound 6 synthesized in Examples.

FIG. 21 is a PL spectrum of a compound 7 synthesized in Examples.

FIG. 22 is a PL spectrum of a compound 8 synthesized in Examples.

FIG. 23 is a PL spectrum of a compound 11 synthesized in Examples.

FIG. 24 is a PL spectrum of a compound 12 synthesized in Examples.

### DESCRIPTION OF EMBODIMENTS

Embodiments of a transition metal complex having an alkoxy group, organic light-emitting device using the same, color conversion light-emitting device using the same, light conversion light-emitting device using the same, organic laser diode light-emitting device using the same, dye laser using the same, display system using the same, lighting system using the same, and electronic equipment using the same according to aspects of the present invention will now be described. The following embodiments will be specifically described for better understanding of the gist of aspects of the invention, and the aspects of the present invention are not limited thereto unless otherwise specified. In the drawings to which will be referred in the following description, some parts are properly enlarged to simply illustrate the characteristics of aspects of the present invention, and the dimensional relationship between components does not always reflect the actual dimensional relationship.

<Transition Metal Complex Having Alkoxy Group>

The transition metal complex of the present disclosure is suitably employed as a luminescent material used in organic EL (electroluminescence) devices, a host material, a charge transport material, and an exciton-blocking material and is particularly suitable for use as a luminescent material, a host material, and an exciton-blocking material.

The transition metal complex having an alkoxy group according to the present disclosure (also hereinafter referred to as “transition metal complex of the present disclosure”) is represented by Formula (1):

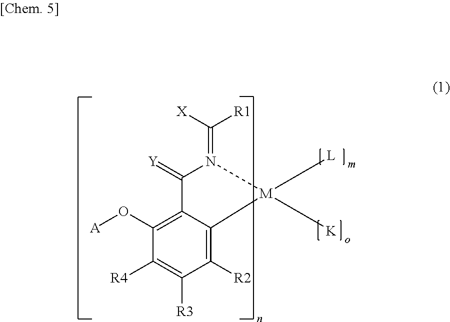

(where M represents a transition metal element belonging to Groups 8 to 12 on the periodic table, and the oxidation state of the transition metal element represented by M is not limited; K represents an uncharged monodentate or bidentate ligand; L represents a monoanionic or dianionic monodentate or bidentate ligand; m represents an integer from 0 to 5; o represents an integer from 0 to 5; n represents an integer from 1 to 3; m, o, and n depend on the oxidation state and coordination number of a transition metal element represented by M; X and Y each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these groups are optionally substituted or unsubstituted; X and Y are each independently optionally combined to each other by connection of parts thereof to form a saturated or unsaturated ring structure having at least one atom between carbon atoms, at least one atom of the ring structure is optionally substituted with an alkyl group or an aryl group (such a substituent is optionally further substituted or unsubstituted), and the ring structure optionally has one or more ring structures; R1, R2, and R4 each independently represent a hydrogen atom, an alkyl group, a cycloalkyl group, a heterocycloalkyl group, an aryl group, an aralkyl group, a heteroaryl group, an alkenyl group, an alkynyl group, or an alkoxy group, and these groups are optionally substituted or unsubstituted; R3 represents a hydrogen atom, an alkyl group, a cycloalkyl group, a heterocycloalkyl group, an aryl group, an aralkyl group, a heteroaryl group, an alkenyl group, an alkynyl group, an aryloxy group, or an alkoxy group having two or more carbon atoms, and these groups are optionally substituted or unsubstituted; and A represents an alkyl group, a cycloalkyl group, a heterocycloalkyl group, an aryl group, a heteroaryl group, an aralkyl group, an alkenyl group, an alkynyl group, or an alkoxy group).

In Formula (1), M represents a transition metal element belonging to Groups 8 to 12 on the periodic table, and the oxidation state of the transition metal element represented by M is not limited. Specific examples of the transition metal element represented by M include Ir, Pt, Pd, Rh, Re, Ru, Os, Ti, Bi, In, Sn, Sb, Te, Au, and Ag; in particular, Ir, Os, and Pt are preferably employed because these elements enable an enhancement in a PL quantum yield owing to a heavy atom effect which will be described later.

In a transition metal complex which is expected to be a highly-sufficient phosphorescent material, it is believed that the emission mechanism is MLCT (Metal-to-Ligand Charge Transfer). This is because the heavy atom effect of the metal center also efficiently affects a ligand in this case with the result that intersystem crossing (transition from the singlet excited state to the triplet excited state, S to T: approximately 100%) is promptly caused, and then the rate constant (kᵣ) of transition from T₁ to S₀ is enhanced similarly owing to the heavy atom effect. Thus, the PL quantum yield (φ_{PL}=kᵣ/(kₙᵣ+kᵣ); where kₙᵣ is the rate constant of thermal deactivation from T₁ to S₀) is enhanced. Such an enhancement in the PL quantum yield leads to an enhancement in the luminous efficiency of such a transition metal complex in the case where the transition metal complex is used in organic electronic devices.

The atomic radius of each of Ir, Os, and Pt is relatively small owing to lanthanoid contraction; however, the atomic weight thereof is large, which can effectively give the above-mentioned heavy atom effect. Hence, in the case where the transition metal complex of the present disclosure is used as a luminescent material, employing Ir, Os, or Pt as the metal center of the transition metal complex enables the PL quantum yield to be enhanced owing to a heavy atom effect, which leads to an enhancement in luminous efficiency.

In Formula (1), m is an integer from 0 to 5; o is an integer from 0 to 5; n is an integer from 1 to 3; and m, o, and n depend on the oxidation state and coordination number of a transition metal element that is to be used.

K is an uncharged monodentate or bidentate ligand; in particular, K preferably represents one selected from phosphine, phosphonate, derivatives thereof, arsenate, derivatives thereof, phosphite, CO, pyridine, and nitrile.

L is a monoanionic or dianionic monodentate or bidentate ligand. Specific examples of L include a halogen and a pseudohalogen; the halogen is preferably Br⁻ or I⁻, and the pseudohalogen is preferably OAc⁻ (Ac represents COCH₃) or NCS⁻.

Furthermore, L is also preferably a group represented by any of Formulae (L-1) to (L-6) which will be described later.

In Formula (1), R1, R2, and R4 each independently represent a hydrogen atom, an alkyl group, a cycloalkyl group, a heterocycloalkyl group, an aryl group, an aralkyl group, a heteroaryl group, an alkenyl group, an alkynyl group, or an alkoxy group; and these groups are optionally substituted or unsubstituted.

The alkyl group represented by R1, R2, and R4 may be an alkyl group having 1 to 8 carbon atoms; specific examples thereof include a methyl group, an ethyl group, an n-propyl group, an isopropyl group, an n-butyl group, a tert-butyl group, an n-pentyl group, an n-hexyl group, an n-heptyl group, and an n-octyl group.

The cycloalkyl group represented by R1, R2, and R4 may be a cycloaklyl group having 3 to 8 carbon atoms; specific examples thereof include a cyclopropyl group, a cyclobutyl group, a cyclopentyl group, a cyclohexyl group, a cycloheptyl group, and a cyclooctyl group.

The heterocycloalkyl group represented by R1, R2, and R4 may be a group in which at least one carbon atom contained in the cyclic structure of the cycloalkyl group is substituted with, for instance, a nitrogen atom, an oxygen atom, or a sulfur atom. Specific examples thereof include an azepanyl group, a diazepanyl group, an aziridinyl group, an azetidinyl group, a pyrrolidinyl group, an imidazolidinyl group, a piperidyl group, a pyrazolidinyl group, a piperazinyl group, an azocanyl group, a thiomorpholinyl group, a thiazolidinyl group, an isothiazolidinyl group, an oxazolidinyl group, a morpholinyl group, a tetrahydrothiopyranyl group, an oxathiolanyl group, an oxiranyl group, an oxetanyl group, a dioxolanyl group, a tetrahydrofuranyl group, a tetrahydropyranyl group, a 1,4-dioxanyl group, a quinuclidinyl group, a 7-azabicyclo[2.2.1]heptyl group, a 3-azabicyclo[3.2.2]nonanyl group, a trithiadiazaindenyl group, a dioxoloimidazolidinyl group, and a 2,6-dioxabicyclo[3.2.2]octo-7-yl group.

Specific examples of the aryl group represented by R1, R2, and R4 include a phenyl group, a terphenyl group, a naphthyl group, a tolyl group, a fluorophenyl group, a xylyl group, a biphenylyl group, an anthryl group, and a phenanthryl group.

Specific examples of the aralkyl group represented by R1, R2, and R3 include a benzyl group and a phenethyl group.

The heteroaryl group represented by R1, R2 and R4 may be a group in which at least one carbon atom contained in the cyclic structure of the aryl group is substituted with, for instance, a nitrogen atom, an oxygen atom, or a sulfur atom. Specific examples thereof include a pyrrolyl group, a furyl group, a thienyl group, an oxazolyl group, an isoxazolyl group, an imidazolyl group, a thiazolyl group, an isothiazolyl group, a pyrazolyl group, a triazolyl group, a tetrazolyl group, a 1,3,5-oxadiazolyl group, a 1,2,4-oxadiazolyl group, a 1,2,4-thiadiazolyl group, a pyridyl group, a pyranyl group, a pyrazinyl group, a pyrimidinyl group, a pyridazinyl group, a 1,2,4-triazinyl group, a 1,2,3-triazinyl group, and a 1,3,5-triazinyl group.

Specific examples of the alkenyl group represented by R1, R2, and R4 include an ethenyl group, a 1-propenyl group, a 2-propenyl group, a 2-methyl-1-propenyl group, a 2-methyl-2-propenyl group, a 1-butenyl group, a 2-butenyl group, a 3-butenyl group, a 2-methyl-1-butenyl group, a 3-methyl-2-butenyl group, a 1-pentenyl group, a 2-pentenyl group, a 3-pentenyl group, a 4-pentenyl group, a 4-methyl-3-pentenyl group, a 1-hexenyl group, a 2-hexenyl group, a 3-hexenyl group, a 4-hexenyl group, a 5-hexenyl group, a 1-heptenyl group, and a 1-octenyl group.

Specific examples of the alkynyl group represented by R1, R2, and R4 include an ethynyl group, a 1-propynyl group, a 2-propynyl group, a 1-butynyl group, a 2-butynyl group, a 3-butynyl group, a 1-pentynyl group, a 2-pentynyl group, a 3-pentynyl group, a 4-pentynyl group, a 1-hexynyl group, a 2-hexynyl group, a 3-hexynyl group, a 4-hexynyl group, a 5-hexynyl group, a 1-heptynyl group, and a 1-octynyl group.

Specific examples of the alkoxy group represented by R1, R2, and R4 include a methoxy group, an ethoxy group, a propoxy group, a butoxy group, an octyloxy group, and a decyloxy group.

In particular, the moieties represented by R1, R2, and R4 are each preferably a hydrogen atom, an alkyl group, or an aryl group; more preferably a hydrogen atom, a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, or a naphthyl group; further preferably a hydrogen atom, a methyl group, a propyl group, or a phenyl group; and especially preferably a hydrogen atom, a methyl group, or a phenyl group.

In Formula (1), R3 represents a hydrogen atom, an alkyl group, a cycloalkyl group, a heterocycloalkyl group, an aryl group, an aralkyl group, a heteroaryl group, an alkenyl group, an alkynyl group, an aryloxy group, or an alkoxy group having two or more carbon atoms, and these groups are optionally substituted or unsubstituted.

Specific examples of the alkyl group, cycloalkyl group, heterocycloalkyl group, aryl group, aralkyl group, heteroaryl group, alkenyl group, or alkynyl group represented by R3 include the same groups as specified for R1, R2, and R4.

Specific examples of the alkoxy group having two or more carbon atoms, which is represented by R3, include an ethoxy group, a propoxy group, a butoxy group, an octyloxy group, and a decyloxy group.

An example of the aryloxy group represented by R3 is a phenoxy group.

Among these, the moiety represented by R3 is preferably a hydrogen atom, an alkyl group, an aryl group, an aryloxy group, or an alkoxy group having two or more carbon atoms; more preferably a hydrogen atom, a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, a naphthyl group, an ethoxy group, a propoxy group, a butoxy group, an octyloxy group, or a phenoxy group; further preferably a hydrogen atom, a methyl group, a propyl group, or a phenyl group; and especially preferably a hydrogen atom, a methyl group, or a phenyl group.

In Formula (1), X and Y each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these groups are optionally substituted or unsubstituted. X and Y may be combined to each other by connection of parts thereof to form a saturated or unsaturated ring structure having at least two atoms between carbon atoms. At least one atom of such a ring structure is optionally substituted with an alkyl group or an aryl group (these substituents may be further substituted or unsubstituted), and it is preferred that such a ring structure optionally have one or more rings.

Specific examples of the alkyl group, cycloalkyl group, heterocycloalkyl group, aryl group, heteroaryl group, aralkyl group, alkenyl group, alkynyl group, and alkoxy group represented by X and Y include the same groups as specified for R1, R2, and R4.

X and Y are each preferably a hydrogen atom, an alkyl group, an aryl group, or an alkoxy group; and more preferably a hydrogen atom, a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, a naphthyl group, a methoxy group, an ethoxy group, or a propoxy group.

In the case where parts of X and Y are connected to each other to form a ring structure, specific examples of the alkyl group and aryl group which are each a substituent optionally contained in such a ring structure include a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, and a naphtyl group; in particular, a methyl group, a propyl group, and a phenyl group are preferred, and a methyl group and a phenyl group are more preferred.

In Formula (1), A each independently represents an alkyl group, a cycloalkyl group, a heterocycloalkyl group, an aryl group, a heteroaryl group, an aralkyl group, an alkenyl group, an alkynyl group, or an alkoxy group, and these groups may be substituted or unsubstituted.

Specific examples of the alkyl group, cycloalkyl group, heterocycloalkyl group, aryl group, heteroaryl group, aralkyl group, alkenyl group, alkynyl group, and alkoxy group represented by A include the same groups as specified for R1, R2, and R4.

A is preferably an alkyl group, an aryl group, or an alkoxy group; and more preferably a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, or a naphtyl group. Among these, A is especially preferably a bulky group because it can generate a twist between the phenyl group and pyridyl group of the ligands to cleave the n conjugated system with the result that the emission wavelength is shortened (enhancement in color purity) and that high luminous efficiency is enabled; in particular, a group having two or more carbon atoms is preferably employed, such as an ethyl group, an isopropyl group, a phenyl group, or an n-octyl group.

The transition metal complex represented by Formula (1) preferably has a structure represented by Formula (2).

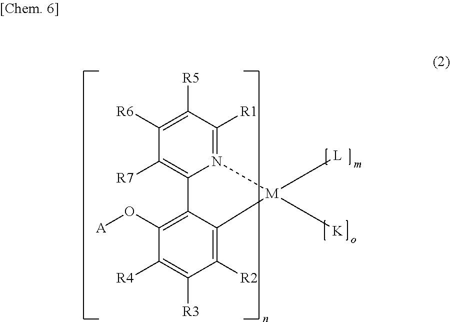

In Formula (2), R5 to R7 each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these groups may be substituted or unsubstituted; R1, R5, R6, R2, and R3 are optionally independently combined with R5, R6, R7, R3, and R4 by connection of parts thereof, respectively, to form saturated or unsaturated ring structures, at least one atom of each ring structure may be substituted with an alkyl group or an aryl group (these substituents may be further substituted or unsubstituted), and each ring structure optionally has one or more ring structures; and R1 to R4, A, M, m, n, o, L, and K represent the same as R1 to R4, A, M, m, n, o, L, and K in Formula (1), respectively.

Specific Examples of the alkyl group, cycloalkyl group, heterocycloalkyl group, aryl group, heteroaryl group, aralkyl group, alkenyl group, alkynyl group, and alkoxy group represented by R5 to R7 include the same groups as specified for R1, R2, and R4 in Formula (1).

The moieties represented by R5 to R7 are each preferably a hydrogen atom, an alkyl group, an aryl group, or an alkoxy group. Specific examples thereof include a hydrogen atom, a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, a naphthyl group, a methoxy group, an ethoxy group, and a propoxy group; in particular, a hydrogen atom, a methyl group, a propyl group, and a phenyl group are preferred, and a hydrogen atom, a methyl group, and a phenyl group are more preferred.

In the case where parts of R1, R5, R6, R2, and R3 are connected to parts of R5, R6, R7, R3, and R4 to form ring structures, respectively, examples of the alkyl group and aryl group which are each a substituent optionally contained in such ring structures include the same substituents as specified for the substituent optionally contained in the ring structure in Formula (1).

In Formula (2), A is preferably an alkyl group, an aryl group, or an alkoxy group; and more preferably a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, or a naphtyl group. Among these, A is especially preferably a bulky group because it can generate a twist between the phenyl group and pyridyl group of the ligands to cleave the n conjugated system with the result that the emission wavelength is shortened (enhancement in color purity) and that high luminous efficiency is enabled; in particular, a group having two or more carbon atoms is preferably employed, such as an ethyl group, an isopropyl group, a phenyl group, or an n-octyl group.

The transition metal complex represented by Formula (1) also preferably has a structure represented by Formula (8).

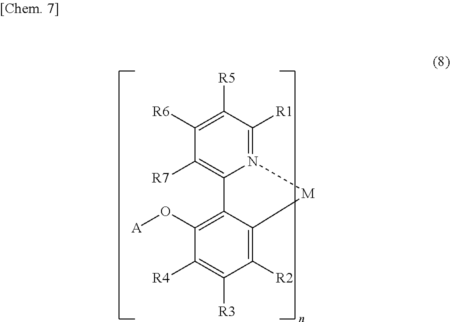

In Formula (8), R1 to R7, M, n, and A represent the same as R1 to R7, M, n, and A in Formulae (1) and (2), respectively.

The moieties represented by R1 to R7 are each preferably a hydrogen atom, an alkyl group, an aryl group, or an alkoxy group. Specific examples thereof include a hydrogen atom, a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, a naphthyl group, a methoxy group, an ethoxy group, and a propoxy group; in particular, a hydrogen atom, a methyl group, a propyl group, and a phenyl group are preferred, and a hydrogen atom, a methyl group, and a phenyl group are more preferred.

In Formula (8), A is preferably an alkyl group, an aryl group, or an alkoxy group; and more preferably a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, or a naphtyl group. Among these, A is especially preferably a bulky group because it can generate a twist between the phenyl group and pyridyl group of the ligands to cleave the n conjugated system with the result that the emission wavelength is shortened (enhancement in color purity) and that high luminous efficiency is enabled; in particular, a group having two or more carbon atoms is preferably employed, such as an ethyl group, an isopropyl group, a phenyl group, or an n-octyl group.

In Formulae (1) and (2), L is preferably Br⁻, I⁻, or a pseudohalogen that is OAc⁻ (Ac represents COCH₃) or NCS⁻ and also preferably a group represented by any of Formulae (L-1) to (L-5).

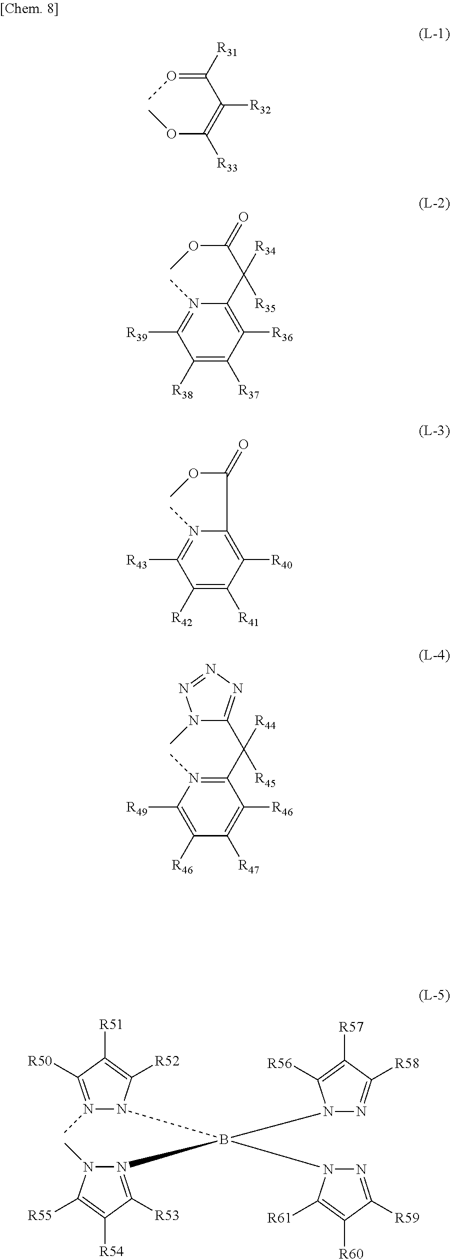

In Formulae (L-1) to (L-5), R31 to R61 each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these substituents may be substituted or unsubstituted; and in R31 to R33, R34 to R39, R40 to R43, R44 to R49, and R50 to R61, adjoining ones may be independently combined to each other by connection of parts thereof to form saturated or unsaturated ring structures. At least one atom of each of the ring structures is optionally substituted with an alkyl group or an aryl group (these substituents may be further substituted or unsubstituted), and such a ring structure optionally have one or more rings.

Specific examples of the alkyl group, cycloalkyl group, heterocycloalkyl group, aryl group, heteroaryl group, aralkyl group, alkenyl group, alkynyl group, and alkoxy group represented by R31 to R61 include the same groups as specified for R1, R2, and R4 in Formula (1).

In particular, the moieties represented by R31 to R61 are each preferably a hydrogen atom, an alkyl group, or an aryl group. Specific examples thereof include a hydrogen atom, a methyl group, an ethyl group, an n-propyl group, an isopropyl group, an n-butyl group, a tert-butyl group, an n-pentyl group, an n-hexyl group, an n-heptyl group, an n-octyl group, a cyclohexyl group, a phenyl group, and a naphthyl group; in particular, a hydrogen atom, a methyl group, a propyl group, and a phenyl group are preferred, and a hydrogen atom, a methyl group, and a phenyl group are more preferred.

In the case where parts of arbitrary adjoining ones of R31 to R61 are connected to each other to form ring structures, examples of the alkyl group and aryl group which are each a substituent optionally contained in such ring structures include the same substituents as specified for the substituent which optionally contained in the ring structure in Formula (1).

In Formulae (1) and (2), L is also preferably a group represented by any of Formulae (L-1) to (L-5) and more preferably a group represented by any of Formulae (3) to (7).

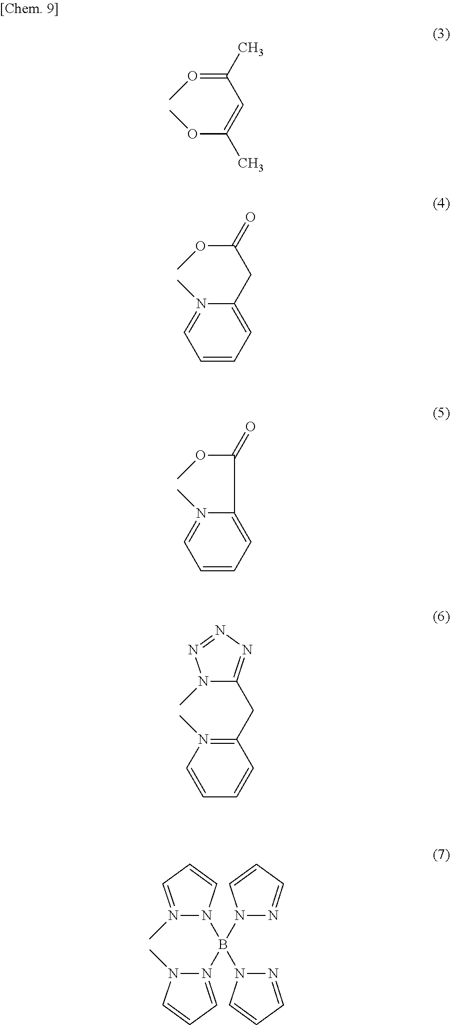

In the transition metal complex of the present disclosure, in the case where the metal center M is Ir or Os, the transition metal complex is preferably a tris complex in which three bidentate ligands are coordinated. In particular, in Formulae (1) and (2), n is preferably 3, m and o are preferably 0; and in Formula (8), n is preferably 3. In this case, the transition metal complex of the present disclosure has geometrical isomers including a fac (facial) isomer and a mer (meridional) isomer; however, the transition metal complex may be any of the fac isomer and mer isomer, or both the fac isomer and mer isomer may be present. In particular, as described below in Examples, the fac isomer content is preferably higher than the mer isomer content, which gives thermal stability and a high PL quantum yield.

Preferred examples of the transition metal complex having an alkoxy group according to the present disclosure will be specified as follows; however, the present disclosure is not limited thereto. In the following examples, geometrical isomers are not particularly specified apart, and the transition metal complex of the present disclosure includes any geometrical isomer. In the following structural formulae, Me represents a methyl group, Et represents an ethyl group, i-Pr represents an isopropyl group, and t-Bu represents a tertiary butyl group.

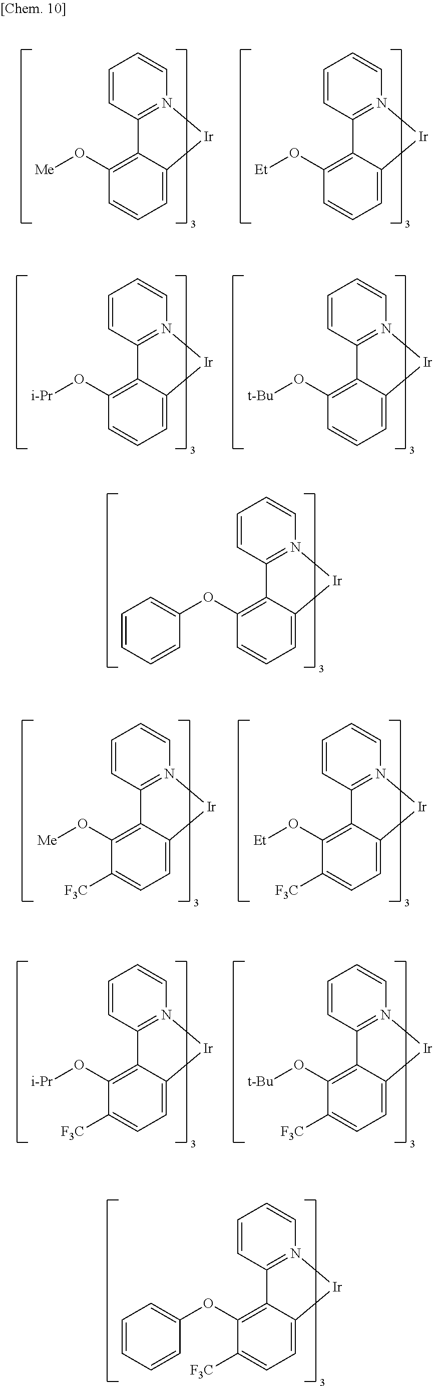

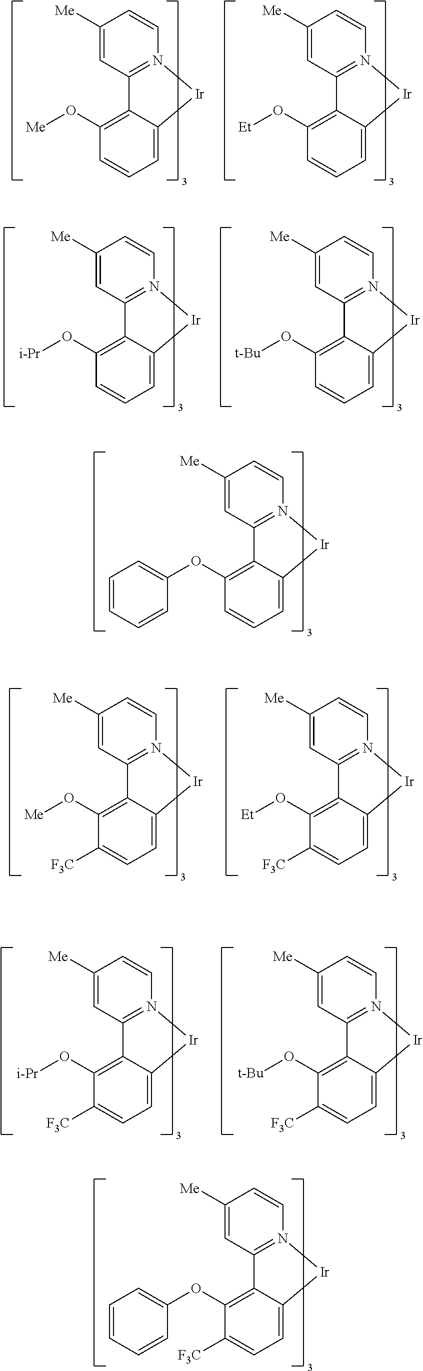

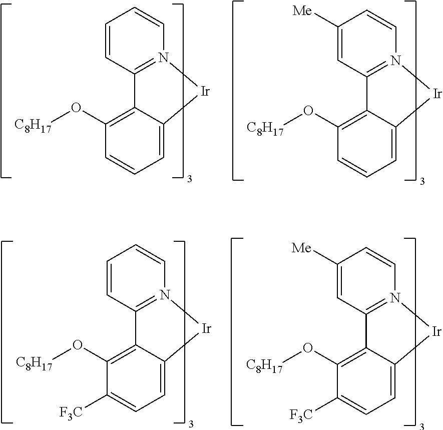

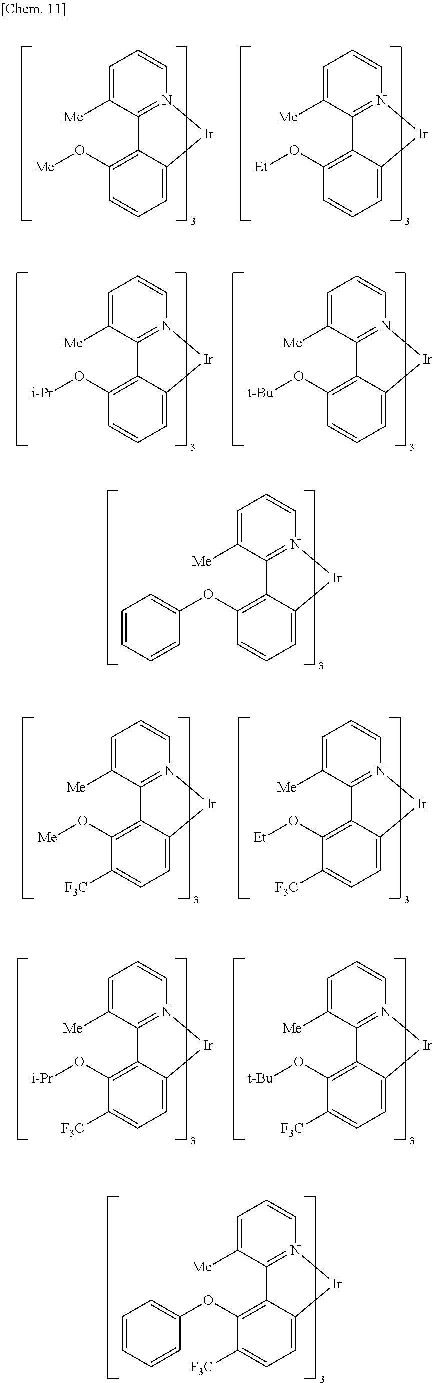

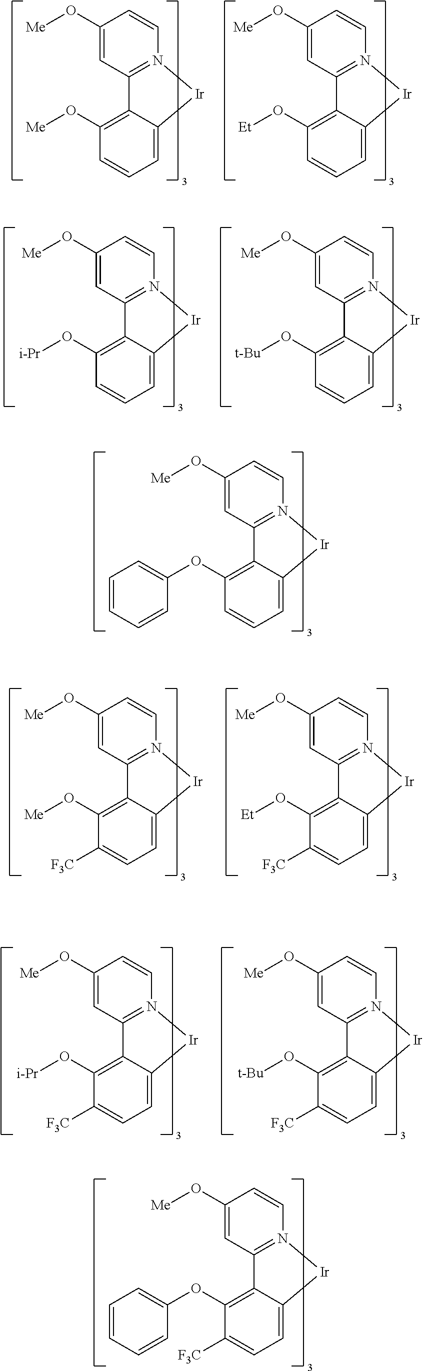

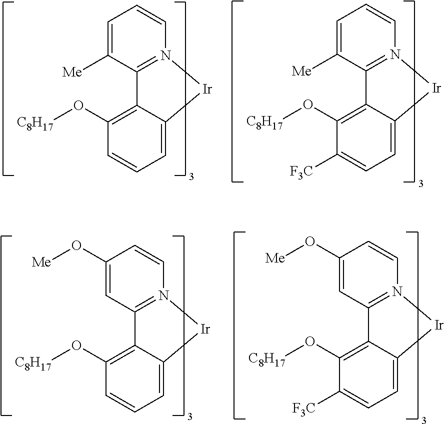

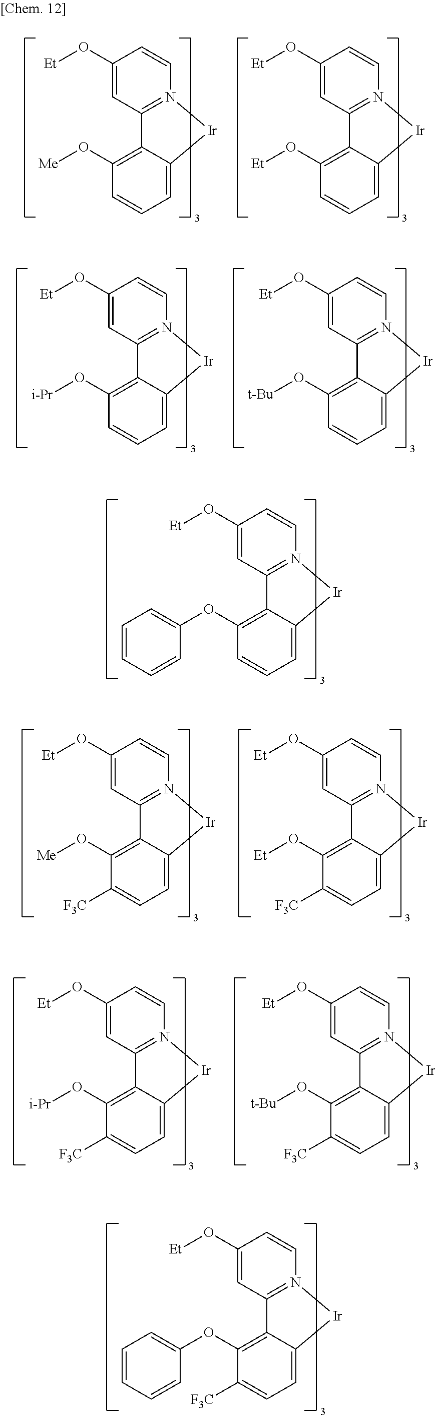

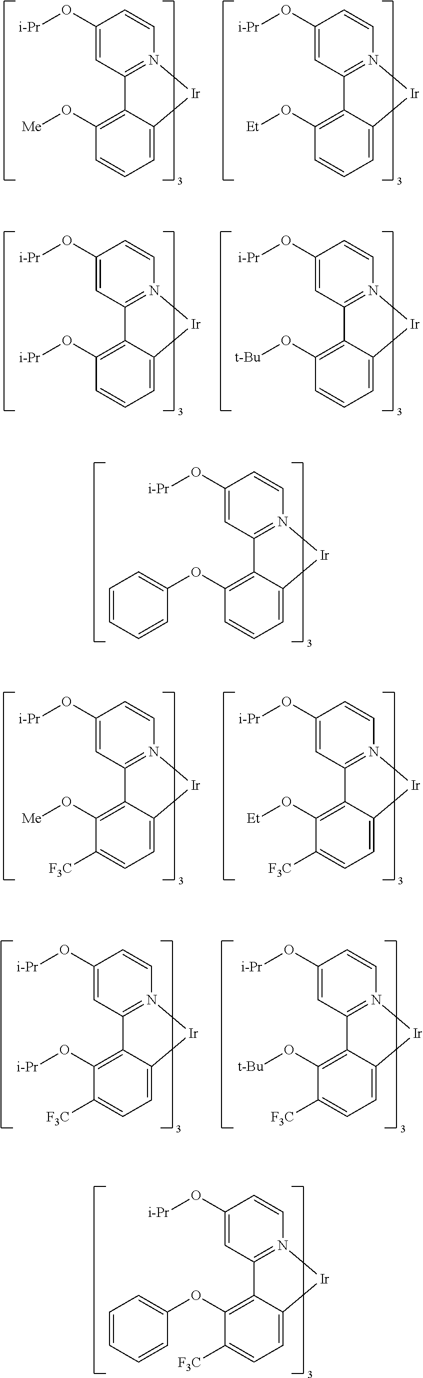

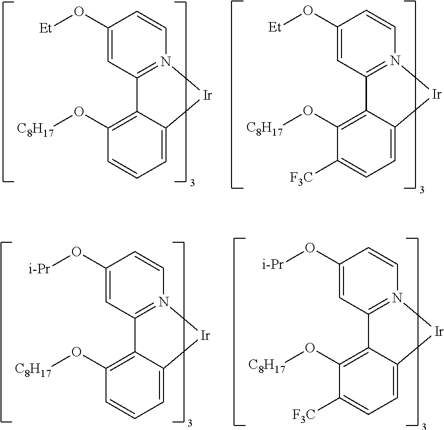

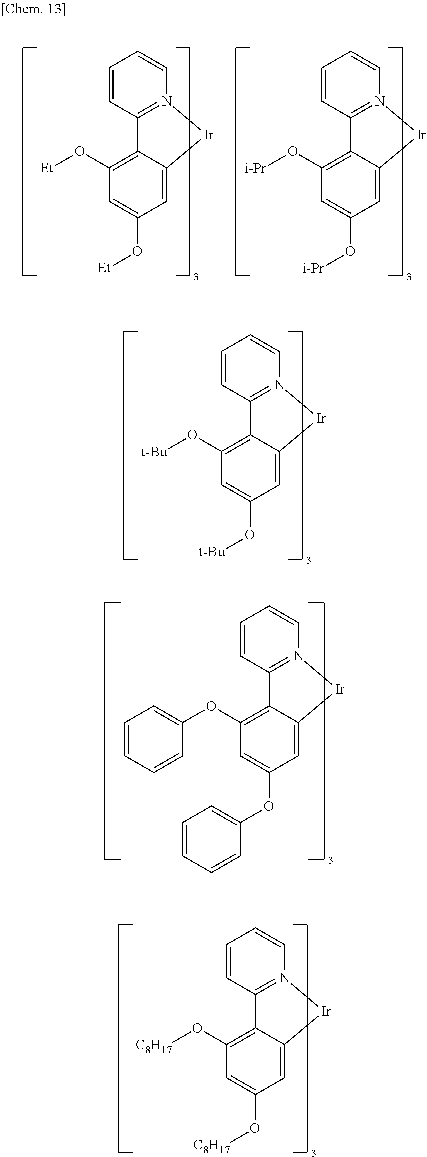

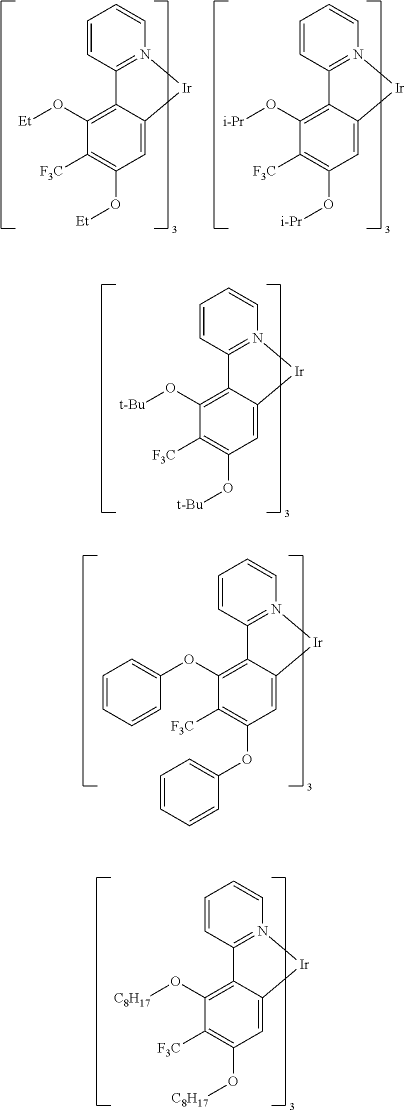

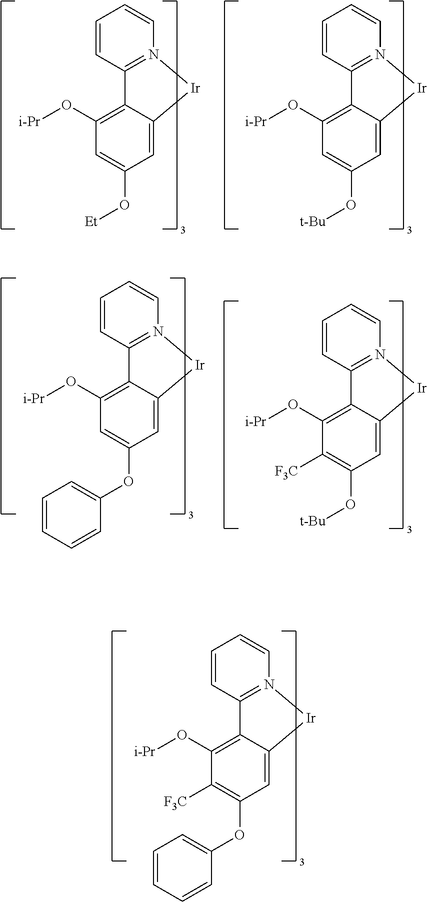

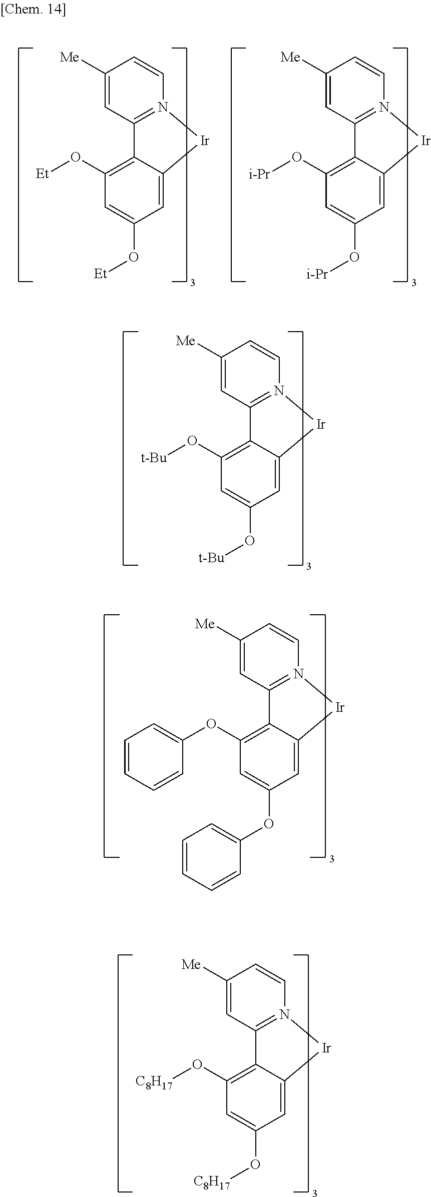

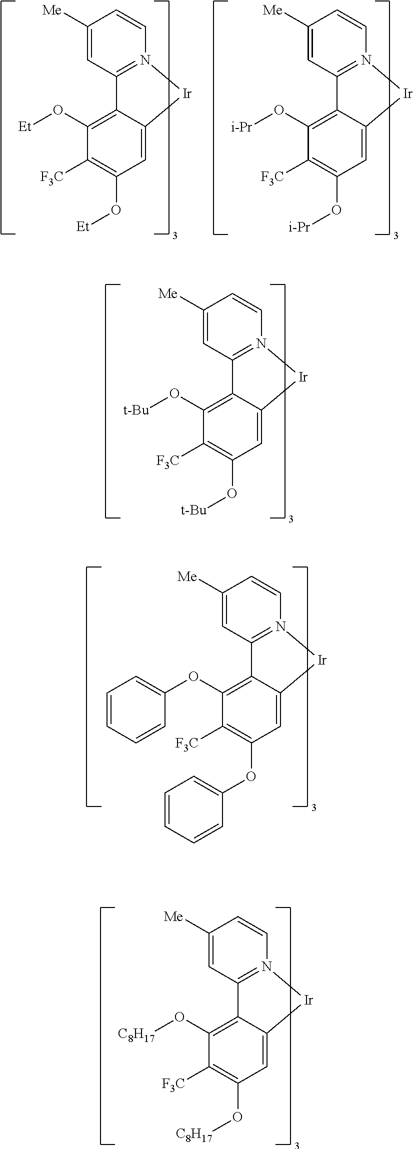

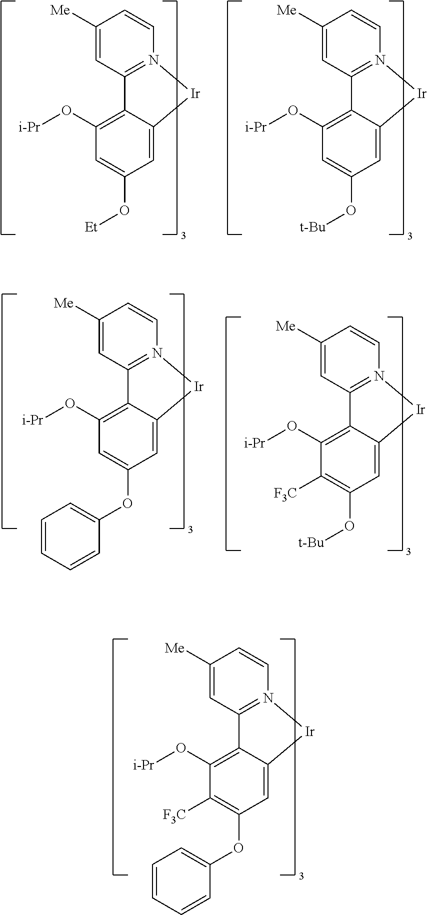

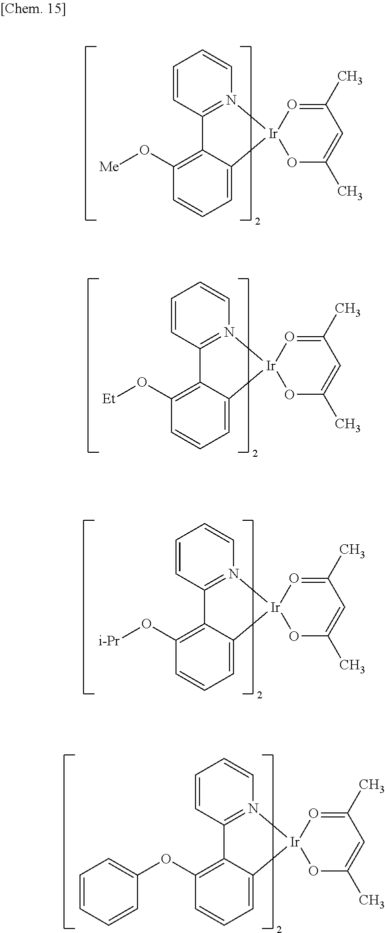

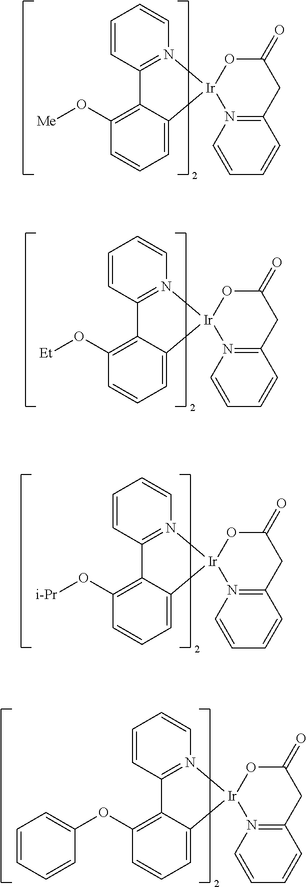

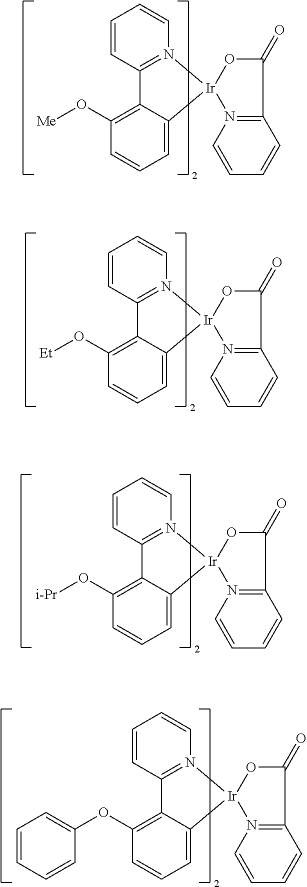

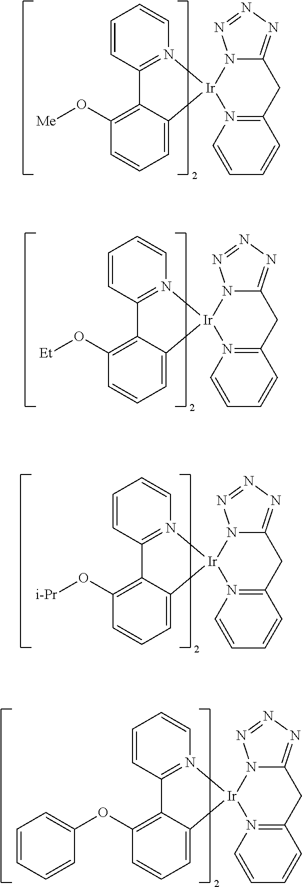

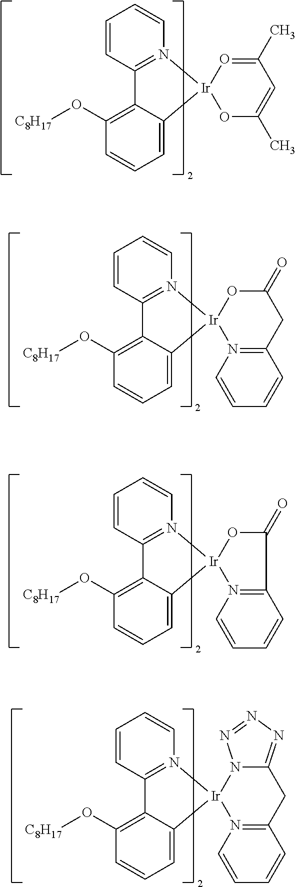

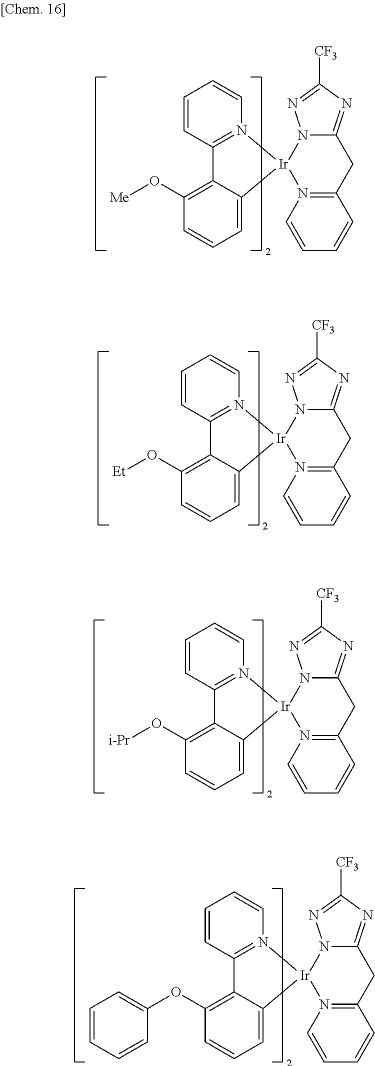

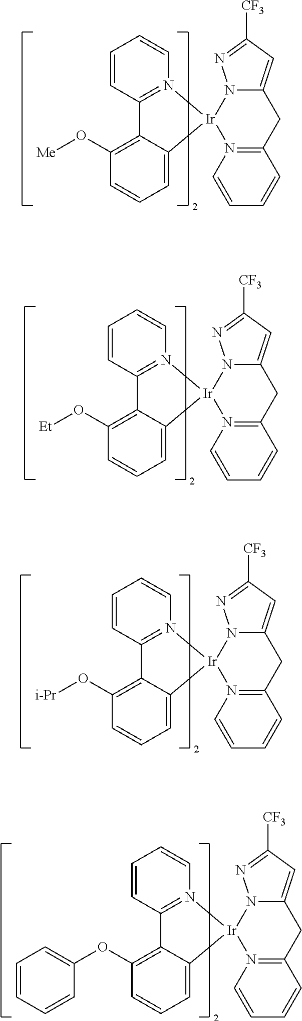

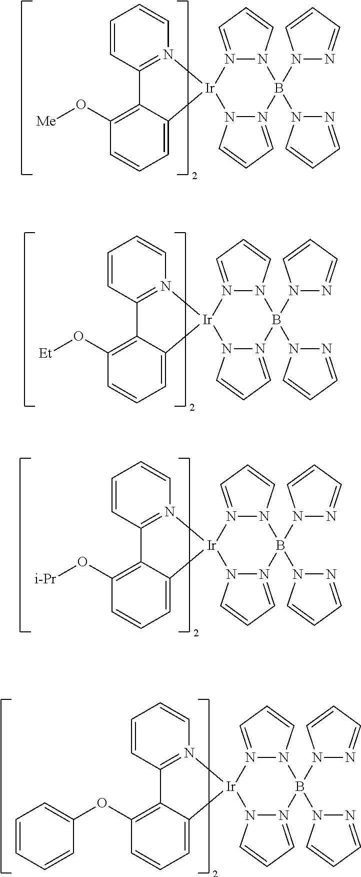

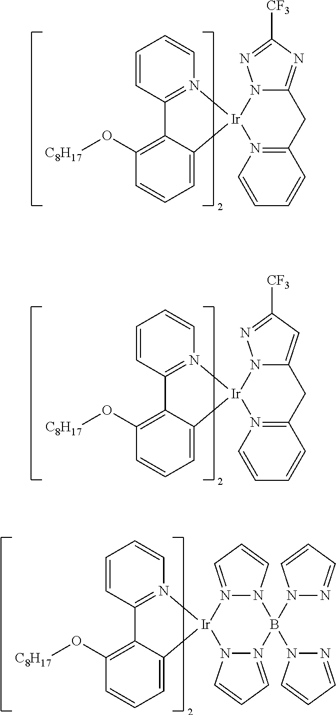

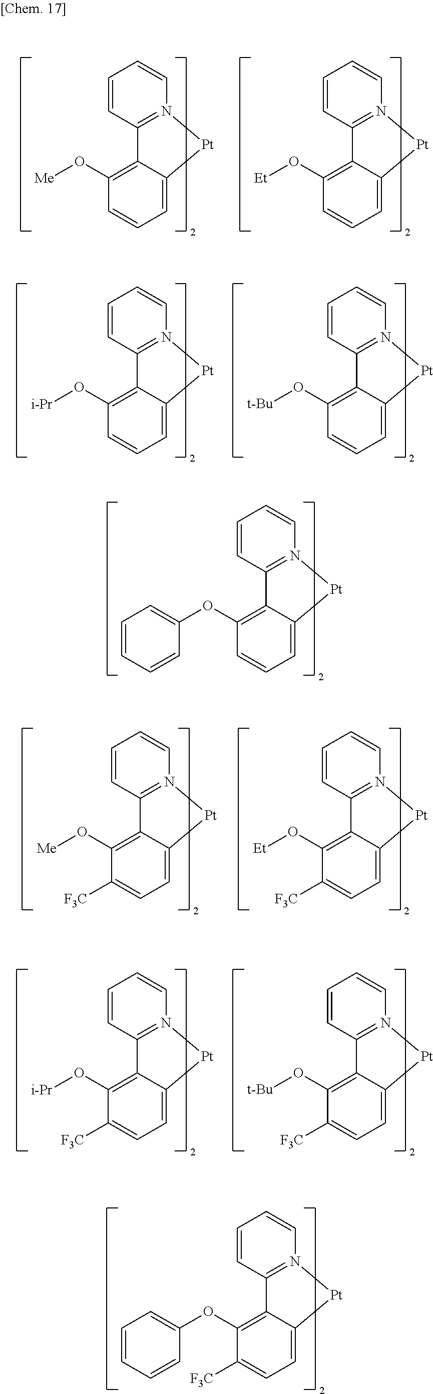

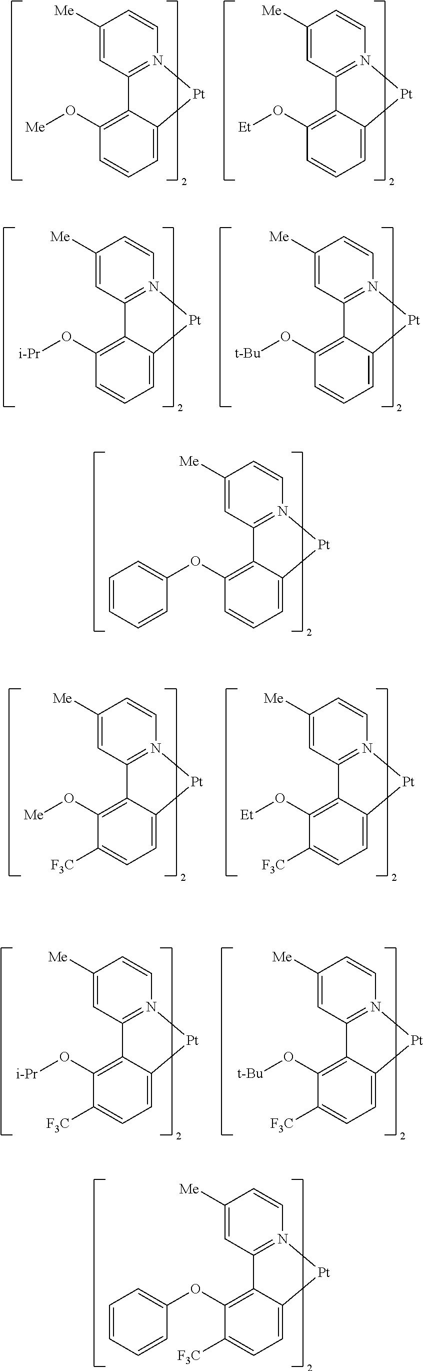

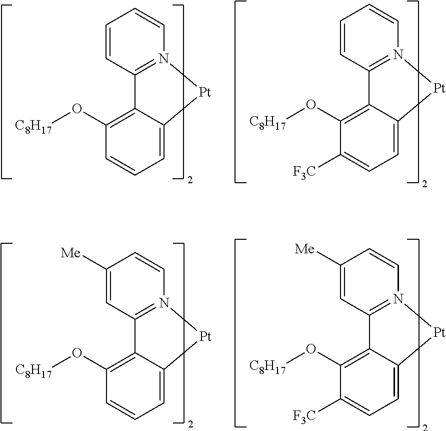

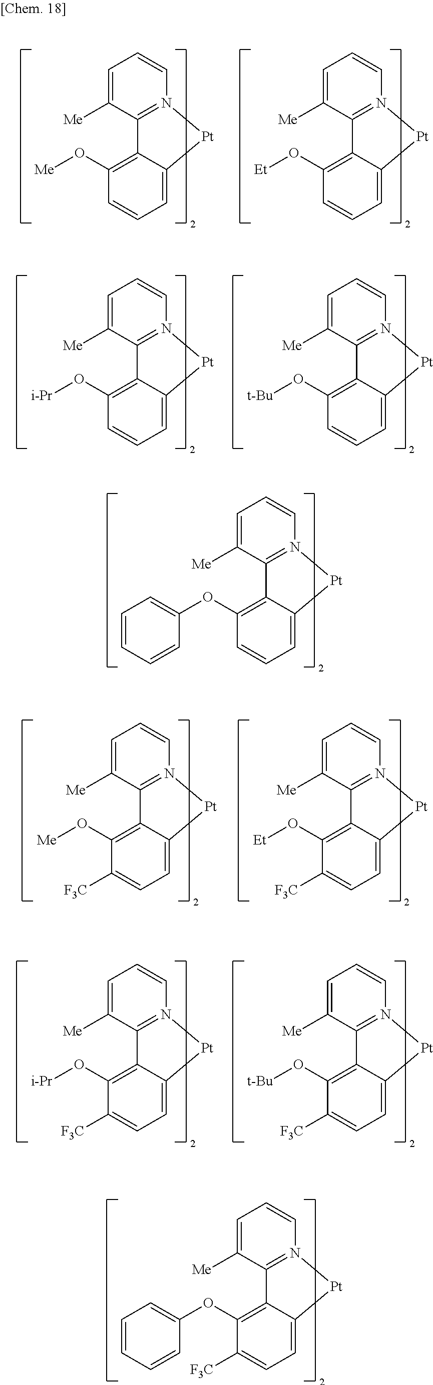

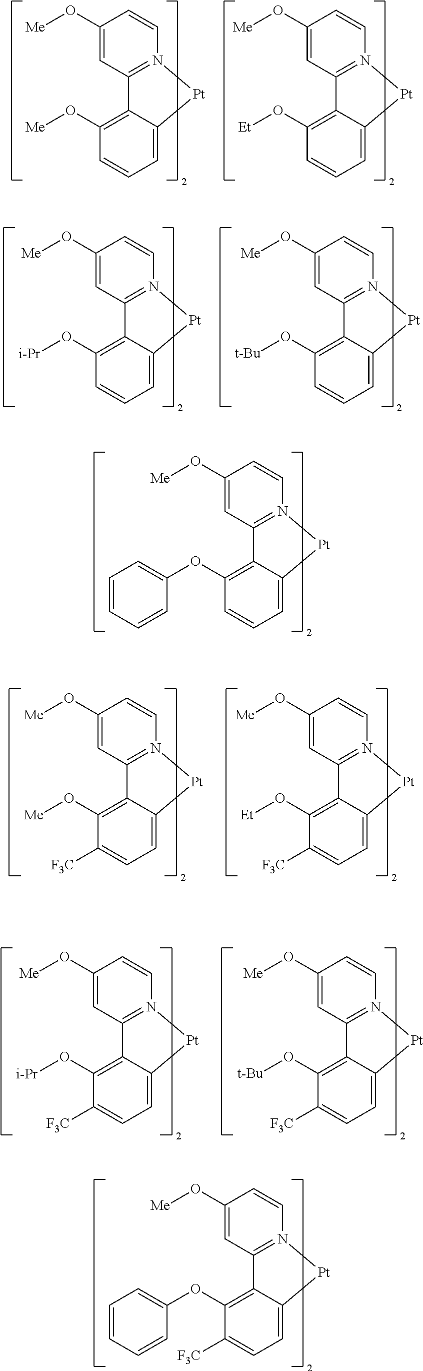

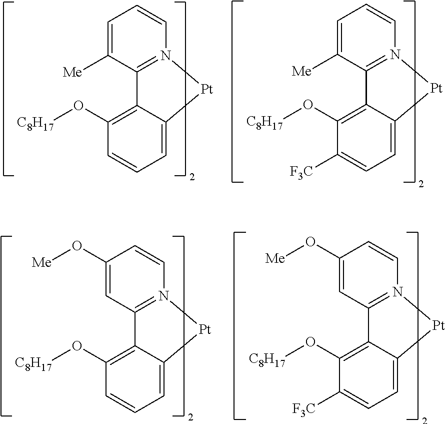

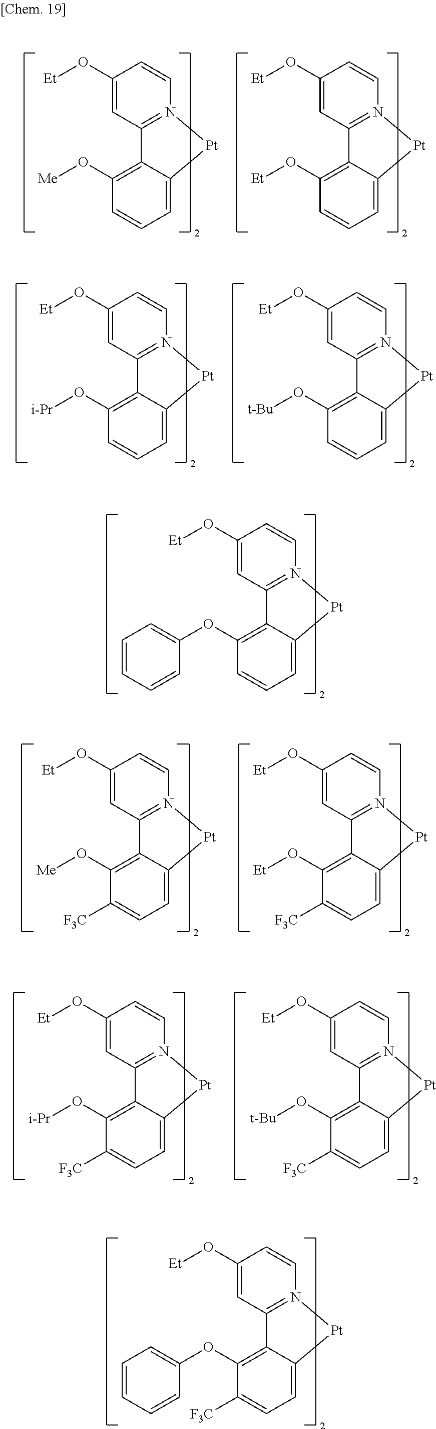

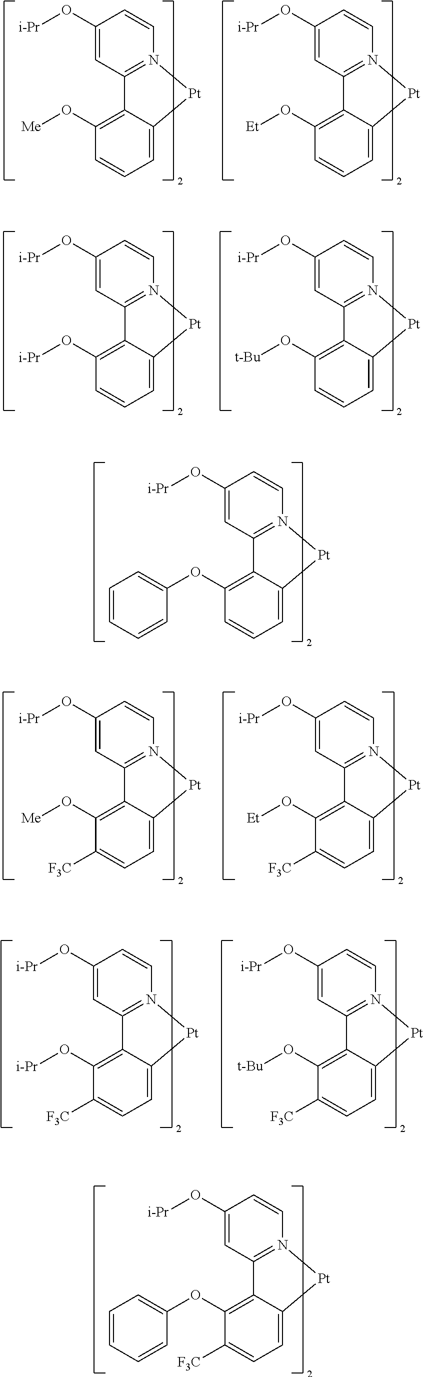

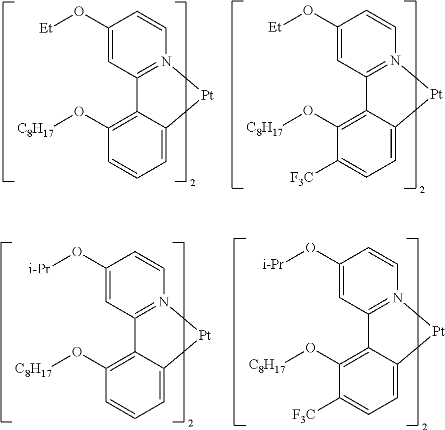

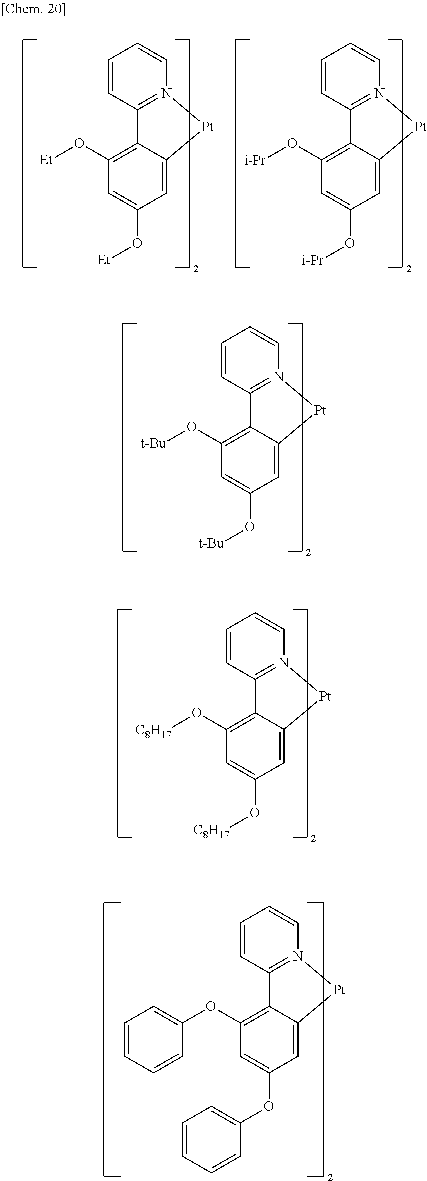

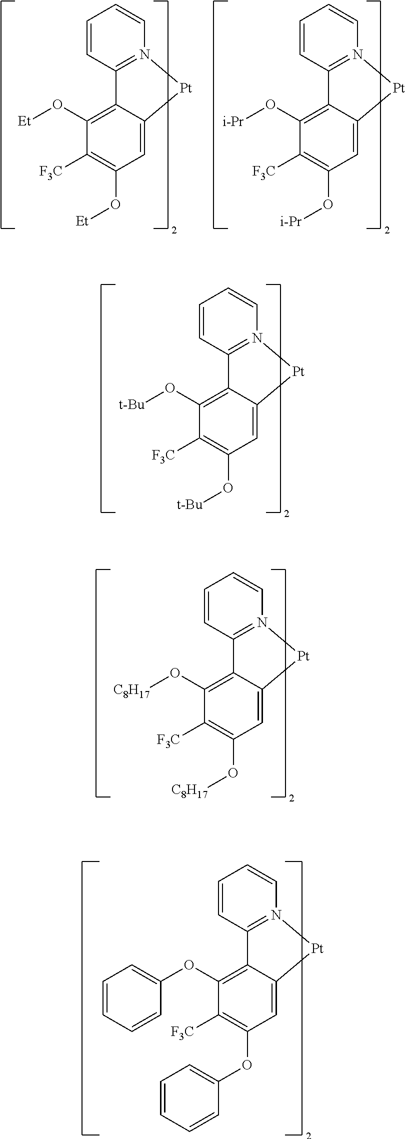

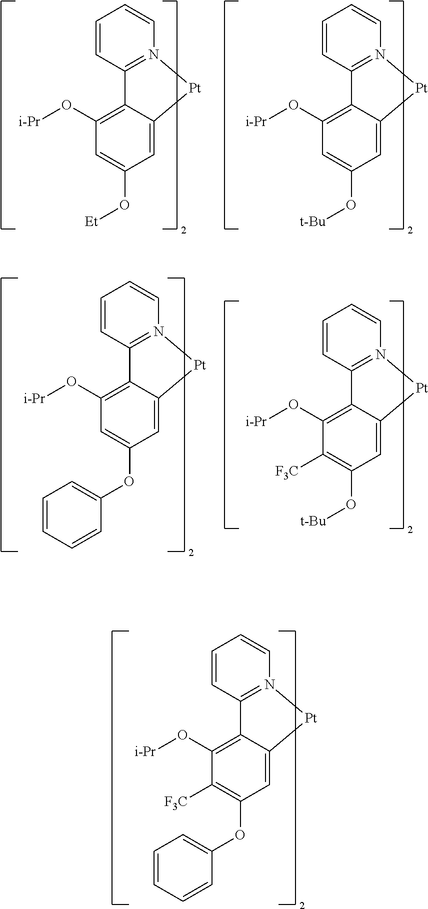

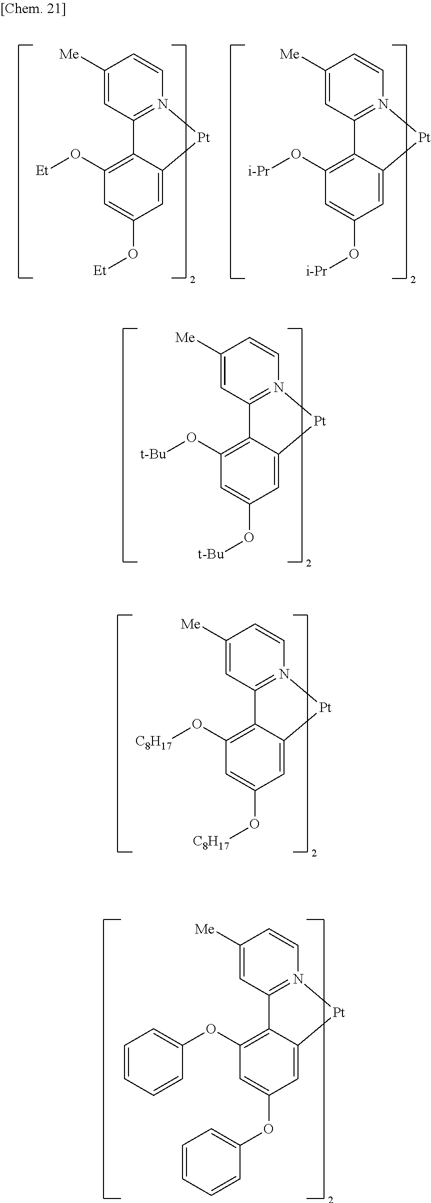

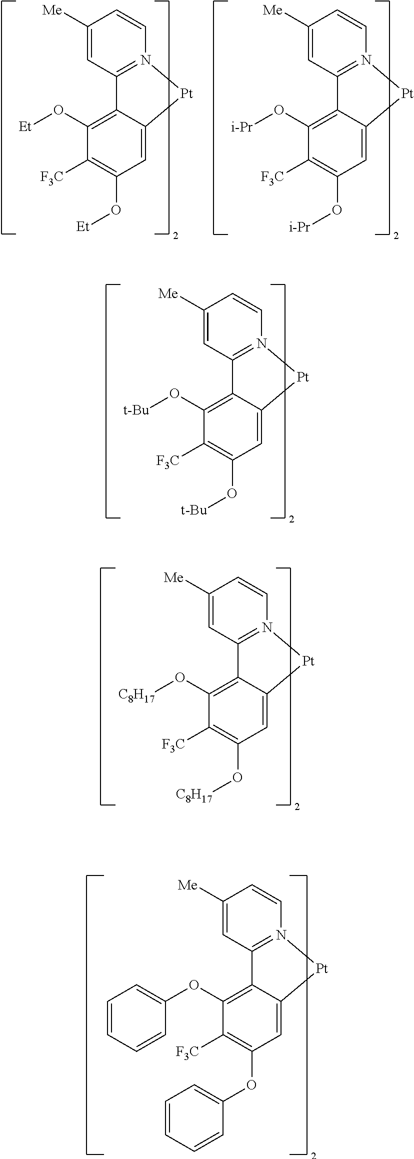

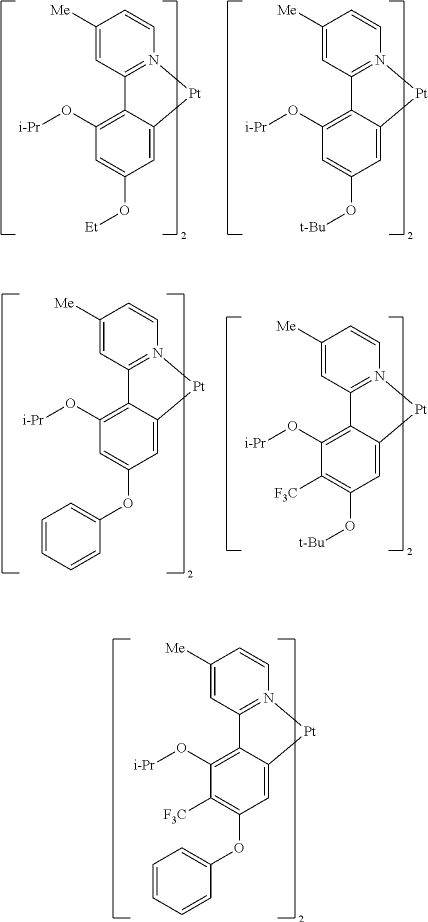

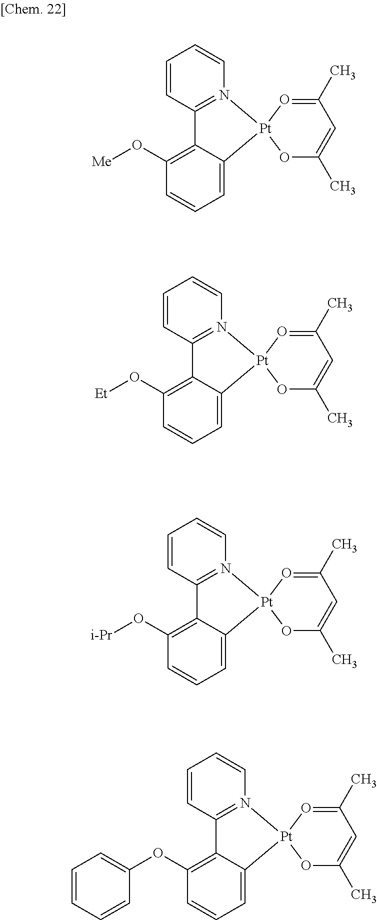

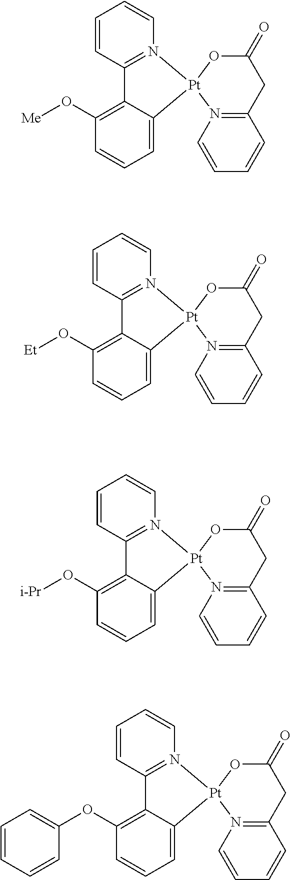

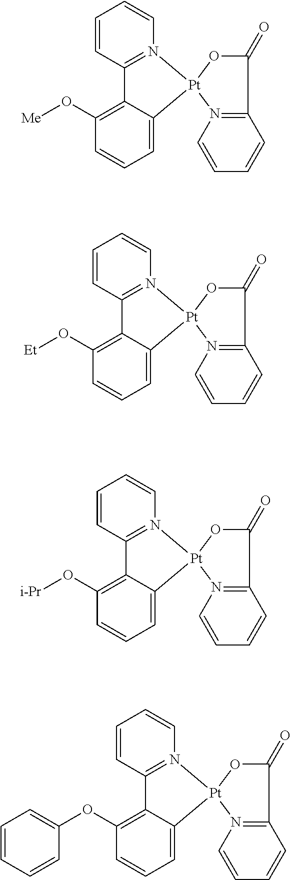

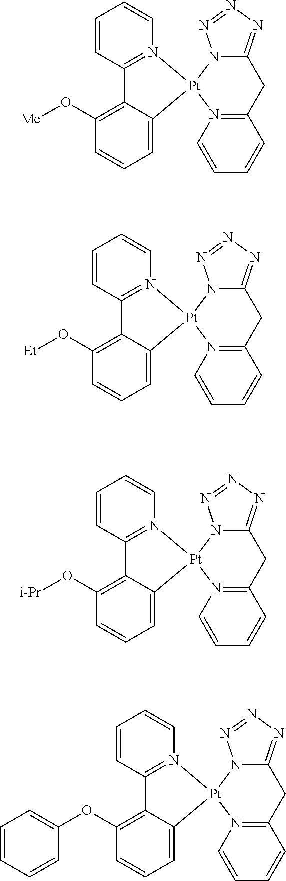

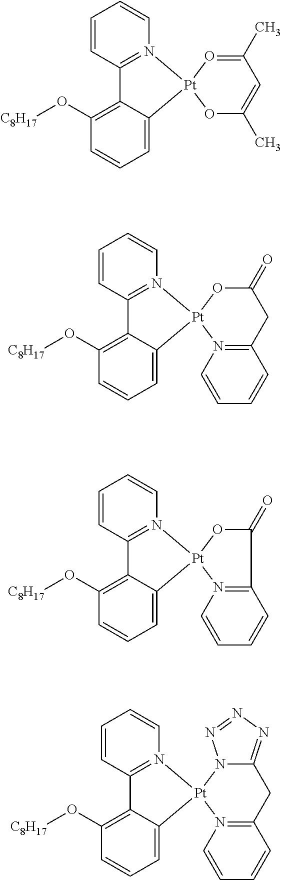

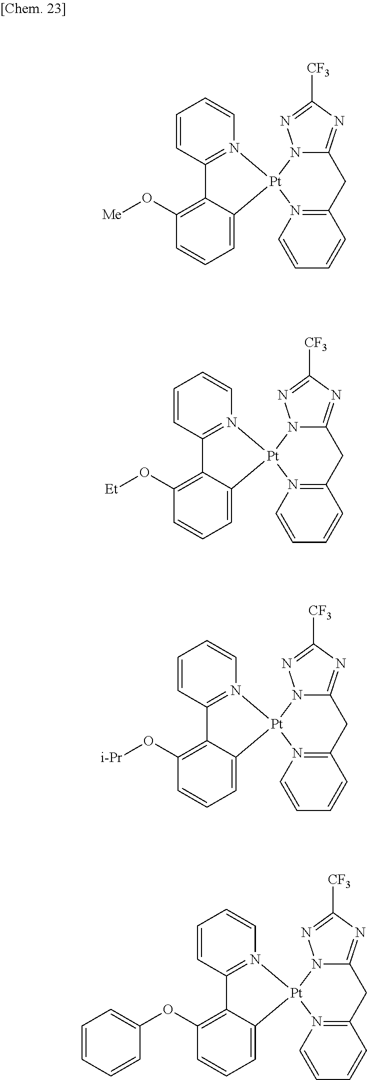

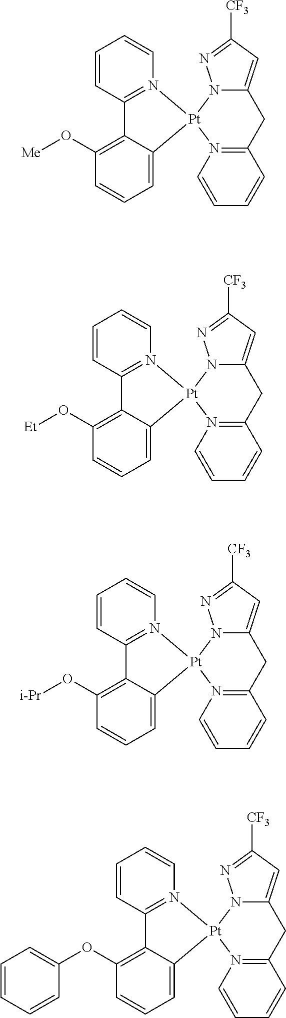

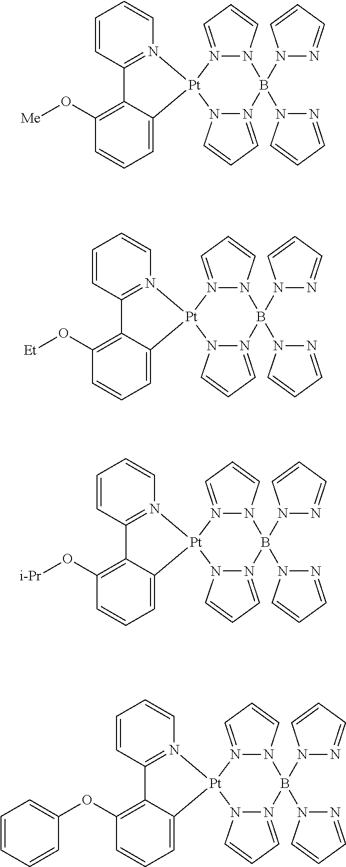

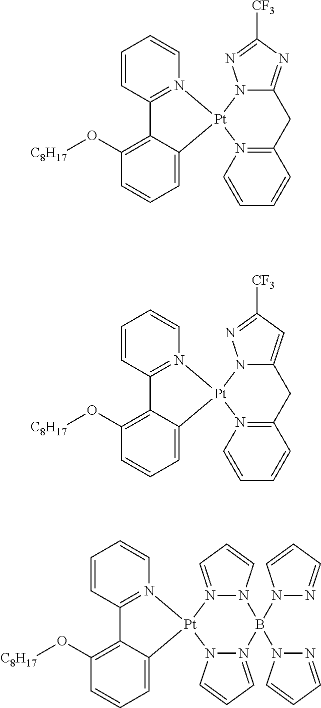

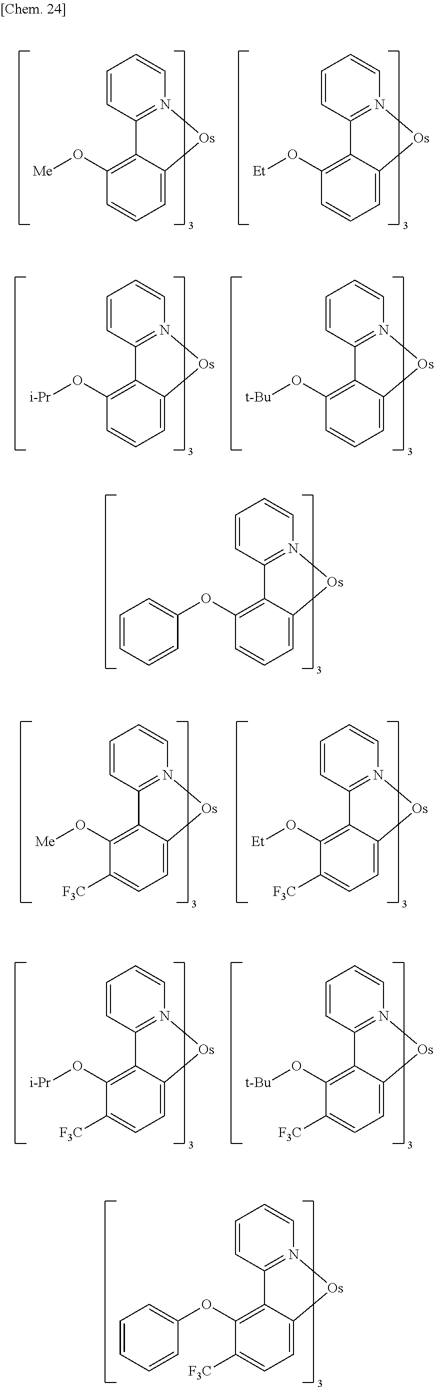

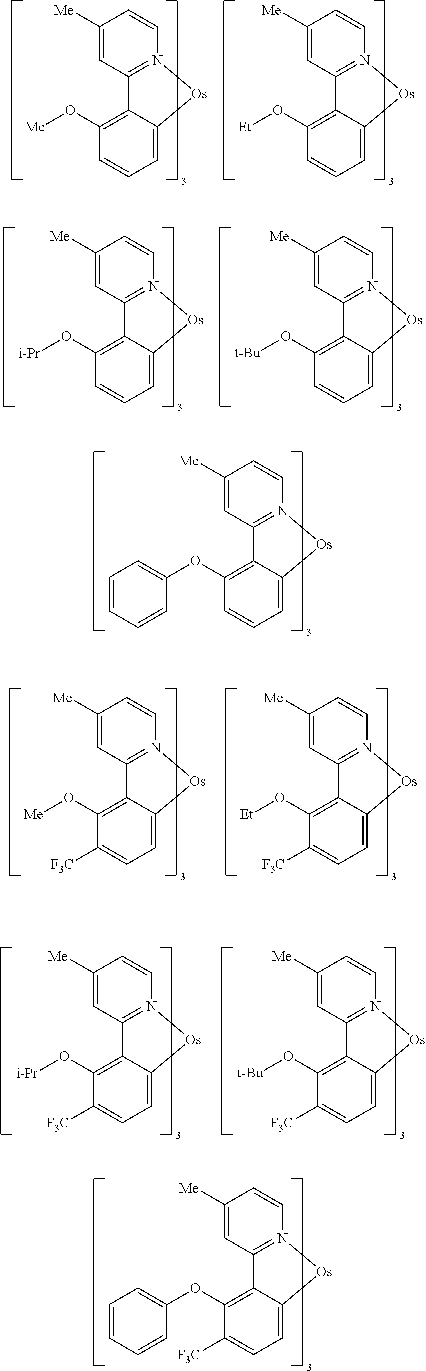

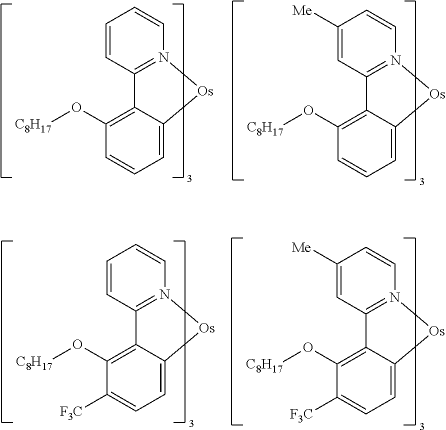

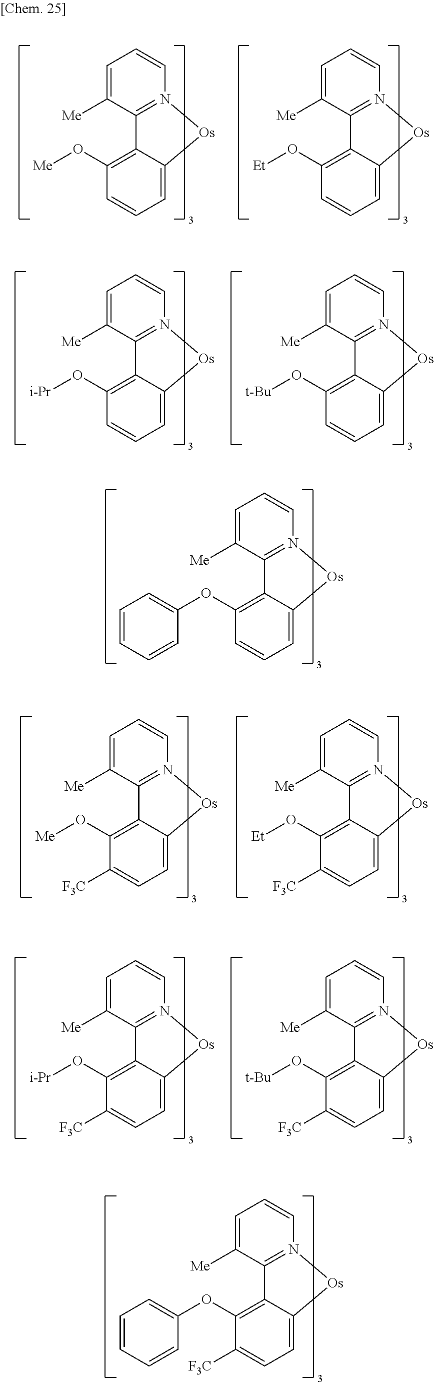

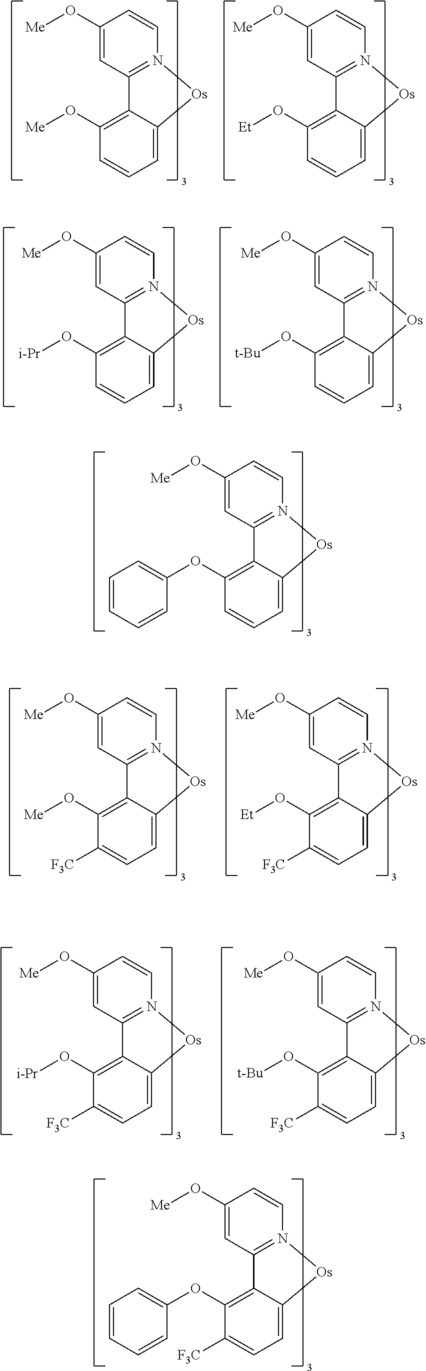

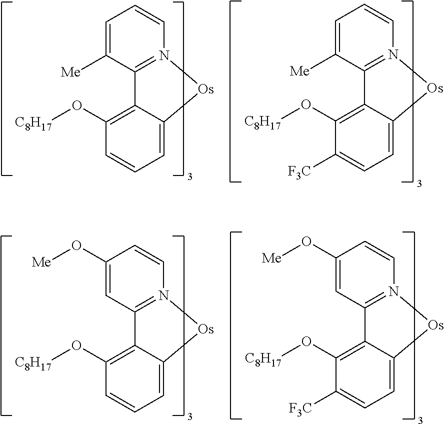

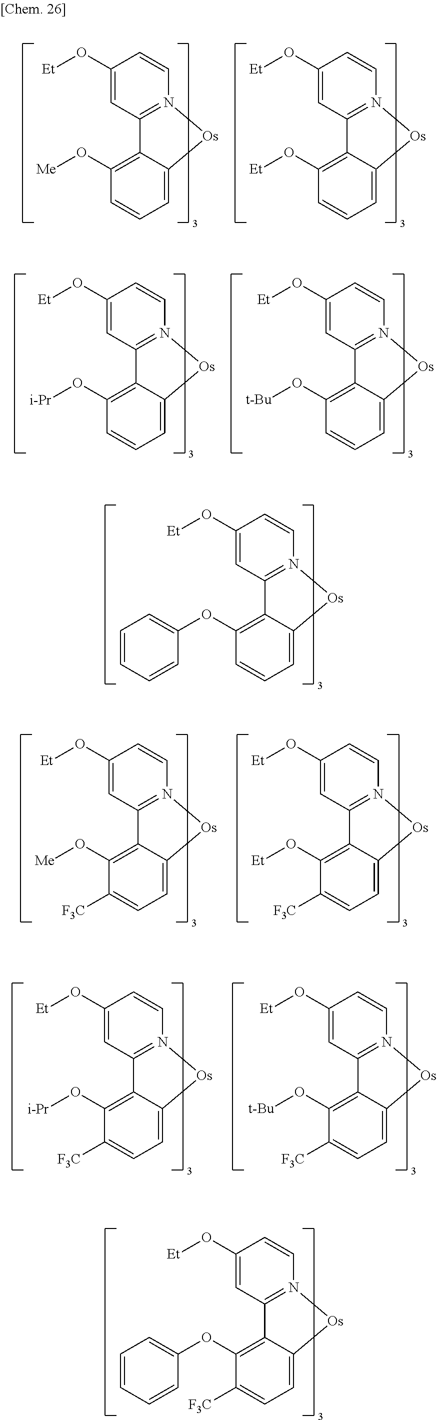

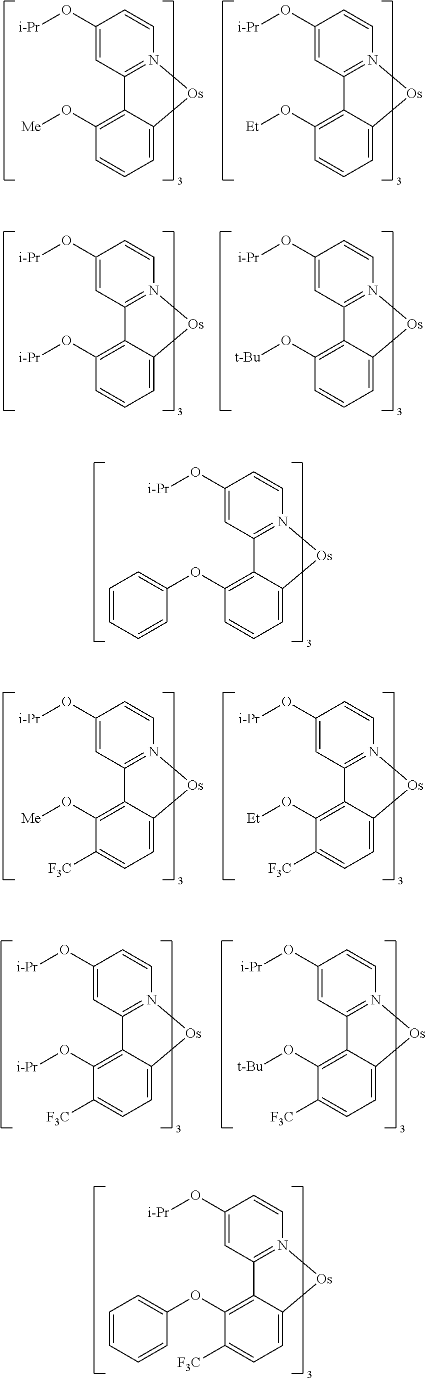

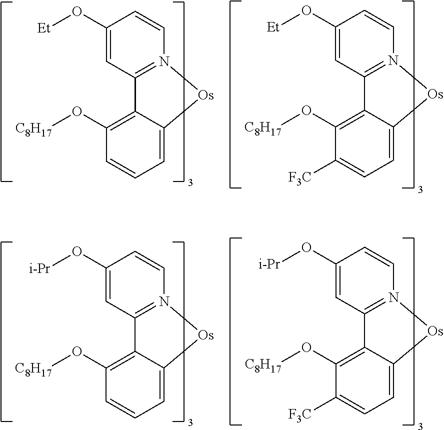

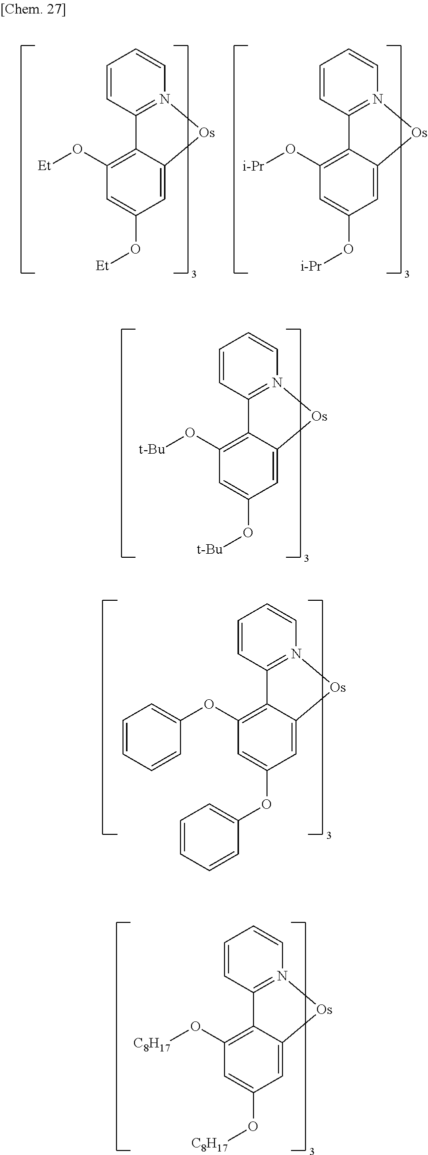

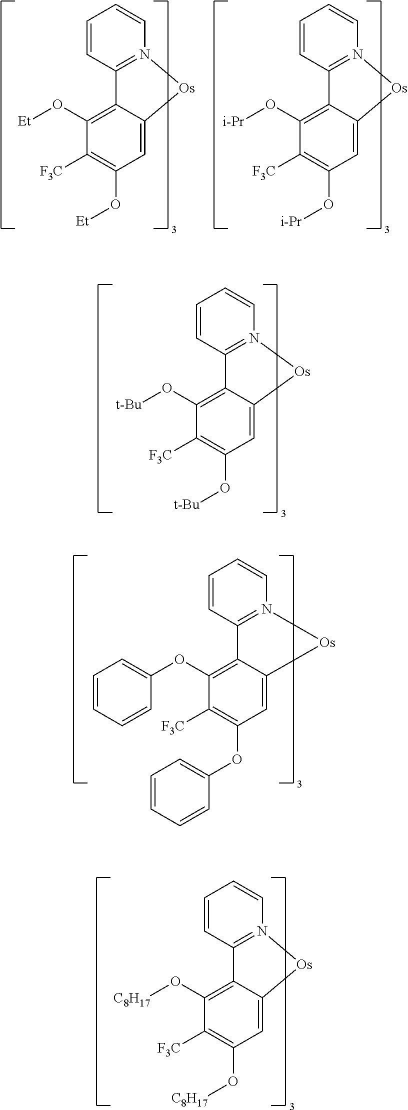

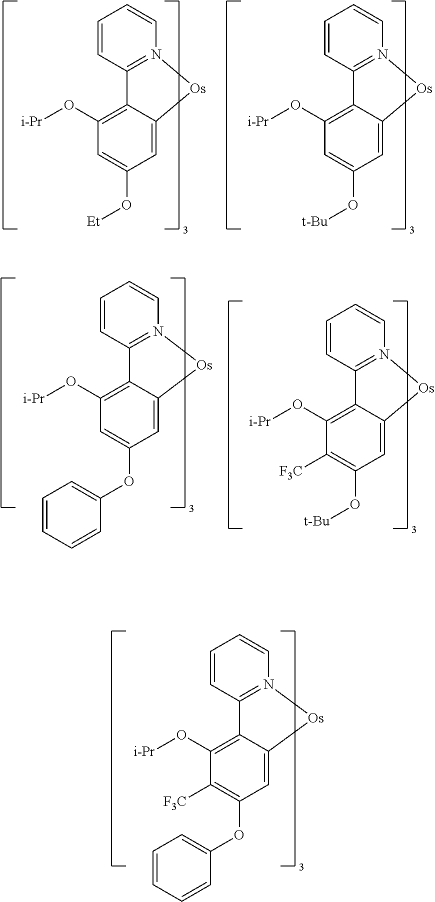

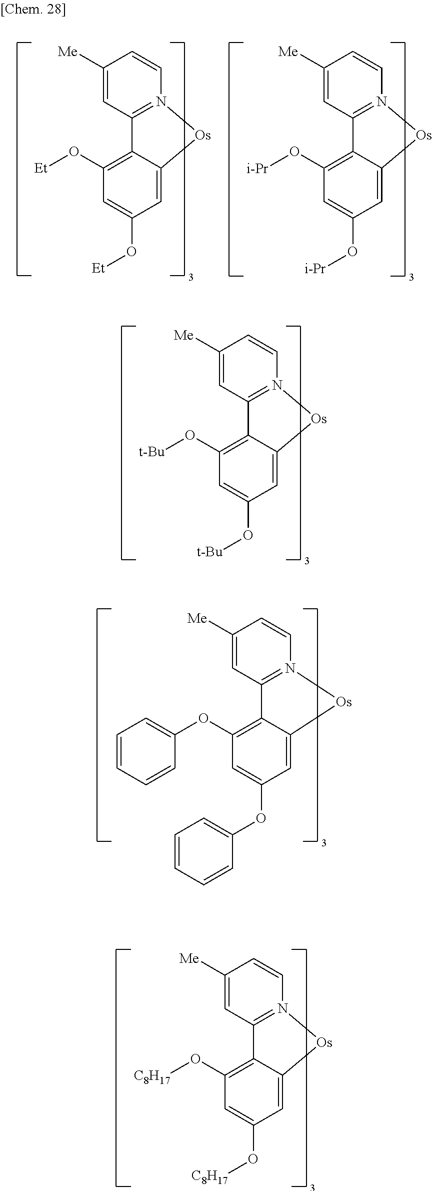

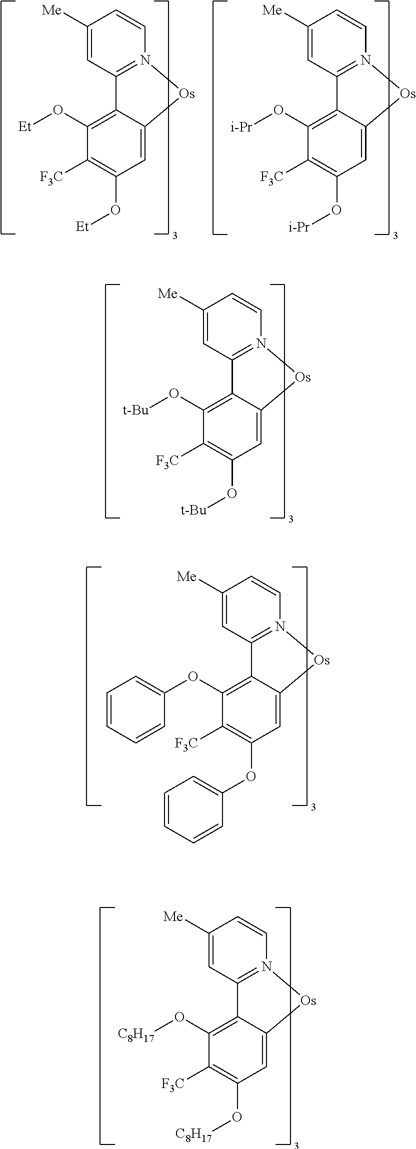

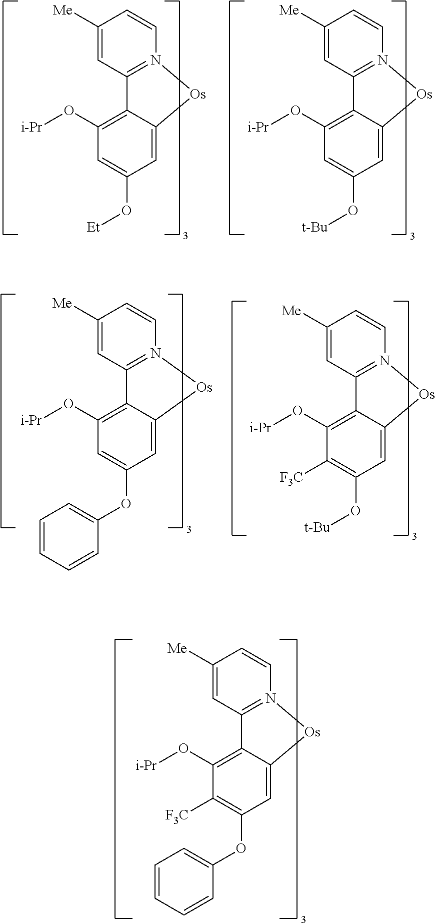

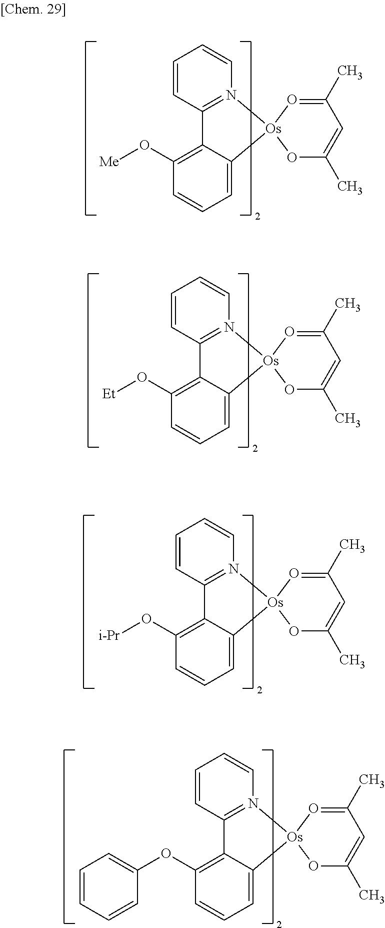

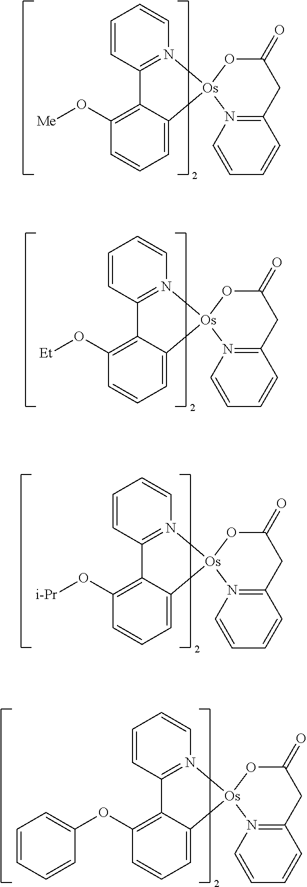

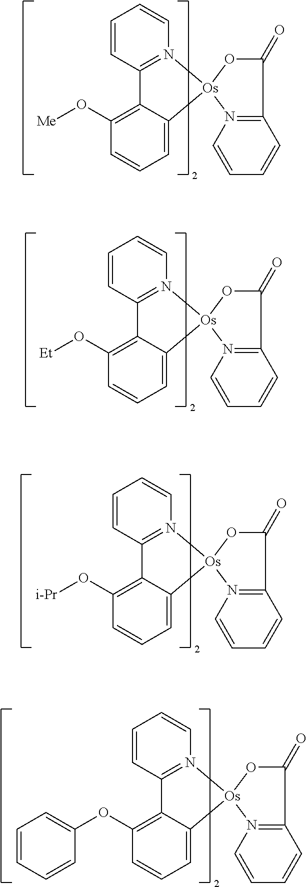

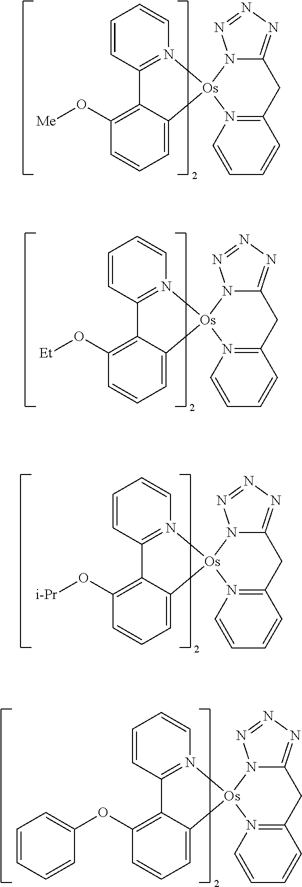

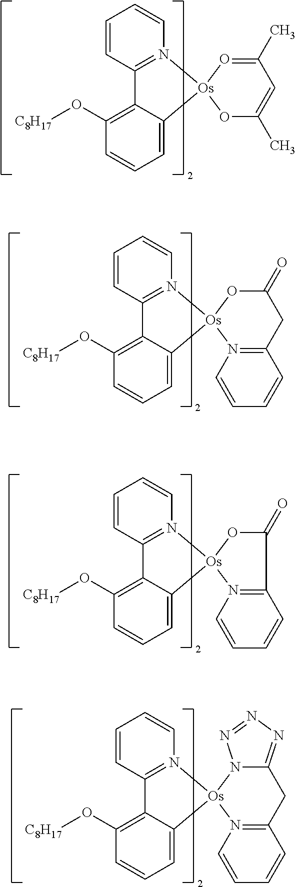

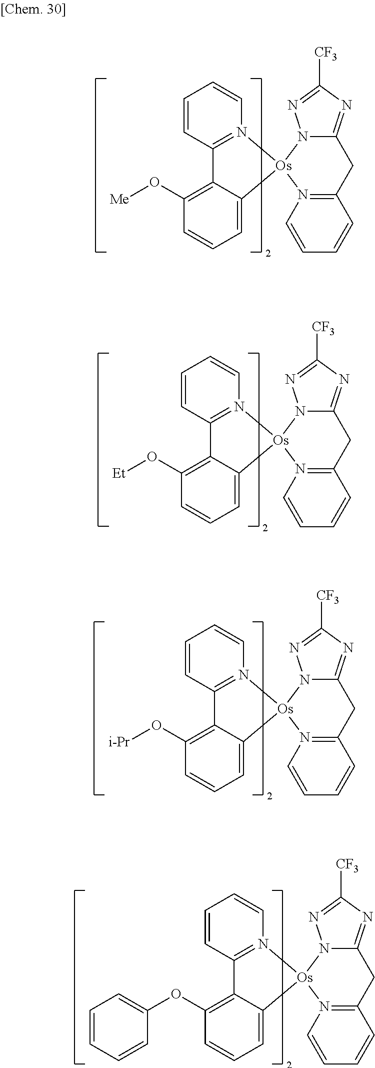

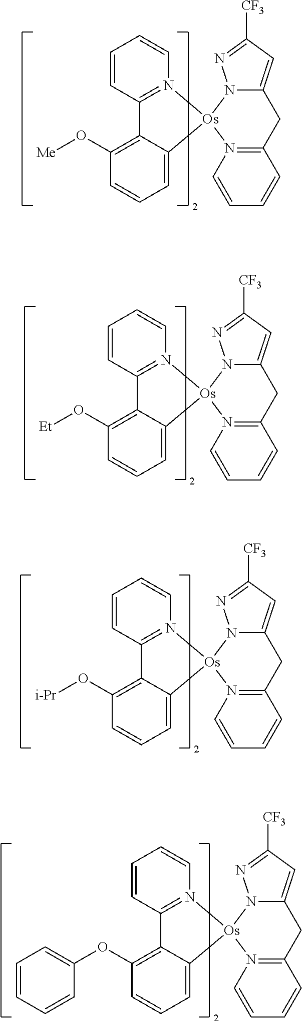

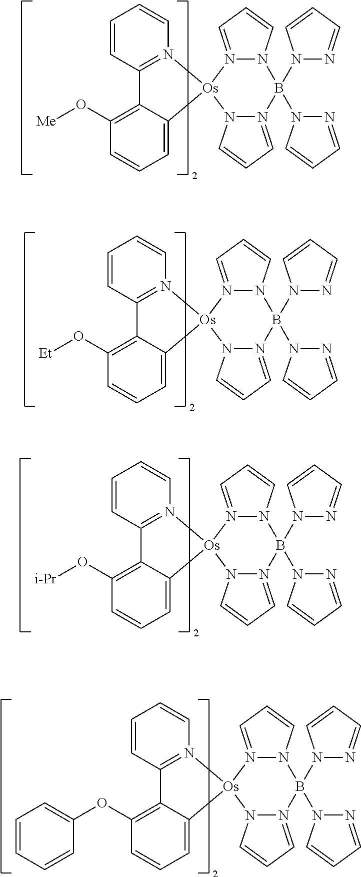

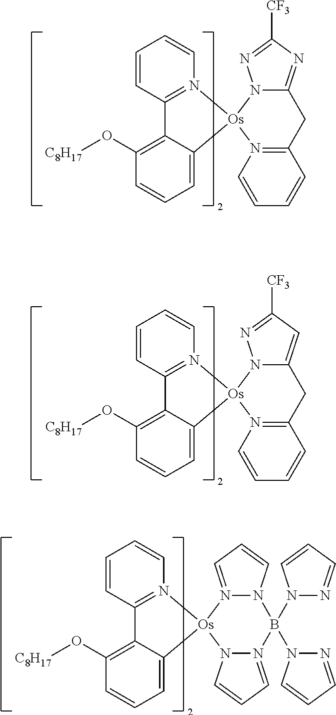

The transition metal complex of the present disclosure has a ligand in which a phenyl group having an alkoxy group (—OA) is in connection with a pyridyl group; furthermore, a carbon atom of the phenyl group and the nitrogen atom of the pyridyl group in the ligand are coordinated with the transition metal M. In the transition metal complex having an alkoxy group according to the present disclosure, such an alkoxy group is present at the third position of the phenyl group in the ligand, which generates twist between the phenyl group and the pyridyl group in the ligand to cleave the n conjugated system; thus, emission wavelength is shortened (an enhancement in color purity), and high luminous efficiency is enabled. Hence, such a transition metal complex can be used as a light-emitting dopant (luminescent material), a host material, and an exciton-blocking material.

A method for synthesizing the transition metal complex having an alkoxy group according to the present disclosure will be described.

An example of the method for synthesizing the transition metal complex having an alkoxy group according to the present disclosure will now be described.

An Ir complex (compound 1) that is an example of the transition metal complex having an alkoxy group according to the present disclosure can be synthesized through the following synthetic route. In the following example of a synthetic scheme, Me represents a methyl group.

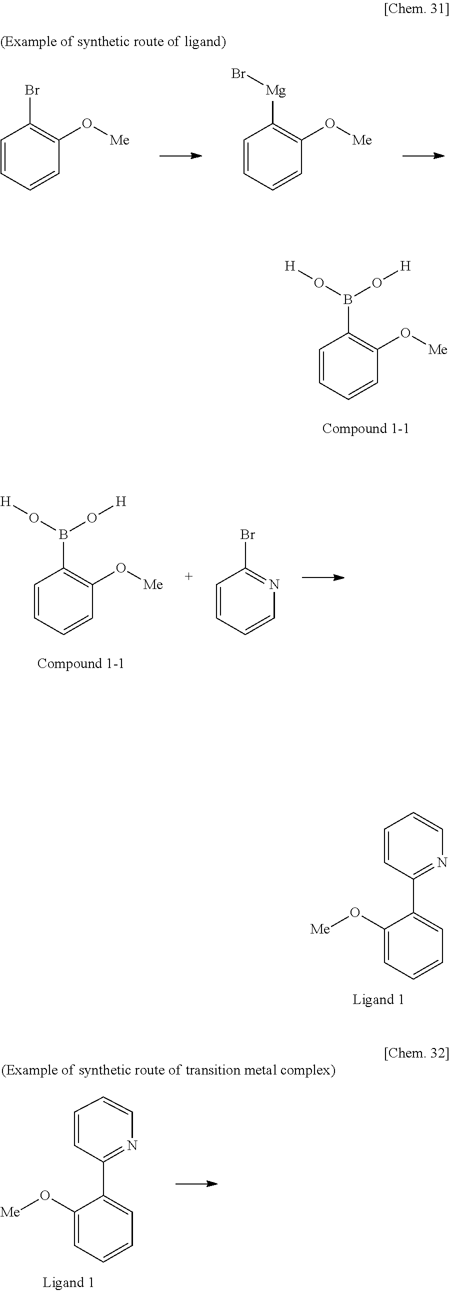

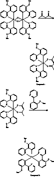

The ligand can be synthesized through the following process.

In the synthesis of the ligand 1, a mixed solution containing 1-bromo-2-methoxybenzene, magnesium, iodine, and THF (tetrahydrofuran) is heated. After the initial reaction terminates, a solution in which 1-bromo-2-methoxybenzene has been dissolved in THF is dropped into the resulting mixed solution, and the product is stirred for 50 minutes at approximately 65° C. Then, the reaction solution was cooled to approximately 10° C., and a solution in which trimethyl borate has been dissolved in THF is dropped thereinto. After the dropping is finished, the reaction solution is stirred for an hour, and then a solution in which ammonium chloride has been dissolved in water is dropped into the reaction solution. After the dropping is finished, the product is stirred for two hours at room temperature, and an insoluble matter is removed by filtration and then washed with THF. The filtrate and the washing liquid are mixed with each other and concentrated under reduced pressure, and water is added to the residue for crystallization. The crystal is collected by filtration and then washed with water, and the wet crystal is dried under reduced pressure to yield a compound 1-1.

Then, a mixed solution containing the compound 1-1, 2-bromopyridine, ethane dichloride, methanol, potassium carbonate, water, and a catalyst is heated under reflux for approximately three hours, then an insoluble matter is removed by filtration, and the filtrate is separated. The separated ethane dichloride layer is washed with water, then hydrochloric acid is dissolved in water, and the ethane dichloride layer is extracted by this solution. The aqueous hydrochloric acid layer is washed with ethane dichloride, a sodium hydroxide solution is added to the aqueous hydrochloric acid layer to adjust the pH to be alkaline, and extraction with methylene chloride is carried out three times. The methylene chloride layer is washed with a salt solution and then dehydrated with magnesium sulfate. The magnesium sulfate is removed by filtration, and then the filtrate is concentrated under reduced pressure to yield a ligand 1.

In the synthesis of the compound 1, under a nitrogen atmosphere, IrCl₃.nH₂O and the ligand 1 in 2-ethoxyethanol and ion exchanged water are stirred at an oil bath temperature of 130° C. for 30 minutes under heating, and the reaction solution is subjected to separation by filtration, collection by filtration, and then drying to yield a dinuclear complex cross-linked with Cl. Then, under a nitrogen atmosphere, the dinuclear complex, acetylacetone, and NaHCO₃ in 2-ethoxyethanol are stirred at an oil bath temperature of 140° C. for an hour under heating. Then, the reaction solution is cooled to room temperature and subjected to separation by filtration and washing with ion exchanged water to produce a crude compound 1. The crude compound 1 is dissolved in chloroform, an insoluble matter is separated by filtration, and then the filtrate is concentrated to yield a compound 1.

In the synthesis of the compound 6, under a nitrogen atmosphere, the compound 1 and the ligand 1 in glycerol are stirred at an oil bath temperature of 150° C. for 4 days under heating, and the resulting solid is subjected to suspension wash with chloroform to produce a solid that is a crude compound 6. The crude compound 6 is purified by sublimation to yield the compound 6. In terms of the geometrical isomer content, this method for synthesizing a transition metal complex enables production of a transition metal complex in which the fac (facial) isomer content is higher than the mer (meridional) isomer content.

The synthesized transition metal complex having an alkoxy group according to the present disclosure can be identified with reference to, for example, a MS spectrum (FAB-MS), a ¹H-NMR spectrum, an LC-MS spectrum.

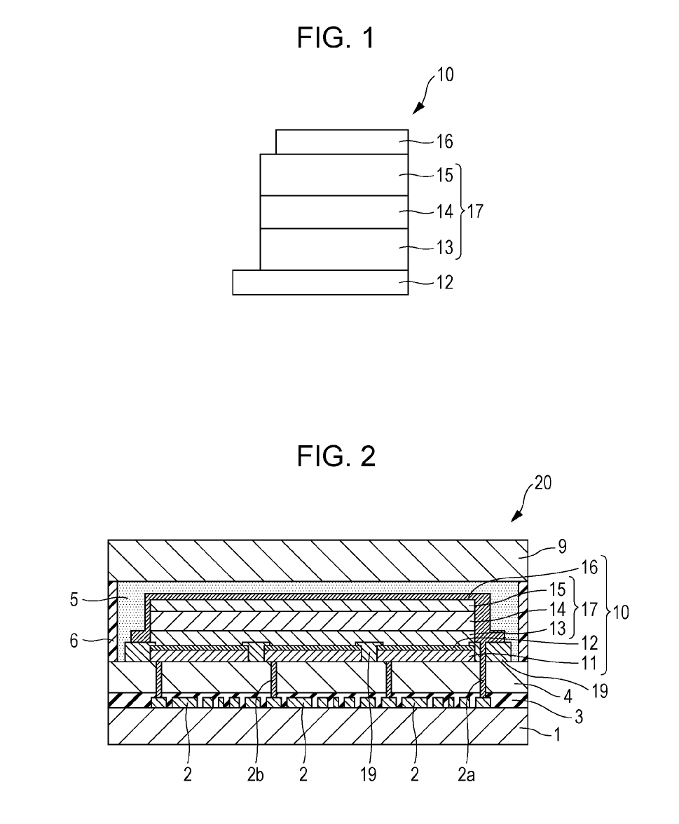

Embodiments of an organic light-emitting device, color conversion light-emitting device, organic laser diode device, dye laser, display system, lighting system, and electronic equipment according to the present disclosure will now be described with reference to the drawings. In FIGS. 1 to 16, the dimensions of elements have been changed to make the elements recognizable on the drawings.

<Organic Light-Emitting Device>

In the organic light-emitting device (organic EL device) of the present disclosure, an organic layer having a mono- or multilayer structure including a light-emitting layer is disposed between a pair of electrodes.

FIG. 1 is a schematic diagram illustrating a first embodiment of the organic light-emitting device of the present disclosure. In an organic light-emitting device 10 illustrated in FIG. 1, a first electrode 12, an organic EL layer (organic layer) 17, and a second electrode 16 are formed in sequence so as to overlie a substrate (not illustrated). In the illustration in FIG. 1, the organic EL layer 17 disposed between the first electrode 12 and the second electrode 16 has a multilayer structure including a hole transport layer 13, organic light-emitting layer 14, and electron transport layer 15 formed in sequence.

The first electrode 12 and the second electrode 16 form a pair to serve as the cathode or anode of the organic light-emitting device 10. In particular, in the case where the first electrode 12 is the anode, the second electrode 16 is the cathode; in the case where the first electrode 12 is the cathode, the second electrode 16 is the anode. In FIG. 1 and the following description, the first electrode 12 is the anode, and the second electrode 16 is the cathode. In the case where the first electrode 12 is the cathode and where the second electrode 16 is the anode, in the multilayer structure of the organic EL layer (organic layer) 17 which will be described later, a hole injection layer and a hole transport layer are placed on the second-electrode-16 side, and an electron injection layer and an electron transport layer are placed on the first-electrode-12 side.

The organic EL layer (organic layer) 17 may have a monolayer structure consisting of the organic light-emitting layer 14 or may have a multilayer structure such as a laminated structure illustrated in FIG. 1 and including the hole transport layer 13, the organic light-emitting layer 14, and the electron transport layer 15. Specific examples of the structure of the organic EL layer (organic layer) 17 are as follows; however, the present disclosure is not limited thereto. In the following structures, the hole injection layer and the hole transport layer 13 are disposed on the first-electrode-12 side, namely the anode side, and the electron injection layer and the electron transport layer 15 are disposed on the second-electrode-16 side, namely the cathode side.

(1) Organic light-emitting layer 14

(2) Hole transport layer 13/organic light-emitting layer 14

(3) Organic light-emitting layer 14/electron transport layer 15

(4) Hole injection layer/organic light-emitting layer 14

(5) Hole transport layer 13/organic light-emitting layer 14/electron transport layer 15

(6) Hole injection layer/hole transport layer 13/organic light-emitting layer 14/electron transport layer 15

(7) Hole injection layer/hole transport layer 13/organic light-emitting layer 14/electron transport layer 15/electron injection layer

(8) Hole injection layer/hole transport layer 13/organic light-emitting layer 14/hole-blocking layer/electron transport layer 15

(9) Hole injection layer/hole transport layer 13/organic light-emitting layer 14/hole-blocking layer/electron transport layer 15/electron injection layer

(10) Hole injection layer/hole transport layer 13/electron-blocking layer/organic light-emitting layer 14/hole-blocking layer/electron transport layer 15/electron injection layer

Each of the organic light-emitting layer 14, hole injection layer, hole transport layer 13, hole-blocking layer, electron-blocking layer, electron transport layer 15, and electron injection layer may have a monolayer structure or a multilayer structure.

In the case where the organic EL layer 17 includes an exciton-blocking layer, the exciton-blocking layer is disposed between the hole transport layer 13 and the organic light-emitting layer 14 and/or between the organic light-emitting layer 14 and the electron transport layer 15. The exciton-blocking layer serves to inhibit excitons generated in the organic light-emitting layer 14 from being deactivated due to energy transfer thereof to the hole transport layer 13 and the electron transport layer 15, so that the energy of the excitons can be further effectively utilized for light emission, which enables efficient light emission. Although the exciton-blocking layer may be formed of known exciton-blocking materials, the transition metal complex having an alkoxy group according to the present disclosure may be used as an exciton-blocking material for forming the exciton-blocking layer.

The organic light-emitting layer 14 may be formed of the above-mentioned transition metal complex of the present disclosure alone. The transition metal complex of the present disclosure may be used as a dopant (luminescent material) in combination with a host material to form the organic light-emitting layer 14. The transition metal complex of the present disclosure may be also used as a host material in combination with a light-emitting dopant to form the organic light-emitting layer 14. In the present disclosure, a hole transport material, an electron transport material, and additives (e.g., donor and acceptor) may be optionally added, and these materials may be dispersed in a polymeric material (binder resin) or an inorganic material. Holes injected from the first electrode 12 are combined with electrons injected from the second electrode 16 in the organic light-emitting layer 14, and the organic light-emitting layer 14 emits light (luminescence) owing to phosphorescence emission by the transition metal complex (luminescent material) of the present disclosure or light-emitting dopant which are contained in the organic light-emitting layer 14.

In the case where the transition metal complex of the present disclosure is used as a light-emitting dopant (luminescent material) in combination with a typical host material in the organic light-emitting layer 14, known host materials used for organic EL can be employed. Examples of such host materials include carbazole derivatives such as 4,4′-bis(carbazole)biphenyl, 9,9-di(4-dicarbazole-benzyl)fluorene (CPF), 3,6-bis(triphenylsilyl)carbazole (mCP), poly(N-octyl-2,7-carbazole-O-9,9-dioctyl-2,7-fluorene) (PCF), 1,3,5-tris(carbazol-9-yl)benzene (TCP), and 9,9-bis[4-(carbazol-9-yl)-phenyl]fluorene (FL-2CBP); aniline derivatives such as 4-(diphenylphosphoyl)-N,N-diphenylaniline (HM-A1); fluorine derivatives such as 1,3-bis(9-phenyl-9H-fluorene-9-yl)benzene (mDPFB) and 1,4-bis(9-phenyl-9H-fluorene-9-yl)benzene (pDPFB); and 1,3,5-tris[4-(diphenylamino)phenyl]benzene (TDAPB), 1,4-bis-triphenylsilyl benzene (UGH-2), 1,3-bis(triphenylsilyl)benzene (UGH-3), and 9-(4-tert-butylphenyl)-3,6-bis(triphenylsilyl)-9H-carbazole (CzSi).

In the case where the transition metal complex of the present disclosure is used as a host material in combination with a typical light-emitting dopant in the organic light-emitting layer 14, known light-emitting dopant materials used for organic EL can be employed. Examples of such light-emitting dopant materials include phosphorescent organic metal complexes, e.g., iridium complexes such as tris(2-phenylpyridine)iridium (III) (Ir(ppy)₃), bis(2-phenylpyridine)(acetylacetonate)iridium (III) (Ir(ppy)₂(acac)), tris[2-(p-tolyl)pyridine]iridium (III) (Ir(mppy)₃), bis[(4,6-difluorophenyl)-pyridinato-N,C2′]picolinate iridium (III) (FIrPic), bis(4′,6′-difluorophenyl pyridinato)tetrakis(1-pyrazolyl)borate iridium (III) (FIr6), tris(1-phenyl-3-methylbenzimidazoline-2-ylidene-C,C2′)iridium (III) (Ir(Pmb)₃), bis(2,4-bifluorophenyl pyridinato)(5-(pyridine-2-yl)-1H-tetrazonate)iridium (III) (FIrN4), bis(2-benzo[b]thiophene-2-yl-pyridine)(acetylacetonato)iridium (III) (Ir(btp)₂(acac)), tris(1-phenylisoquinoline)iridium (III) (Ir(piq)₃), tris(1-phenylisoquinoline)(acetylacetonate)iridium (III) (Ir(piq)₂(acac)), bis[1-(9,9-dimethyl-9H-fluorene-2-yl)-isoquinoline](acetylacetonate)iridium (III) (Ir(fliq)₂(acac)), bis[2-(9,9-dimethyl-9H-fluorene-2-yl)-isoquinoline](acetylacetonate)iridium (III) (Ir(flq)₂(acac)), tris(2-phenylquinoline)iridium (III) (Ir(2-phq)₃), and tris(2-phenylquinoline)(acetylacetonate)iridium (III) (Ir(2-phq)₂(acac)); osmium complexes such as bis(3-trifluoromethyl-5-(2-pyridyl)-pyrazolynate)(dimethylphenylphosphine)osmium (Os(fppz)₂(PPhMe₂)₂) and bis(3-trifluoromethyl)-5-(4-tert-butylpyridyl)-1,2,4-triazonate)(diphenylmethylphosphine)osmium (Os(bpftz)₂(PPh₂Me)₂); and platinum complexes such as 5,10,15,20-tetraphenyltetrabenzoporphyrin platinum.

The hole injection layer and the hole transport layer 13 are disposed between the first electrode 12 and the organic light-emitting layer 14 to further efficiently inject holes from the first electrode 12, which is the anode, and transport (inject) the holes to the organic light-emitting layer 14. The electron injection layer and the electron transport layer 15 are disposed between the second electrode 16 and the organic light-emitting layer 14 to further efficiently inject electrons from the second electrode 16, which is the cathode, and transport (inject) the electrons to the organic light-emitting layer 14.

These hole injection layer, hole transport layer 13, electron injection layer, and electron transport layer 15 may be formed of known materials, be formed of only the materials which will be described below as examples, or optionally contain, for example, additives (e.g., donor and acceptor); furthermore, such materials may be dispersed in a polymeric material (binder resin) or an inorganic material.

Examples of materials used for forming the hole transport layer 13 include oxides such as vanadium oxide (V₂O₅) or molybdenum oxide (MoO₃); inorganic p-type semiconductor materials; low-molecular-weight materials such as porphyrin compounds, aromatic tertiary amine compounds, e.g., N,N′-bis(3-methylphenyl)-N,N′-bis(phenyl)-benzidine (TPD) and N,N′-di(naphthalen-1-yl)-N,N′-diphenyl-benzidine (NPD), hydrazone compounds, quinacridone compounds, and styrylamine compounds; and polymeric materials such as polyaniline (PANI), polyaniline-camphorsulfonic acid (polyaniline-camphorsulfonic acid; PANI-CSA), 3,4-polyethylene dioxythiophene/polystyrene sulfonate (PEDOT/PSS), a poly(triphenylamine) derivative (Poly-TPD), polyvinyl carbazole (PVCz), poly(p-phenylene vinylene) (PPV), and poly(p-naphthalene vinylene) (PNV).

In order to further efficiently inject and transport holes from the first electrode 12 that is the anode, the material used for forming the hole injection layer is preferably a material in which the energy level on the highest occupied molecular orbital (HOMO) is lower than that in a material used for forming the hole transport layer 13, and the material used for forming the hole transport layer 13 is preferably a material having a higher hole mobility than a material used for forming the hole injection layer.

Examples of the material used for forming the hole injection layer include, but are not limited to, phthalocyanine derivatives such as copper phthalocyanine; amine compounds such as 4,4′,4″-tris(3-methylphenylphenylamino)triphenylamine, 4,4′,4″-tris(1-naphthylphenylamino)triphenylamine, 4,4′,4″-tris(2-naphthylphenylamino)triphenylamine, 4,4′,4″-tris[biphenyl-2-yl(phenyl)amino]triphenylamine, 4,4′,4″-tris[biphenyl-3-yl(phenyl)amino]triphenylamine, 4,4,4′″-tris[biphenyl-4-yl(3-methylphenyl)amino]triphenylamine, and 4,4′,4″-tris[9,9-dimethyl-2-fluorenyl(phenyl)amino]triphenylamine; and oxides such as vanadium oxide (V₂O₅) and molybdenum oxide (MoO₃).

The hole injection layer and the hole transport layer 13 are preferably doped with an acceptor to further promote the injection and transport of holes. Known materials used as acceptor materials for organic EL can be employed as the acceptor.

Examples of the acceptor materials include inorganic materials such as Au, Pt, W, Ir, POCl₃, AsF₆, Cl, Br, I, vanadium oxide (V₂O₅), and molybdenum oxide (MoO₃) and organic materials including compounds having a cyano group, such as TCNQ (7,7,8,8,-tetracyanoquinodimethane), TCNQF4 (tetrafluorotetracyanoquinodimethane), TCNE (tetracyanoethylene), HCNB (hexacyanobutadiene), and DDQ (dicyclodicyanobenzoquinone), compounds having a nitro group, such as TNF (trinitrofluorenone) and DNF (dinitrofluorenone), fluoranil, chloranil, and bromanil. Among these, compounds having a cyano group, such as TCNQ, TCNQF4, TCNE, HCNB, DDQ, can effectively enhance the carrier concentration and are therefore preferably employed.

The above-mentioned materials of the hole transport layer 13 and hole injection layer can be also used for forming the electron-blocking layer.

Examples of a material used for forming the electron transport layer 15 include inorganic materials that are n-type semiconductors; low-molecular-weight materials such as oxadiazole derivatives, triazole derivatives, thiopyrazinedioxide derivatives, benzoquinone derivatives, naphthoquinone derivatives, anthraquinone derivatives, diphenoquinone derivatives, fluorenone derivatives, and benzodifuran derivatives; and polymeric materials such as poly(oxadiazole) (Poly-OXZ) and polystyrene derivatives (PSS).

Examples of a material used for forming the electron injection layer particularly include fluorides, such as lithium fluoride (LiF) and barium fluoride (BaF₂), and oxides such as lithium oxide (Li₂O).

In order to further efficiently inject and transport electrons from the second electrode 16 that is the cathode, the material used for forming the electron injection layer is preferably a material in which the energy level on the lowest unoccupied molecular orbital (LUMO) is higher than that in a material used for forming the electron transport layer 15, and the material used for forming the electron transport layer 15 is preferably a material having a higher electron mobility than a material used for forming the electron injection layer.

The electron injection layer and the electron transport layer 15 are preferably doped with a donor to further promote the injection and transport of electrons. Known materials used as donor materials for organic EL can be employed as the donor.

Examples of the donor materials include inorganic materials, such as alkali metals, alkaline earth metals, rare earth elements, Al, Ag, Cu and In, and organic materials including anilines, phenylenediamines, benzidines [e.g., N,N,N′,N′-tetraphenylbenzidine, N,N′-bis-(3-methylphenyl)-N,N′-bis-(phenyl)-benzidine, and N,N′-di(naphthalene-1-yl)-N,N′-diphenyl-benzidine], compounds having an aromatic tertiary amine as a backbone, such as triphenylamines [e.g., triphenylamine, 4,4′,4″-tris(N,N-diphenyl-amino)-triphenylamine, 4,4′,4″-tris(N-3-methyl-phenyl-N-phenyl-amino)-triphenylamine, and 4,4′,4″-tris(N-(1-naphthyl)-N-phenyl-amino)-triphenylamine] and tri-phenyl diamine [e.g., N,N′-di-(4-methyl-phenyl)-N,N′-diphenyl-1,4-phenylenediamine], condensed polycyclic compounds such as phenanthrene, pyrene, perylene, anthracene, tetracene, and pentacene (the condensed polycyclic compound may have a substituent), TTFs (tetrathiafulvalenes), dibenzofuran, phenothiazine, and carbazole.

Among these, compounds having an aromatic tertiary amine as a backbone, condensed polycyclic compounds, and alkali metals can further effectively enhance the carrier concentration and are therefore preferably employed.

The above-mentioned materials of the electron transport layer 15 and electron injection layer can be also used for forming the hole-blocking layer.

The organic light-emitting layer 14, hole transport layer 13, electron transport layer 15, hole injection layer, electron injection layer, hole-blocking layer, electron-blocking layer, and exciton-blocking layer included in the organic EL layer 17 may be formed by, for example, the following process: a known wet process involving use of coating liquids for forming the organic EL layer in which the above-mentioned materials have been dispersed and dissolved in solvents, such as a coating technique, e.g., a spin coating method, a dipping method, a doctor blade method, a discharge coating method, or a spray coating method, or a printing technique, e.g., an ink jet method, a relief printing method, an intaglio printing method, a screen printing method, or a micro gravure coating method; a known dry process involving use of the above-mentioned materials, such as a resistance heating deposition method, an electron beam (EB) deposition method, a molecular beam epitaxy (MBE) method, a sputtering method, or an organic vapor phase deposition (OVPD) method; or a laser transfer process. In the case where the organic EL layer 17 is formed by a wet process, the coating liquids for forming the organic EL layer may contain an additive for adjusting the physical properties of the coating liquids, such as a leveling agent or a viscosity modifier.

The thickness of each layer included in the organic EL layer 17 is normally in the range of approximately 1 nm to 1000 nm, and preferably 10 nm to 200 nm. In the case where the thickness of each layer included in the organic EL layer 17 is less than 10 nm, desired physical properties (injection property, transport property, and confinement property of charges (electrons and holes)) are not obtained in some cases, or a defective pixel due to a foreign substance such as dust may be caused. In the case where the thickness of each layer included in the organic EL layer 17 is greater than 200 nm, the driving voltage may increase, leading to an increase in power consumption.

The first electrode 12 is formed on a substrate (not illustrated), and the second electrode 16 is formed on the organic EL layer (organic layer) 17.

Known electrode materials can be used for forming the first electrode 12 and the second electrode 16. In order to further efficiently inject holes to the organic EL layer 17, examples of the material used for forming the first electrode 12 that is the anode include metals having a work function of not less than 4.5 eV, such as gold (Au), platinum (Pt), and nickel (Ni); an oxide (ITO) containing indium (In) and tin (Sn); an oxide (SnO₂) of tin (Sn); and a compound (IZO) containing indium (In) and zinc (Zn). In order to further efficiently inject electrons to the organic EL layer 17, examples of the electrode material used for forming the second electrode 16 that is the cathode include metals having a work function of not more than 4.5 eV, such as lithium (Li), calcium (Ca), cerium (Ce), barium (Ba), and aluminum (Al), and alloys containing such metals, such as an Mg:Ag alloy and an Li:Al alloy.

The first electrode 12 and the second electrode 16 can be formed of the above-mentioned materials by known techniques such as an EB (electron beam) deposition method, a sputtering method, an ion plating method, and a resistance heating vapor deposition method so as to overlie a substrate; however, the present disclosure is not limited to such techniques. In addition, the formed electrodes can be optionally patterned by photolithography or laser abrasion, and a shadow mask can be also used in combination therewith to directly form patterned electrodes.

The thickness of each of the first electrode 12 and second electrode 16 is preferably 50 nm or more. In the case where the thickness of each of the first electrode 12 and second electrode 16 is less than 50 nm, wiring resistance increases, which may lead to an increase in the driving voltage.

In the organic light-emitting device 10 illustrated in FIG. 1, the above-mentioned transition metal complex of the present disclosure is used in the organic EL layer (organic layer) 17 including the organic light-emitting layer 14. Hence, holes injected from the first electrode 12 are combined with electrons injected from the second electrode 16 to induce phosphorescence emission from the transition metal complex of the present disclosure used as a luminescent material in the organic layer 17 (organic light-emitting layer 14), which enables highly efficient light emission (luminescence). Furthermore, the transition metal complex of the present disclosure is used as a host material in combination with a typical phosphorescent dopant in the organic layer 17 (organic light-emitting layer 14), which enables highly efficient light emission by use of a typical phosphorescent material. Moreover, if the transition metal complex of the present disclosure is used as an exciton-blocking material for the exciton-blocking layer included in the organic EL layer 17, the energy of excitons can be confined in the light-emitting layer. Accordingly, the energy of the excitons can be further effectively utilized for light emission, which enables efficient light emission.

The light-emitting device of the present disclosure may be a bottom-emission-type device in which generated light is emitted to the substrate side or may be a top-emission-type device in which the light is emitted to the side opposite to the substrate side. The organic light-emitting device of the present disclosure may have any driving system and may be an active-driving type or a passive-driving type; however, the organic light-emitting device is preferably an active-driving type. The light emission time is longer in an organic light-emitting device that is an active-driving type than in an organic light-emitting device that is a passive-driving type, which enables a decrease in a driving voltage for obtaining an intended brightness and a decrease in power consumption; hence, the active-driving type is preferably employed.

FIG. 2 is a schematic cross-sectional view of a second embodiment of the organic light-emitting device according to the present disclosure. An organic light-emitting device 20 illustrated in FIG. 2 is a top-emission organic light-emitting device that is an active-driving type, in which the organic light-emitting device 10 (hereinafter also referred to as “organic EL device 10”) having the organic EL layer (organic layer) 17 placed between a pair of the electrodes 12 and 16 is disposed so as to overlie a substrate 1 on which TFT (thin film transistor) circuits 2 have been formed. In FIG. 2, the components the same as those of the organic light-emitting device 10 illustrated in FIG. 1 are denoted by the same reference signs to omit description thereof.

The organic light-emitting device 20 illustrated in FIG. 2 generally includes the substrate 1, the organic EL device 10, an inorganic sealing film 5, a sealing substrate 9, and a sealing member 6. The substrate 1 has the TFT (thin film transistor) circuits 2. The organic EL device 10 is disposed so as to overlie the substrate 1 with an interlayer insulating film 3 and planarization film 4 interposed therebetween. The organic EL device 10 is covered with the inorganic sealing film 5. The sealing substrate 9 is disposed on the inorganic sealing film 5. The sealing member 6 is placed between the substrate 1 and the sealing substrate 9. In the organic EL device 10, as in the first embodiment, the organic EL layer (organic layer) 17 having a multilayer structure including the hole transport layer 13, the light-emitting layer 14, and the electron transport layer 15 is disposed between the first electrodes 12 and the second electrode 16. Reflecting electrodes 11 are placed under the first electrodes 12. Each of the reflecting electrodes 11 and first electrodes 12 is connected to corresponding one of the TFT circuits 2 via wiring 2b formed so as to penetrate through the interlayer insulating film 3 and the planarization film 4. The second electrode 16 is connected to one of the TFT circuits 2 via wiring 2a formed so as to penetrate through the interlayer insulating film 3, the planarization film 4, and an edge cover 19.

On the substrate 1, the TFT circuits 2 and a variety of wiring (not illustrated) are disposed. The interlayer insulating film 3 and the planarization film 4 are placed in sequence so as to cover the upper surface of the substrate 1 and the TFT circuits 2.

Examples of the substrate 1 include insulating substrates such as substrates formed of inorganic materials, e.g., glass and quartz, plastic substrates formed of, e.g., polyethylene terephthalate, polycarbazole, and polyimide, and ceramic substrates formed of, e.g., alumina; metal substrates formed of, e.g., aluminum (Al) and iron (Fe); substrates formed by coating the surfaces of the above-mentioned substrates with insulators formed of, e.g., organic insulating materials such as silicon oxide (SiO₂); and substrates formed by subjecting the surfaces of metal substrates formed of, e.g., Al to an insulating treatment such as anodic oxidation. The present disclosure, however, is not limited thereto.

The TFT circuits 2 are formed on the substrate 1 in advance of production of the organic light-emitting device 20 and serve for switching and driving. The TFT circuits 2 may be known TFT circuits 2. In the present disclosure, a metal-insulator-metal (MIM) diode also can be used for switching and driving in place of TFT.

The TFT circuits 2 can be formed of known materials by known techniques so as to have known structures. Examples of a material used for the active layer of each of the TFT circuits 2 include non-crystalline silicon (amorphous silicon); polycrystalline silicon (polysilicon); inorganic semiconductor materials such as microcrystalline silicon and cadmium selenide; oxide semiconductor materials such as zinc oxide and indium oxide-gallium oxide-zinc oxide; and organic semiconductor materials such as polythiophene derivatives, thiophene olygomers, poly(p-phenylenevinylene) derivatives, naphthacene, and pentacene. Examples of the structure of each of the TFT circuits 2 include a staggered type, an inverted staggered type, a top-gate type, and a coplanar type.

The gate insulator of each of the TFT circuits 2 used in the present disclosure can be formed of known materials. Examples of the gate insulator include SiO₂ formed by plasma enhanced chemical vapor deposition (PECVD) or low pressure chemical vapor deposition (LPCVD) and SiO₂ formed by thermal oxidation of a polysilicon film. The signal electrode wire, scanning electrode wire, common electrode wire, first driving electrode, and second driving electrode of each of the TFT circuits 2 used in the present disclosure can be formed of known materials, and examples thereof include tantalum (Ta), aluminum (Al), and cupper (Cu).

The interlayer insulating film 3 can be formed of known materials, and examples thereof include inorganic materials, such as silicon oxide (SiO₂), silicon nitride (SiN or Si₂N₄), and tantalum oxide (TaO or Ta₂O₅), and organic materials such as acrylic resins and resist materials.

Examples of a technique for forming the interlayer insulating film 3 include dry processes, such as chemical vapor deposition (CVD) and vacuum deposition, and wet processes such as spin coating. The interlayer insulating film 3 can be optionally patterned by, for instance, photolithography.

In the organic light-emitting device 20 of the present disclosure, in order to extract light emitted from the organic EL device 10 from the substrate-9 side, the interlayer insulating film 3 that can block light (light-shielding insulating film) is preferably employed because it can prevent a change in the TFT properties due to external light entering the TFT circuits 2 formed on the substrate 1. Furthermore, in the present disclosure, the interlayer insulating film 3 can be used also in combination with the light-shielding insulating film. The light-shielding insulating film may be formed of, for example, a material in which a pigment or dye, such as phthalocyanine or quinacridone, has been dispersed in a polymeric resin such as polyimide, a color resist, a material used for a black matrix, or an inorganic insulating material such as NiₓZn_{y}Fe₂O₄.

The planarization film 4 is provided to prevent problems in the organic EL device 10 due to the uneven surface profile of each of the TFT circuits 2, such as a defective pixel electrode, a defective organic EL layer, disconnection with a counter electrode, short-circuit between a pixel electrode and a counter electrode, and decreased withstand voltage. The planarization film 4 need not be formed where appropriate.

The planarization film 4 can be formed of known materials, and examples thereof include inorganic materials, such as silicon oxide, silicon nitride, and tantalum oxide, and organic materials such as polyimide, acrylic resins, and resist materials. Examples of a technique for forming the planarization film 4 include dry processes, such as CVD and vacuum deposition, and wet processes such as spin coating; however, the present disclosure is not limited to such materials and techniques. The planarization film 4 may have a monolayer structure or a multilayer structure.

In the organic light-emitting device 20 of the present disclosure, the second electrode 16 is preferably a semitransparent electrode to extract light emitted from the organic light-emitting layer 14 of the organic EL device 10 as a light source from the second-electrode-16 side that is the sealing-substrate-9 side. A metal semitransparent electrode material alone or a combination of a metal semitransparent electrode material and a transparent electrode material can be used as the material of the semitransparent electrode; however, silver or a silver alloy is preferably used in view of reflectance and transmittance.

In the organic light-emitting device 20 of the present disclosure, in order to enhance efficiency at which light emitted from the organic light-emitting layer 14 is extracted, the first electrodes 12 positioned opposite to the side from which light emitted from the organic light-emitting layer 14 is extracted are preferably electrodes that reflect light at high reflectance (reflecting electrodes). Examples of an electrode material used in this case include reflecting metal electrode materials, such as aluminum, silver, gold, an aluminum-lithium alloy, an aluminum-neodymium alloy, and an aluminum-silicon alloy, and a combination of transparent electrode materials and such reflecting metal electrode (reflecting electrode) materials. In FIG. 2, each of the first electrodes 12 as transparent electrodes is disposed so as to overlie the planarization film 4 with the reflecting electrodes 11 interposed therebetween.

In the organic light-emitting device 20 of the present disclosure, the first electrodes 12 are arrayed in parallel on the substrate-1 side (side opposite to the side from which light emitted from the organic light-emitting layer 14 is extracted) so as to correspond to pixel electrodes, and edge covers 19 are formed of an insulating material so as to cover the edges (ends) of the adjoining first electrodes 12. The edge covers 19 are provided to prevent the occurrence of electric leakage between the first electrodes 12 and the second electrode 16. The edge covers 19 can be formed of an insulating material by known techniques such as EB deposition, sputtering, ion plating, and resistance heating deposition and patterned by photolithography based on known dry or wet processes; however, the present disclosure is not limited to such formation techniques. Known materials can be used as the insulating material for forming the edge covers 19, and such materials need to be light-transmitting; examples thereof include, but are not limited to, SiO, SiON, SiN, SiOC, SiC, HfSiON, ZrO, HfO, and LaO.

The thickness of each of the edge covers 19 is preferably in the range of 100 nm to 2000 nm. At a thickness of not less than 100 nm, each of the edge covers 19 can hold enough insulating properties and can prevent an increase in power consumption and defective light emission due to the occurrence of electric leakage between the first electrodes 12 and the second electrode 16. At a thickness of not more than 2000 nm, a reduction in the productivity in the formation process of the edge covers 19 and disconnection with the second electrode 16 in the edge covers 19 can be prevented.

Each of the reflecting electrodes 11 and first electrodes 12 is connected to the corresponding one of the TFT circuits 2 via the wiring 2b formed so as to penetrate through the interlayer insulating film 3 and the planarization film 4. The second electrode 16 is connected to one of the TFT circuits 2 via the wiring 2a formed so as to penetrate thorough the interlayer insulating film 3, the planarization film 4, and an edge cover 19. The wiring 2a and 2b may be formed of a conductive material, and examples thereof include, but are not limited to, Cr, Mo, Ti, Ta, Al, an Al alloy, Cu, and a Cu alloy. The wiring 2a and 2b are formed by known techniques such as sputtering, CVD, and a technique involving use of a mask.

The inorganic sealing film 5 is formed of, for example, SiO, SiON, or SiN so as to cover the upper surface and side surfaces of the organic EL device 10 formed so as to overlie the planarization film 4. In formation of the inorganic sealing film 5, an inorganic film can be formed of, for instance, SiO, SiON, or SiN by, e.g., a plasma CVD method, an ion plating method, an ion beam method, or a sputtering method. The inorganic sealing film 5 needs to be light-transmitting for the extraction of light.

The sealing substrate 9 is placed on the inorganic sealing film 5, and the organic light-emitting device 10 formed between the substrate 1 and the sealing substrate 9 is confined in a sealing region surrounded by the sealing member 6.

The inorganic sealing film 5 and the sealing member 6 can protect the organic EL layer 17 from intrusion of external oxygen and moisture thereinto, which can prolong the lifetime of the light-emitting device 20.

Although the same material as used for the substrate 1 can be used for the sealing substrate 9, a light-transmitting material needs to be used for the sealing substrate 9 because emitted light is extracted from the sealing-substrate-9 side (viewers see display, which is enabled by light emission, from the outside of the sealing substrate 9) in the organic light-emitting device 20 of the present disclosure. In addition, the sealing substrate 9 may have a color filter to enhance color purity.

The sealing member 6 can be formed of known sealing materials, and the sealing member 6 can be formed by known sealing techniques.

The sealing member 6 can be formed of, for example, resin (curable resin). In this case, after the organic EL device 10 and the inorganic sealing film 5 are formed so as to overlie the substrate 1, a curable resin (photocurable resin or thermosetting resin) is applied onto the upper surface and/or side surfaces of the inorganic sealing film 5 or onto the sealing substrate 9 by spin coating or lamination, the substrate 1 is attached to the sealing substrate 9 with the resin layer interposed therebetween, and the product is subjected to photo-curing or thermal curing to form the sealing member 6. The sealing member 6 needs to be light-transmitting.

Inert gas such as nitrogen gas or argon gas may be used to serve as the sealing member 6; for example, inert gas such as nitrogen gas or argon gas is confined by the sealing substrate 9 formed of, e.g., glass.

In this case, in order to effectively reduce effects of moisture on the organic EL, for instance, a moisture absorbent such as barium oxide is preferably mixed with the inert gas to be confined.

In the organic light-emitting device 20 of the present disclosure, as in the organic light-emitting device 10, the organic EL layer (organic layer) 17 contains the transition metal complex of the present disclosure. Hence, holes injected from the first electrodes 12 are combined with electrons injected from the second electrode 16 to induce phosphorescence emission from the transition metal complex of the present disclosure used as a luminescent material in the organic layer 17 (organic light-emitting layer 14), which enables highly efficient light emission (luminescence). Furthermore, the transition metal complex of the present disclosure is used as a host material in combination with a typical phosphorescent dopant in the organic layer 17 (organic light-emitting layer 14), which enables highly efficient light emission by use of a typical phosphorescent material. Moreover, if the transition metal complex of the present disclosure is used as an exciton-blocking material for the exciton-blocking layer included in the organic EL layer 17, the energy of excitons can be confined in the light-emitting layer. Accordingly, the energy of the excitons can be further effectively utilized for light emission, which enables efficient light emission.

<Color Conversion Light-Emitting Device>

The color conversion light-emitting device of the present disclosure includes a light-emitting device and fluorescent layers which are disposed on the side from which light emitted from the light-emitting device is extracted and which absorb light emitted from the light-emitting device to emit light having a color different from that of the absorbed light.

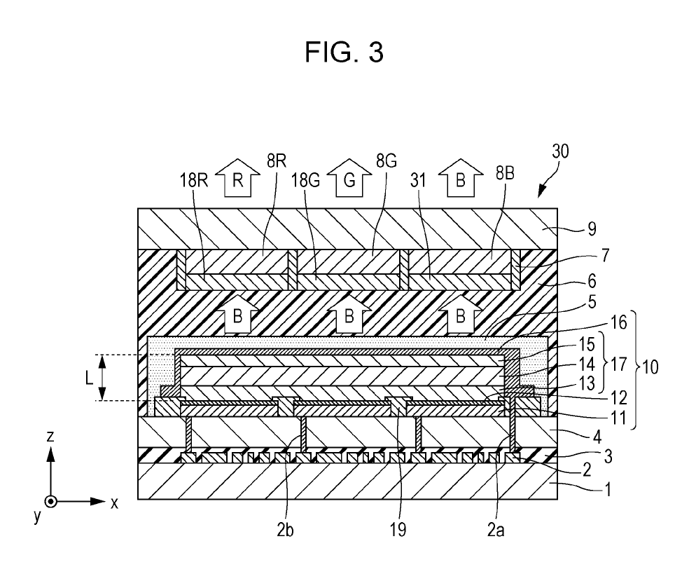

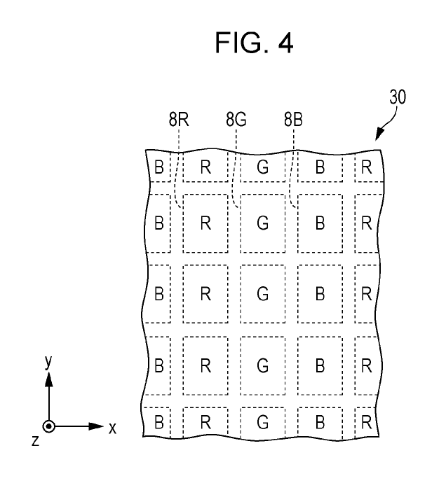

FIG. 3 is a schematic cross-sectional view illustrating an embodiment of the color conversion light-emitting device according to the present disclosure, and FIG. 4 is a top view illustrating the organic light-emitting device illustrated in FIG. 3. A light conversion light-emitting device 30 illustrated in FIG. 3 includes red fluorescent layers 18R which absorb blue light emitted from the above-mentioned organic light-emitting device 10 of the present disclosure to convert the color of the light into red and green fluorescent layers 18G which absorb the emitted blue light to convert the color of the light into green. The red fluorescent layers 18R and the green fluorescent layers 18G are hereinafter also collectively referred to as “fluorescent layers”.

In the color conversion light-emitting device 30 illustrated in FIG. 3, the components the same as those of the above-mentioned organic light-emitting devices 10 and 20 of the present disclosure are denoted by the same reference signs to omit description thereof.

The color conversion light-emitting device 30 illustrated in FIG. 3 generally includes the substrate 1, the organic light-emitting device (light source) 10, the sealing substrate 9, red color filters 8R, green color filters 8G, blue color filters 8B, the red fluorescent layers 18R, the green fluorescent layers 18G, and scattering layers 31. The substrate 1 has TFT (thin film transistor) circuits 2. The organic light-emitting device (light source) 10 is disposed so as to overlie the substrate 1 with the interlayer insulating film 3 and planarization film 4 interposed therebetween. The red color filters 8R, the green color filters 8G, and the blue color filters 8B are arrayed in parallel on one side of the sealing substrate 9 so as to be defined by a black matrix 7. The red fluorescent layers 18R are disposed on the red color filters 8R formed on one side of the sealing substrate 9 such that the positions of the red fluorescent layers 18R correspond to the positions of the red color filters 8R. The green fluorescent layers 18G are disposed on the green color filters 8R formed on one side of the sealing substrate 9 such that the positions of the green fluorescent layers 18G correspond to the positions of the green color filters 8R. The scattering layers 31 are disposed on the blue color filters 8B formed on the sealing substrate 9 such that the positions of the scattering layers 31 correspond to the positions of the blue color filters 8B. The substrate 1 and the sealing substrate 9 are placed such that the organic light-emitting device 10 face the fluorescent layers 18R and 18G and the scattering layers 31 with the sealing member interposed therebetween. The fluorescent layers 18R and 18G and the scattering layers 31 are separated from each other by the black matrix 7.

The organic EL light-emitting portion 10 is covered with the inorganic sealing film 5. In the organic EL light-emitting portion 10, the organic EL layer (organic layer) 17 having a multilayer structure including the hole transport layer 13, the organic light-emitting layer 14, and the electron transport layer 15 is disposed between the first electrodes 12 and the second electrode 16. The reflecting electrodes 11 are disposed on the lower surfaces of the first electrodes 12. Each of the reflecting electrodes 11 and first electrodes 12 is connected to the corresponding one of the TFT circuits 2 via the wiring 2b formed so as to penetrate through the interlayer insulating film 3 and the planarization film 4. The second electrode 16 is connected to one of the TFT circuits 2 via the wiring 2a formed so as to penetrate thorough the interlayer insulating film 3, the planarization film 4, and an edge cover 19.

In the color conversion light-emitting device 30 of the present disclosure, light emitted from the organic light-emitting device 10 as the light source enters the fluorescent layers 18R and 18G and the scattering layers 31, the light which has entered the scattering layers 31 is transmitted without being converted, and the light which has entered the fluorescent layers 18R and 18G is converted, so that light beams of three colors of red, green, and blue are emitted to the sealing-substrate-9 side (viewer side).

In FIG. 3 illustrating the color conversion light-emitting device 30 of the present disclosure, one red fluorescent layer 18R and one red color filter 8R, one green fluorescent layer 18G and one green color filter 8G, and one scattering layer 31 and one blue color filter 8B are arranged for simple illustration that is easy to be understood. As illustrated in the top view of FIG. 4, however, the color filters 8R, 8G, and 8B depicted by dashed lines are two-dimensionally placed in the form of a stripe; in particular, the color filters 8R, 8G, and 8B are arrayed in sequence in parallel with the X axis so as to form lines extending in parallel with the Y axis in a striped pattern.

Although the RGB pixels (color filters 8R, 8G, and 8B) are arrayed in the form of a stripe in FIG. 4, the present disclosure is not limited thereto; the RGB pixels can be placed in known RGB pixel array, such as in the form of mosaic or delta.

The red fluorescent layers 18R absorb light which has been emitted from the organic light-emitting device 10 as a light source and which is in a blue wavelength region, convert such light into light which is in a red wavelength region, and then emit the light, which is in a red wavelength region, to the sealing-substrate-9 side.

The green fluorescent layers 18G absorb light which has been emitted from the organic light-emitting device 10 as a light source and which is in a blue wavelength region, convert such light into light which is in a green wavelength region, and then emit the light, which is in a green wavelength region, to the sealing-substrate-9 side.

The scattering layers 31 are disposed for the purpose of enhancing the viewing angle properties of light which has been emitted from the organic light-emitting device 10 as a light source and which is in a blue wavelength region and increasing the efficiency at which the light is extracted and emit the light, which is in a blue wavelength region, to the sealing-substrate-9 side. The scattering layers 31 need not be formed where appropriate.

In such a configuration including the red fluorescent layers 18R and the green fluorescent layers 18G (and scattering layers 31), light emitted from the organic light-emitting device 10 is converted into light beams of three colors of red, green, and blue and then emitted from the sealing-substrate-9 side, thereby enabling full-color display.

The color filters 8R, 8G, and 8B are disposed between the sealing substrate 9, which is on the side from which light is extracted (viewer side), and the fluorescent layers 18R and 18G and scattering layers 31 to enhance the color purity of red, green, and blue light emitted from the color conversion light-emitted device 30 and to expand a color reproduction range by the color conversion light-emitted device 30. Since the red color filters 8R formed on the red fluorescent layers 18R and the green color filters 8G formed on the green fluorescent layers 18G absorb the blue components and ultraviolet components of external light, light emission from the fluorescent layers 8R and 8G due to external light can be reduced or prevented, which leads to suppressing or preventing a reduction in contrast.

The color filters 8R, 8G, and 8B are not specifically limited, and known color filters can be used. The color filters 8R, 8G, and 8B can be formed by known techniques, and the thickness thereof can be properly adjusted.

In the scattering layers 31, transparent particles have been dispersed in a binder resin. The thickness of each of the scattering layers 31 is normally in the range of 10 μm to 100 μm, and preferably 20 μm to 50 μm.

The binder resin used for the scattering layers 31 may be known materials without limitation and is preferably light-transmitting. The transparent particles are not specifically limited provided that the transparent particles can scatter and transmit light emitted from the organic light-emitting device 10; for example, polystyrene particles each having an average particle size of 25 μm and a standard deviation of particle size distribution of 1 μm can be used. The transparent particle content in the scattering layers 31 can be appropriately adjusted without limitation.

The scattering layers 31 can be formed by known techniques without limitation; for instance, a coating liquid in which the binder resin and the transparent particles have been dissolved or dispersed in a solvent is used to carry out known wet processes based on a coating technique, such as a spin coating method, a dipping method, a doctor blade method, a discharge coating method, or a spray coating method, or a printing technique, such as an ink jet method, a relief printing method, an intaglio printing method, a screen printing method, or a micro gravure coating method.

Each of the red fluorescent layers 18R contains a fluorescent material which can absorb light to enter an excited state and which then can emit fluorescence that is in a red wavelength region, the light being emitted from the organic light-emitting device 10 and in a blue wavelength region.

Each of the green fluorescent layers 18G contains a fluorescent material which can absorb light to enter an excited state and which then can emit fluorescence that is in a green wavelength region, the light being emitted from the organic light-emitting device 10 and in a blue wavelength region.

The red fluorescent layers 18R and the green fluorescent layers 18G may contain fluorescent materials which will be described below alone, optionally contain, for example, additives, or have a structure in which such materials have been dispersed in a polymeric material (binder resin) or an inorganic material.

Known fluorescent materials can be used for forming the red fluorescent layers 18R and the green fluorescent layers 18G. Such materials are classified into organic fluorescent materials and inorganic fluorescent materials. Specific compounds will now be described as examples of such fluorescent materials; however, the present disclosure is not limited to such materials.

Organic fluorescent materials will be described first. Examples of the fluorescent materials used for forming the red fluorescent layers 18R include fluorescent dyes that enable conversion of ultraviolet or blue excitation light into red light, such as cyanine dyes, e.g., 4-dicyanomethylene-2-methyl-6-(p-dimethylaminostyryl)-4H-pyran; pyridine dyes, e.g., 1-ethyl-2-[4-(p-dimethylaminophenyl)-1,3-butadienyl]-pyridium-perchlorate; and rhodamine dyes, e.g., rhodamine B, rhodamine 6G, rhodamine 3B, rhodamine 101, rhodamine 110, basic violet 11, and sulforhodamine 101.

Examples of fluorescent materials used for forming the green fluorescent layers 18G include fluorescent dyes that enable conversion of ultraviolet or blue excitation light into green light, such as coumarin dyes, e.g., 2,3,5,6-1H,4H-tetrahydro-8-trifluoromethy quinolizidine (9,9a, 1-gh) coumarin (coumarin 153), 3-(2′-benzothiazolyl)-7-diethylaminocoumarin (coumarin 6), and 3-(2′-benzoimidazolyl)-7-N,N-diethylaminocoumarin (coumarin 7), and naphthalimido dyes, e.g., basic yellow 51, solvent yellow 11, and solvent yellow 116.

Examples of inorganic fluorescent materials will now be described. Examples of the fluorescent materials used for forming the red fluorescent layers 18R include fluorescent substances that enable conversion of ultraviolet or blue excitation light into green light, such as (BaMg)Al₁₆O₂₇:Eu²⁺, Mn²⁺, Sr₄Al₁₄O₂₅:Eu²⁺, (SrBa) Al₁₂Si₂O₈:Eu²⁺, (BaMg)₂SiO₄:Eu²⁺, Y₂SiO₅:Ce³⁺, Tb³⁺, Sr₂P₂O₇—Sr₂B₂O₅:Eu²⁺, (BaCaMg)₅(PO₄)Cl:Ey²⁺, Sr₂Si₃O₈-2SrCl₂:Eu²⁺, Zr₂SiO₄, MgAl₁₁O₁₉:Ce³⁺, Tb³⁺, Ba₂SiO₄:Eu²⁺, Sr₂SiO₄:Eu²⁺, and (BaSr)SiO₄:Eu²⁺.

Examples of fluorescent materials used for forming the green fluorescent layers 18G include fluorescent substances that enable conversion of ultraviolet or blue excitation light into red light, such as Y₂O₂S:Eu³⁺, YAlO₃:Eu³⁺, Ca₂Y₂(SiO₄)₆:Eu³⁺, LiY₉(SiO₄)₆O₂:Eu³⁺, YVO₄:Eu³⁺, CaS:Eu³⁺, Gd₂O₃:Eu³⁺, Gd₂O₂S:Eu³⁺, Y(P,V)O₄:Eu³⁺, Mg₄GeO_{5.5}F:Mn⁴⁺, Mg₄GeO⁶:Mn⁴⁺, K₃Eu_{2.5} (WO₄)_{6.25}, Na₅Eu_{2.5} (WO₄)_{6.25}, K₃Eu_{2.5}(MoO₄)_{6.25}, and Na₅Eu_{2.5} (MoO₄)_{6.25}.

In the color conversion light-emitting device 30 of the present disclosure, blue fluorescent layers may be provided instead of the scattering layers 31; the blue fluorescent layers absorb light belonging to an ultraviolet wavelength region in light emitted from the organic light-emitting device 10 that is a light source, convert such light into light which is in a blue wavelength region, and then emit the light, which is in a blue wavelength region, to the sealing-substrate-9 side.

In this case, examples of organic fluorescent materials used for forming the blue fluorescent layers include fluorescent dyes which enable conversion of ultraviolet excitation light into blue light, such as styrlbenzene dyes, e.g., 1,4-bis(2-methylstyryl)benzene and trans-4,4′-diphenyl styrlbenzene, and coumarin dyes, e.g., 7-hydroxy-4-methylcoumarin. Examples of inorganic fluorescent materials include fluorescent substances which enable conversion of ultraviolet excitation light into blue light, such as Sr₂P₂O₇:Sn⁴⁺, Sr₄Al₁₄O₂₅:Eu²⁺, BaMgAl₁₀O₁₇:Eu²⁺, SrGa₂S₄:Ce³⁺, CaGa₂S₄:Ce³⁺, (Ba, Sr) (Mg, Mn)Al₁₀O₁₇:Eu²⁺, (Sr, Ca, Ba₂, Mg)₁₀(PO₄)₆Cl₂:Eu²⁺, BaAl₂SiO₈:Eu²⁺, Sr₂P₂O₇:Eu²⁺, Sr₅(PO₄)₃Cl:Eu²⁺, (Sr,Ca,Ba)₅(PO₄)₃Cl:Eu²⁺, BaMg₂Al₁₆O₂₇:Eu²⁺, (Ba,Ca)₅(PO₄)₃Cl:Eu²⁺, Ba₃MgSi₂O₈:Eu²⁺, and Sr₃MgSi₂O₈:Eu²⁺.

The above-mentioned inorganic fluorescent materials are preferably optionally subjected to a surface modification treatment, and examples of the surface modification treatment include a chemical treatment with a silane coupling agent or another material, a physical treatment by addition of fine submicron particles or another material, and a combination thereof. In view of degradation or another effect due to excitation light and emitted light, inorganic fluorescent materials are preferably employed for the stability thereof. In the case where the inorganic fluorescent materials are used, the average particle size (d50) thereof is preferably in the range of 0.5 μm to 50 μm.

In the case where each of the red fluorescent layers 18R and green fluorescent layers 18G has a structure in which the above-mentioned fluorescent material has been dispersed in a polymeric material (binder resin), use of a photosensitive resin as the polymeric material enables patterning by photolithography. Usable photosensitive resin is one selected from photosensitive resins (photocurable resist materials) having reactive vinyl groups, such as an acrylic resin, a methacrylic resin, a polyvinyl cinnamate resin, and a hard rubber resin, and mixtures of such photosensitive resins.

Each of the red fluorescent layers 18R and green fluorescent layers 18G can be formed of a coating liquid used for forming a fluorescent layer by known wet processes, dry processes, laser transfer techniques, or other techniques; in the coating liquid used for forming a fluorescent layer, the above-mentioned fluorescent material (dye) and a resin material have been dissolved or dispersed in a solvent. Examples of known wet processes include coating techniques, such as a spin coating method, a dipping method, a doctor blade method, a discharge coating method, and a spray coating method, and printing techniques, such as an ink jet method, a relief printing method, an intaglio printing method, a screen printing method, and a micro gravure coating method. Examples of known dry processes include a resistance heating deposition method, an electron beam (EB) deposition method, a molecular beam epitaxy (MBE) method, a sputtering method, and an organic vapor phase deposition (OVPD) method.

The thickness of each of the red fluorescent layers 18R and green fluorescent layers 18G is normally in the range of approximately 100 nm to 100 μm, and preferably 1 μm to 100 μm. If the thickness of each of the red fluorescent layers 18R and green fluorescent layers 18G is less than 100 nm, the blue light emitted from the organic light-emitting device 10 is less likely to be sufficiently absorbed; thus, the luminous efficiency in the light conversion light-emitting device 30 is impaired, and light converted by each of the fluorescent layers 18R and 18G is mixed with blue transmitted light with the result that the color impurity is impaired. In order to enhance the absorption of blue light emitted from the organic light-emitting device 10 and reduce the blue transmitted light to an extent that enables avoiding the impairment of the color purity, the thickness of each of the fluorescent layers 18R and 18G is preferably not less than 1 μm. Even if the thickness of each of the red fluorescent layers 18R and green fluorescent layers 18G is greater than 100 μm, the blue light emitted from the organic light-emitting device 10 has been sufficiently absorbed, and such a thickness therefore does not lead to an increase in luminous efficiency in the light conversion light-emitting device 30. Hence, the thickness of each of the red fluorescent layers 18R and green fluorescent layers 18G is preferably not more than 100 μm because material costs can be reduced.

The inorganic sealing film 5 is disposed so as to cover the upper surface and side surfaces of the organic light-emitting device 10. The sealing substrate 9 in which the red fluorescent layers 18R, green fluorescent layers 18G, scattering layers 31, and color filters 8R, 8G, and 8B have been arrayed in parallel on or above one surface thereof and defined by the black matrix 7 is disposed above the inorganic sealing film 5 such that the fluorescent layers 18R and 18G and the scattering layers 31 face the organic light-emitting device, and the sealing member 6 is placed between the inorganic sealing film 5 and the sealing substrate 9. In other words, each of the fluorescent layers 18R and 18G and scattering layers 31, which are disposed so as to face the organic light-emitting device 10, are surrounded by the black matrix 7 so as to be separated from each other and, in addition, confined in the sealing region surrounded by the sealing member 6.

In the case where the sealing member 6 is formed of a resin (curable resin), a curable resin (photocurable resin or thermosetting resin) is applied to the substrate 1 having the organic light-emitting device 10 and the inorganic sealing film 5 so as to cover the inorganic sealing film 5 or to the sealing substrate 9 having the fluorescent layers 18R and 18G, the scattering layers 31, and the color filters 8R, 8G, and 8B so as to cover the fluorescent layers 18R and 18G and the scattering layers 31 by spin coating or lamination, the substrate 1 is attached to the sealing substrate 9 with the resin layer interposed therebetween, and the product is subjected to photo-curing or thermal curing to form the sealing member 6.

The side of each of the fluorescent layers 18R and 18G and scattering layers 31, which is opposite to the sealing substrate 9, is preferably flattened by, for example, a planarization film (not illustrated). Such a structure can prevent generation of a gap between the organic light-emitting layer 10 and each of the fluorescent layers 18R and 18G and scattering layers 31 in an attachment process in which the organic light-emitting layer 10 is placed so as to face the fluorescent layers 18R and 18G and the scattering layer 31 with the sealing member 6 interposed therebetween and also enables the substrate 1 having the organic light-emitting device 10 to be further tightly attached to the sealing substrate 9 having the fluorescent layers 18R and 18G, the scattering layers 31, and the color filters 8R, 8G, and 8B. The planarization film may be the same as the planarization film 4 described above.

The black matrix 7 can be formed of known materials by known techniques without limitation. In particular, the black matrix 7 is preferably formed of a material which can reflect light, which has entered the fluorescent layers 18R and 18G and then been scattered, to the fluorescent layers 18R and 18G, such as metal having light reflectivity.

The organic light-emitting device 10 preferably has a top-emission structure that enables light to sufficiently reach the fluorescent layers 18R and 18B and the scattering layers 31. In such a structure, it is preferred that the first electrodes 12 and the second electrode 16 be configured as reflecting electrodes and that the optical distance L between the electrodes 12 and 16 be adjusted to enable formation of a microresonator structure (microcavity structure). In this case, it is preferred that the first electrodes 12 be reflecting electrodes and that the second electrode 16 be a semitransparent electrode.

A metal semitransparent electrode material alone or a combination of a metal semitransparent electrode material and a transparent electrode material can be used as the material of the semitransparent electrode. In particular, silver or a silver alloy is preferably used as the semitransparent electrode material in view of reflectance and transmittance.

The thickness of the second electrode 16 that is the semitransparent electrode is preferably in the range of 5 nm to 30 nm. If the thickness of the semitransparent electrode is less than 5 nm, light is not sufficiently reflected, and effects of light interference may be therefore insufficient. If the thickness of the semitransparent electrode is greater than 30 nm, the light transmittance is greatly reduced, which may lead to a reduction in brightness and efficiency.

An electrode which can reflect light at high reflectance can be used as each first electrode 12 that is a reflecting electrode. Examples of the reflecting electrode include reflecting metal electrodes formed of aluminum, silver, gold, an aluminum-lithium alloy, an aluminum-neodymium alloy, and an aluminum-silicon alloy. The reflecting electrode may be a combination of a transparent electrode and such a reflecting metal electrode. In FIG. 3, each first electrode 12 that is a transparent electrode is formed so as to overlie the planarization film 4 with the reflecting electrode 11 interposed therebetween.

In the microresonator structure (microcavity structure) constituted by the first electrodes 12 and the second electrode 16, the interference effect brought about by the first electrodes 12 and the second electrode 16 enables light emitted from the organic EL layer 17 to focus in the front direction (direction in which light is extracted: sealing-substrate-9 side). In other words, since the light emitted from the organic EL layer 17 can have directivity, the loss of emitted light which is scatter of the emitted light can be reduced, which leads to an enhancement in the luminous efficiency thereof. Hence, luminescence energy generated in the organic light-emitting device 10 can be further efficiently transmitted to the fluorescent layers 18R and 18B, and the brightness on the front side of the color conversion light-emitting device 30 can be enhanced.

The microresonator structure enables adjustment of the emission spectrum of the organic EL layer 17, and the emission spectrum can be adjusted to have an intended emission peak wavelength and half width. Hence, the emission spectrum of the organic EL layer 17 can be adjusted to be a spectrum which enables effective excitation of the fluorescent materials in the fluorescent layers 18R and 18B.

Employing a semitransparent electrode as the second electrode 16 enables reuse of light emitted in the direction opposite to the direction in which light is to be extracted in the fluorescent layers 18R and 18B and the scattering layers 31.

In the fluorescent layers 18R and 18G, the optical distance between the luminous point of converted light and the surface from which the light is extracted varies on the basis of the color of the light-emitting device. In the light conversion light-emitting device 30 of the present disclosure, the above-mentioned “luminous point” is the surface of each the fluorescent layers 18R and 18G which faces the organic light-emitting device 10.

In each of the fluorescent layers 18R and 18G, the optical distance between the luminous point of converted light and the surface from which the light is extracted can be adjusted by changing the thickness of each of the fluorescent layers 18R and 18G. The thickness of each of the fluorescent layers 18R and 18G can be adjusted by changing the printing conditions of screen printing (attack pressure of squeegee, squeegee attack angle, squeegee speed, and clearance width), the details of a screen printing plate (type of screen gauze, thickness of emulsion, tension, and strength of frame), and the details of a coating liquid used for forming a fluorescent layer (viscosity, fluidity, and a blend ratio of resin, dye, and solvent).

In the color conversion light-emitting device 30 of the present disclosure, light emitted from the organic light-emitting device 10 is amplified by a microresonator structure (microcavity structure), and the efficiency at which light converted by the fluorescent layers 18R and 18B is extracted can be enhanced by adjusting the above-mentioned optical distance (adjusting the thickness of each of the fluorescent layers 18R and 18B). Accordingly, the luminous efficiency in the color conversion light-emitting device 30 can be further enhanced.

The color conversion light-emitting device 30 of the present disclosure has a structure in which light emitted from the organic light-emitting device 10 in which the transition metal complex of the present disclosure is used is converted by the fluorescent layers 18R and 18B and therefore enables light emission at high efficiency.

Although the color conversion light-emitting device of the present disclosure has been described, the color conversion light-emitting device of the present disclosure is not limited to the above-mentioned embodiment. It is also preferred, for instance, that a polarizing plate be disposed on the side from which light is extracted (on the sealing substrate 9) in the color conversion light-emitting device 30 of the above-mentioned embodiment. A usable polarizing plate is a combination of a known linear polarizing plate and a known λ/4 plate. The polarizing plate contributes to preventing reflection of external light by the first electrodes 12 and the second electrode 16 and reflection of external light by the surface of the substrate 1 or sealing substrate 9, which enables an enhancement in the contrast of the color conversion light-emitting device 30.

Although the organic light-emitting device 10 in which the transition metal complex of the present disclosure is used is employed as a light source (light-emitting device) in the above-mentioned embodiment, the present disclosure is not limited thereto. A light source such as an organic EL in which another luminescent material is used, an inorganic EL, or an LED (light-emitting diode) can be used as the light-emitting device, and a layer containing the transition metal complex of the present disclosure can be disposed as a fluorescent layer which absorbs light emitted from such a light-emitting device (light source) to emit blue light. In this case, the light-emitting device as the light source preferably emits light having a wavelength shorter than that of blue light (ultraviolet light).

Although light beams of three colors of red, green, and blue are emitted in the color conversion light-emitting device 30 of the above-mentioned embodiment, the color conversion light-emitting device of the present disclosure is not limited thereto. The light conversion light-emitting device may be a single-colored light-emitting device having only one fluorescent layer or may include devices of multiple primary colors of, for example, white, yellow, magenta, and cyan in addition to light-emitting devices of red, green, and blue. In such a case, the fluorescent layers for individual colors may be used. Such a structure enables a reduction in power consumption and expansion of a color reproduction range. Furthermore, the fluorescent layers for multiple primary colors can be more easily formed by photolithography involving use of a resist, printing, or a wet process than by a technique in which a material is applied to a predetermined portion with a mask.

<Light Conversion Light-Emitting Device>

The light conversion light-emitting device of the present disclosure includes an organic layer having a mono- or multilayer structure including a light-emitting layer containing the transition metal complex of the present disclosure, and a layer which amplifies electric current, a pair of electrodes between which the organic layers and the layer which amplifies electric current are disposed.

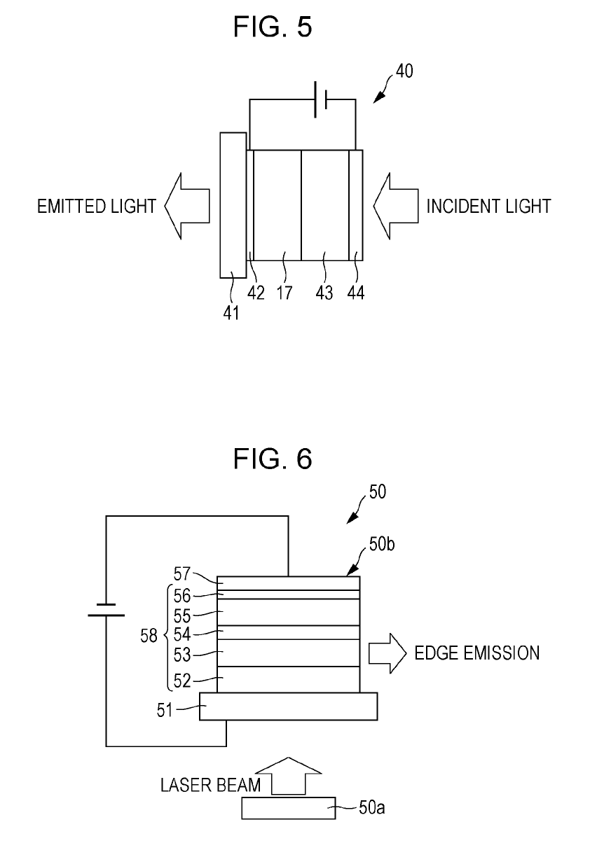

FIG. 5 is a schematic diagram illustrating an embodiment of the light conversion light-emitting device according to the present disclosure. A light conversion light-emitting device 40 illustrated in FIG. 5 utilizes photoelectric conversion brought about by a photocurrent multiplication effect to convert generated electrons into light again on the basis of the mechanism of EL emission.

The light conversion light-emitting device 40 illustrated in FIG. 5 includes a lower electrode 42, such as an ITO electrode, formed on one side of a device substrate 41 that is a transparent glass substrate and the organic EL layer 17, organic photoelectric material layer 43, and Au electrode 44 formed on the lower electrode 42 in sequence, the lower electrode 42 is connected to the positive electrode of a driving power source, and the Au electrode 44 is connected to the negative electrode of the driving power source.

The structure of the organic EL layer 17 may be the same as the structure of the above-mentioned organic EL layer 17 specified in the organic light-emitting device of the present disclosure.

The organic photoelectric material layer 43 has a photoelectric effect which amplifies electric current and may have a monolayer structure consisting of an NTCDA (naphthalenetetracarboxylic acid) layer alone or a multilayer structure that allows the range of sensitive wavelength to be selected. The organic photoelectric material layer 43 may have, for example, two-layer structure including an Me-PTC (perylene pigment) layer and an NTCDA layer. The organic photoelectric material layer 43 may have any thickness; for instance, the thickness is approximately in the range of 10 nm to 100 nm, and the organic photoelectric material layer 43 can be formed by vacuum deposition.

In the light conversion light-emitting device 40 of the present disclosure, a predetermined voltage is applied between the lower electrode 42 and the Au electrode 44, light is emitted from the outside of the Au electrode 44, and then holes generated by this emission of light are trapped in the vicinity of the Au electrode 44 as the negative electrode and accumulated. Then, an electric field is concentrated at the interface between the organic photoelectric material layer 43 and the Au electrode 44, and electrons are injected from the Au electrode 44 with the result that electric current is multiplied. The electric current amplified in this manner serves to light emission in the organic EL layer 17; hence good light emission properties can be provided.

In the light conversion light-emitting device 40 of the present disclosure, the organic EL layer 17 contains the above-mentioned transition metal complex of the present disclosure, which can further improve luminous efficiency.

<Organic Laser Diode Light-Emitting Device>

The organic laser diode light-emitting device of the present disclosure includes a continuous wave excitation light source and a resonator structure which is irradiated with light emitted from the continuous wave excitation light source. In the resonator structure, an organic layer having a mono- or multilayer structure including a light-emitting layer is disposed between a pair of electrodes.

FIG. 6 is a schematic diagram illustrating an embodiment of the organic laser diode light-emitting device according to the present disclosure. An organic laser diode light-emitting device 50 illustrated in FIG. 6 includes a continuous wave excitation light source 50a that emits a laser beam and a resonator structure 50b formed on an ITO substrate 51 and having a multilayer structure including a hole transport layer 52, laser active layer 53, hole-blocking layer 54, electron transport layer 55, electron injection layer 56, and electrode 57 formed in sequence. An ITO electrode formed in the ITO substrate 51 is connected to the positive electrode of a driving power source, and the electrode 57 is connected to the negative electrode of the driving power source.

The hole transport layer 52, the hole-blocking layer 54, the electron transport layer 55, and the electron injection layer 56 have the same structures as the above-mentioned hole transport layer 13, hole-blocking layer, electron transport layer 15, and electron injection layer in the organic light-emitting device of the present disclosure, respectively. The laser active layer 53 can have the same structure as the above-mentioned organic light-emitting layer 14 of the organic light-emitting device of the present disclosure; it is preferred that a typical host material be doped with a luminescent material that is the transition metal complex of the present disclosure or that a host material that is the transition metal complex of the present disclosure is doped with a typical luminescent dopant material. In FIG. 6, an organic EL layer 58 has a multilayer structure including the hole transport layer 52, laser active layer 53, hole-blocking layer 54, electron transport layer 55, and electron injection layer 56 formed in sequence; however, the organic laser diode light-emitting device 50 of the present disclosure is not limited thereto and may have the same structure as the above-mentioned organic light-emitting layer 14 of the organic light-emitting device of the present disclosure.

In the organic laser diode light-emitting device 50 of the present disclosure, since a laser beam is emitted from the continuous wave excitation light source 50a on the ITO-substrate-51 side, namely, the anode side, light is emitted from the side surface of the resonator structure 50b by ASE oscillation (edge light emission) in which peak brightness is enhanced on the basis of the excitation intensity of the laser beam.

<Dye Laser>

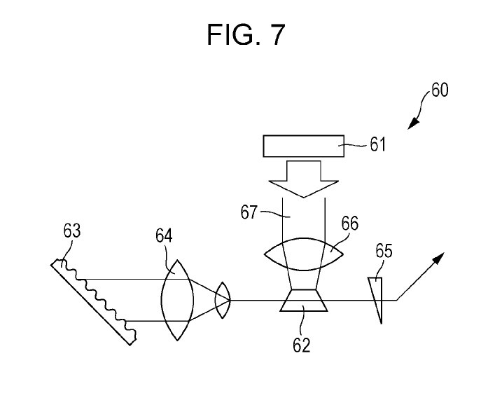

FIG. 7 is a schematic diagram illustrating an embodiment of the dye laser according to the present disclosure. A dye laser 60 illustrated in FIG. 7 generally includes a light source for excitation 61, a dye cell 62, a lens 66, a partial reflecting mirror 65, a diffraction grating 63, and a beam expander 64. The light source for excitation 61 emits a pump beam 67. The lens 66 serves to focus the pump beam 67 on the dye cell 62. The partial reflecting mirror 65 is disposed so as to face the beam expander 64 with the dye cell 62 interposed therebetween. The beam expander 64 is disposed between the diffraction grating 63 and the dye cell 62. The beam expander 64 serves to focus light emitted from the diffraction grating 63. The dye cell 62 is formed of, for example, quartz glass. The dye cell 62 is filled with a laser medium that is a liquid containing the transition metal complex of the present disclosure.

In the dye laser 60 of the present disclosure, the pump beam 67 is emitted from the light source for excitation 61, the lens 66 focuses the pump beam 67 on the dye cell 62, the transition metal complex of the present disclosure contained in the laser medium in the dye cell 62 is excited, and then light is emitted. The light emitted from the luminescent material is released to the outside of the dye cell 62 and then reflected and amplified between the partial reflecting mirror 62 and the diffraction grating 63.

The amplified light passes through the partial reflecting mirror 65 and then is emitted to the outside. The transition metal complex of the present disclosure can be applied also to the dye laser in this manner.

The above-mentioned organic light-emitting device, color conversion light-emitting device, and light conversion light-emitting device of the present disclosure can be applied to a display system and lighting system.

<Display System>

The display system of the present disclosure includes an image signal output unit, a driver, and a light-emitting unit. The image signal output unit generates an image signal. The driver generates electric current or voltage on the basis of the signal generated in the image signal output unit. The light-emitting unit emits light owing to the electric current or voltage generated in the driver. In the display system of the present disclosure, the light-emitting unit is any of the above-mentioned organic light-emitting device, color conversion light-emitting device, and light conversion light-emitting device of the present disclosure. The case in which the light-emitting unit is the organic light-emitting device of the present disclosure will now be described; however, the present disclosure is not limited thereto, and the light-emitting unit of the display system of the present disclosure may be the color conversion light-emitting device or the light conversion light-emitting device.

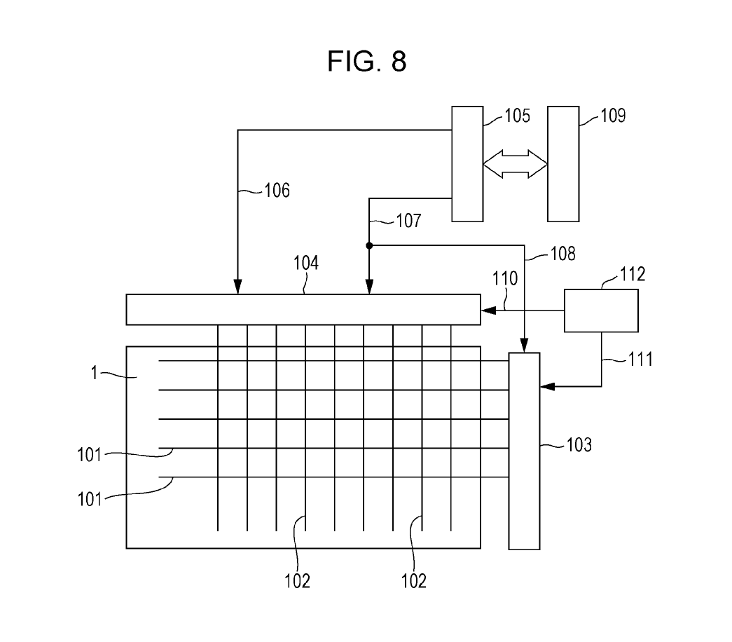

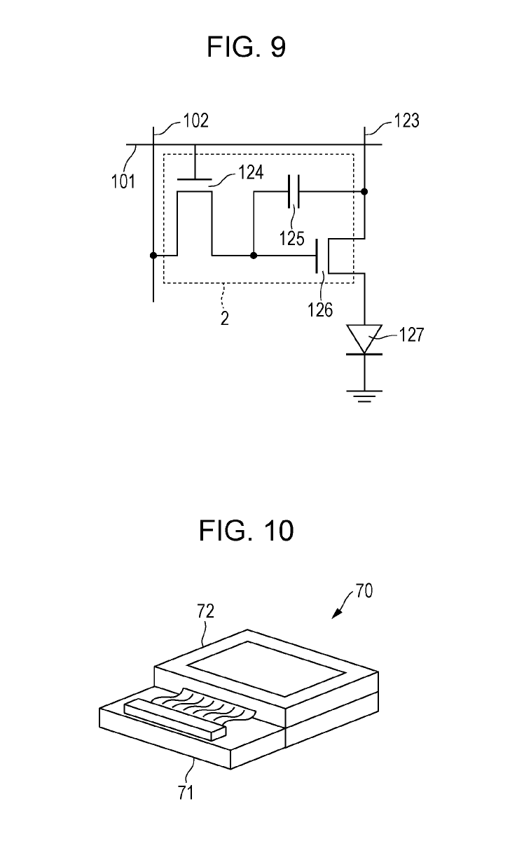

FIG. 8 is a block diagram illustrating an example of connection of wiring to a driving circuit in the display system including the organic light-emitting device 20 of the second embodiment and the driver. FIG. 9 is a pixel circuit diagram illustrating a circuit included in a pixel disposed in the display system including the organic light-emitting device of the present disclosure.

With reference to FIG. 8, in the display system of the present disclosure, scanning lines 101 and signal lines 102 are provided for the substrate 1 of the organic light-emitting device 20 in the form of a matrix in plan view. Each scanning line 101 is connected to a scanning circuit 103 disposed at an end of the substrate 1. Each signal line 102 is connected to a video signal driving circuit 104 disposed at another end of the substrate 1. In particular, driving devices such as the thin film transistors of the organic light-emitting diodes 20 illustrated in FIG. 2 (TFT circuits 2) are disposed in the vicinity of the intersections of scanning lines 101 and the signal lines 102, and the driving devices are connected to corresponding pixel electrodes. Such pixel electrodes correspond to the reflecting electrodes 11 of the organic light-emitting device 20 illustrated in FIG. 2. The reflecting electrodes 11 are associated with the first electrodes 12.

The scanning circuit 103 and the video signal driving circuit 104 are electrically connected to a controller 105 via controlling wires 106, 107, and 108. The operation of the controller 105 is controlled by a central processing unit 109. The scanning circuit 103 and the video signal driving circuit 104 are further connected to a power supply circuit 112 via power linens 111 and 110, respectively. The image signal output unit is composed of the CPU 109 and the controller 105.

The driver which drives the organic EL device 10 (organic EL light-emitting portion) of the organic light-emitting device 20 is composed of the scanning circuit 103, the video signal driving circuit 104, and the organic EL power supply circuit 112. The TFT circuits 2 of the organic light-emitting device 20 illustrated in FIG. 2 are disposed in regions defined by the scanning lines 101 and the signal lines 102.

FIG. 9 illustrates the pixel circuit of one of the pixels included in the organic light-emitting device 20 and positioned in the regions defined by the scanning lines 101 and the signal lines 102. In the pixel circuit illustrated in FIG. 9, a scanning signal applied to the scanning line 101 is applied to the gate electrode of a switching TFT 124 as a thin film transistor to turn on the switching TFT 124. Then, a pixel signal applied to the signal line 102 is applied to the source electrode of the switching TFT 124 and then passes through the TFT 124, which has been in an on-state, to charge a storage capacitor 125 connected to the drain electrode thereof. The storage capacitor 125 is connected to the source electrode and gate electrode of a driving TFT 126. Hence, until the next scan in which the switching TFT 124 is selected, the gate voltage of the driving TFT 126 is retained at a level determined by the voltage of a storage capacitor 125. A power line 123 is connected to the power supply circuit (FIG. 8), and an electric current supplied therefrom passes to an organic light-emitting device (organic EL device) 127 through the driving TFT 126 to let the device 127 continuously emit light.

Owing to the image signal output unit and driving unit having such structures, application of voltage to the organic EL layer (organic layer) 17 disposed between the first electrode 12 and the second electrode 16 in a predetermined pixel allows the organic light-emitting device 20 corresponding to the pixel to emit light, so that visible light can be emitted from the pixel to display intended colors and images.

Although the display system of the present disclosure includes the organic light-emitting device 20 as the light-emitting unit, the present disclosure is not limited thereto. Any of the above-mentioned organic light-emitting device, color conversion light-emitting device, and light conversion light-emitting device of the present disclosure can be suitably used as the light-emitting unit.

The display system of the present disclosure includes the light-emitting unit that is any of the organic light-emitting device, color conversion light-emitting device, and light conversion light-emitting device in which the transition metal complex of the present disclosure is used, which enables the display system to have high luminous efficiency.

<Lighting System>

FIG. 10 is a schematic perspective view illustrating a first embodiment of the lighting system according to the present disclosure. Lighting system 70 illustrated in FIG. 10 includes a driver 71 which generates an electric current or voltage and a light-emitting unit 72 that emits light owing to the electric current or voltage generated by the driver 71. In the lighting system of the present disclosure, the light-emitting unit 72 is any of the above-mentioned organic light-emitting device, color conversion light-emitting device, and light conversion light-emitting device of the present disclosure. The case in which the light-emitting unit is the organic light-emitting device 10 of the present disclosure will now be described; however, the present disclosure is not limited thereto, and the light-emitting unit of the display system of the present disclosure may be the color conversion light-emitting device or the light conversion light-emitting device.

The lighting system 70 illustrated in FIG. 10 has pixels each including the first electrode 12, the second electrode 16, and the organic EL layer (organic layer) 17 disposed between the first electrode 12 and the second electrode 16. In the lighting system 70, voltage generated by the driver is applied to the organic EL layer (organic layer) 17 to allow the organic light-emitting device 10 corresponding to any of the pixels to emit light for light emission.

In the display system 70 in which the organic light-emitting device of the present disclosure is used as the light-emitting unit 72 thereof, the organic light-emitting layer of the organic light-emitting device may contain known organic EL luminescent materials in addition to the transition metal complex of the present disclosure.

Although the lighting system of the present disclosure includes the organic light-emitting device 10 as the light-emitting unit, the present disclosure is not limited thereto, and the lighting system can suitably include the light-emitting unit that is any of the above-mentioned organic light-emitting device, color conversion light-emitting device, and light conversion light-emitting device of the present disclosure.

The lighting system of the present disclosure includes the light-emitting unit that is any of the organic light-emitting device, color conversion light-emitting device, and light conversion light-emitting device in which the transition metal complex of the present disclosure is used, which enables the lighting system to have high luminous efficiency.

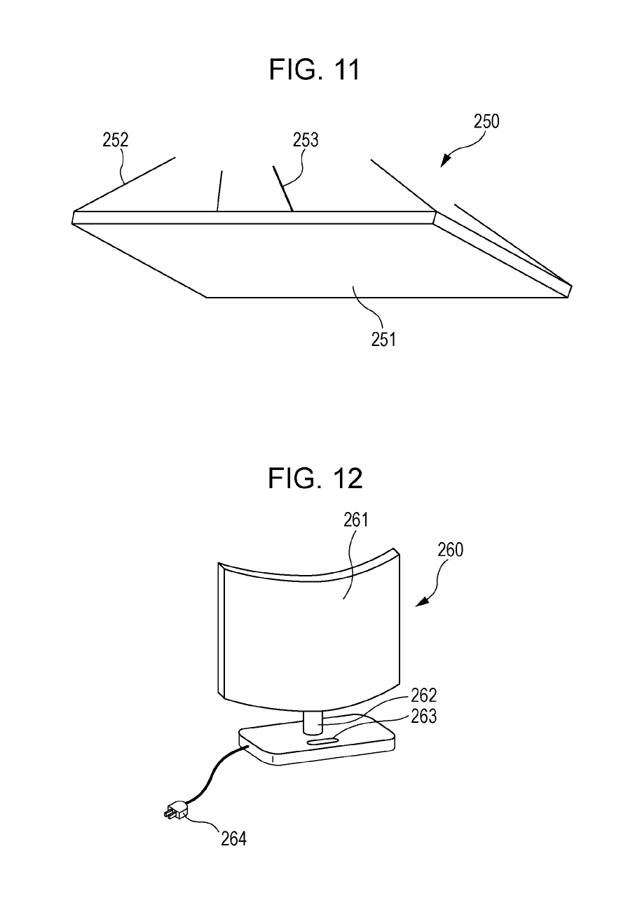

The organic light-emitting device, color conversion light-emitting device, and light conversion light-emitting device of the present disclosure can be applied to, for example, a ceiling light (lighting system) illustrated in FIG. 11.

A ceiling light 250 illustrated in FIG. 11 includes a light-emitting unit 251, suspending wires 252, and a power source cord 253. Any of the organic light-emitting device, color conversion light-emitting device, and light conversion light-emitting device of the present disclosure can be suitably used as the light-emitting unit 251.

The lighting system of the present disclosure includes the light-emitting unit that is any of the organic light-emitting device, color conversion light-emitting device, and light conversion light-emitting device in which the transition metal complex of the present disclosure is used, which enables the lighting system to have high luminous efficiency. The organic light-emitting device, color conversion light-emitting device, and light conversion light-emitting device of the present disclosure can be also similarly applied to, for example, a light stand (lighting system) illustrated in FIG. 12.

A light stand 260 illustrated in FIG. 12 includes a light-emitting unit 261, a stand 262, a main switch 263, and a power source cord 264. Any of the organic light-emitting device, color conversion light-emitting device, and light conversion light-emitting device of the present disclosure can be suitably used as the light-emitting unit 261.

The lighting system of the present disclosure also includes the light-emitting unit that is any of the organic light-emitting device, color conversion light-emitting device, and light conversion light-emitting device in which the transition metal complex of the present disclosure is used, which enables the lighting system to have high luminous efficiency.

<Electronic Equipment>

The above-mentioned display system of the present disclosure can be used in a variety of electronic equipment.

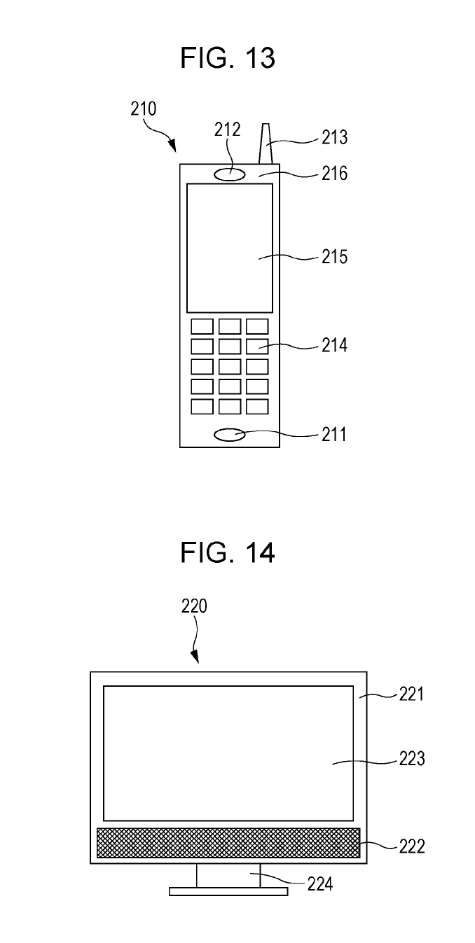

Electronic equipment including the display system of the present disclosure will now be described with reference to FIGS. 13 to 16.

The above-mentioned display system of the present disclosure can be applied to, for instance, a mobile phone illustrated in FIG. 13. A mobile phone 210 illustrated in FIG. 13 includes a voice input unit 211, a voice output unit 212, an antenna 213, operation switches 214, a display 215, and a case 216. The display system of the present disclosure can be suitably applied to the display 215.

Application of the display system of the present disclosure to the display 215 of the mobile phone 210 enables pictures to be displayed at high luminous efficiency.

The above-mentioned display system of the present disclosure can be also applied to a thin television set illustrated in FIG. 14. A thin television set 220 illustrated in FIG. 14 includes a display 221, a speaker 222, a cabinet 223, and a stand 224. The display system of the present disclosure can be suitably applied to the display 221. Application of the display system of the present disclosure to the display 221 of the thin television set 220 enables pictures to be displayed at high luminous efficiency.

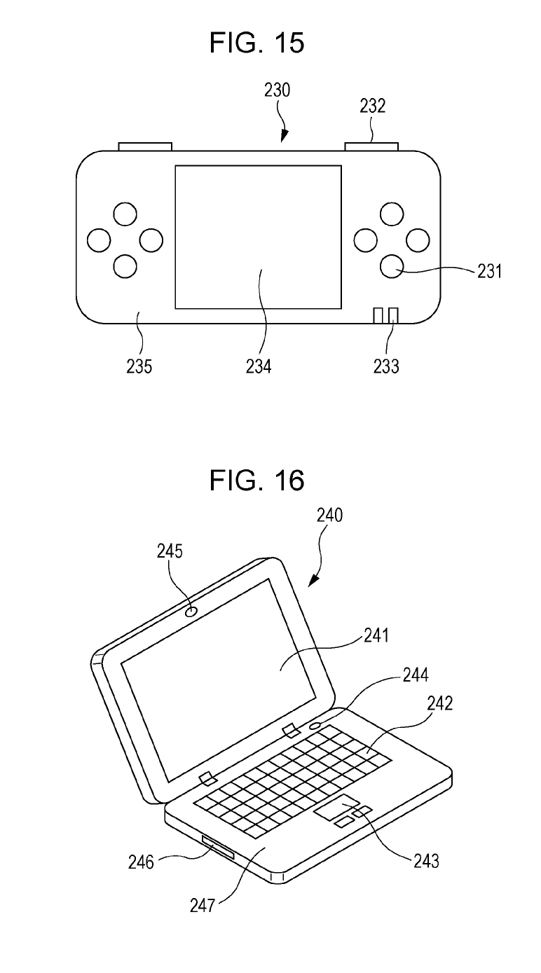

The above-mentioned display system of the present disclosure can be also applied to a portable game machine illustrated in FIG. 15. A portable game machine 230 illustrated in FIG. 15 includes operation buttons 231 and 232, an external connection terminal 233, a display 234, and a case 235. The display system of the present disclosure can be suitably applied to the display 234. Application of the display system of the present disclosure to the display 234 of the portable game machine 230 enables pictures to be displayed at high luminous efficiency.

The above-mentioned display system of the present disclosure can be also applied to a laptop illustrated in FIG. 16. A laptop 240 illustrated in FIG. 16 includes a display 241, a keyboard 242, a touch pad 243, a main switch 244, a camera 245, a memory medium slot 246, and a case 247. The display system of the present disclosure can be suitably applied to the display 241 of the laptop 240. Application of the display system of the present disclosure to the display 241 of the laptop 240 enables pictures to be displayed at high luminous efficiency.

Although preferred embodiments of the present disclosure have been described with referent to the accompanying drawings, it is obvious that the present disclosure is not limited to such embodiments. The shapes and combinations of the elements explained in the above-mentioned embodiments are merely examples and can be variously modified without departing from the scope of the present disclosure on the basis of, for example, requirements of design.

In the display system described in the above-mentioned embodiment, for example, a polarizing plate is preferably disposed on the side from which light is extracted. A usable polarizing plate is a combination of a known linear polarizing plate and a known λ/4 late. The polarizing plate contributes to preventing reflection of external light by the electrodes of the display system and reflection of external light by the surface of the substrate or sealing substrate, which enables an enhancement in the contrast of the display system. Moreover, the details of the shape, number, arrangement, material, and formation method of the components of the fluorescent substrate, display system, and lighting system are not limited to the above-mentioned embodiments and can be appropriately changed.

### EXAMPLES

Although aspects of the present invention will now be described further in detail with reference to Examples, the aspects of the present invention are not limited thereto.

Compounds used in Examples and Comparative Examples were as follows. In the following structural formulae, Me represents a methyl group, Et represents an ethyl group, and i-Pr represents an isopropyl group.

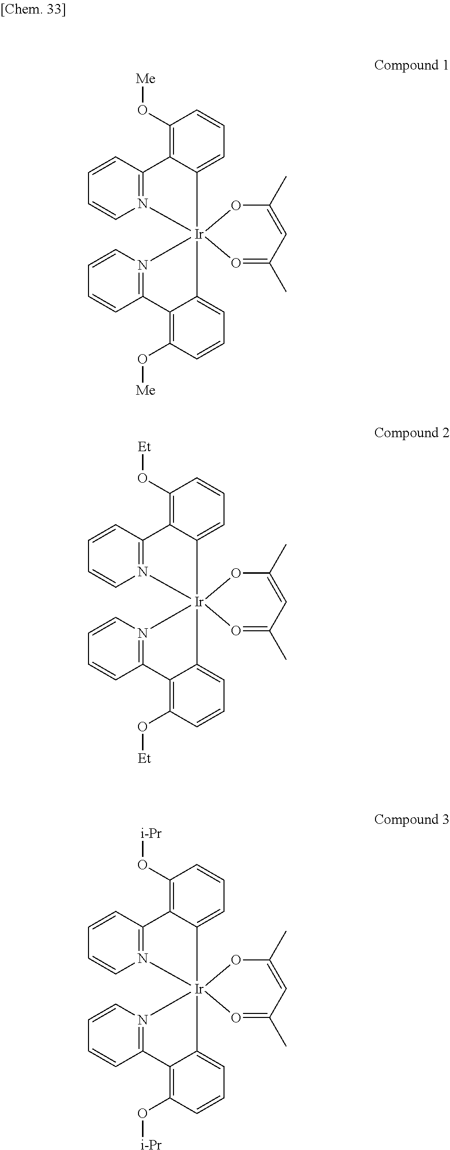

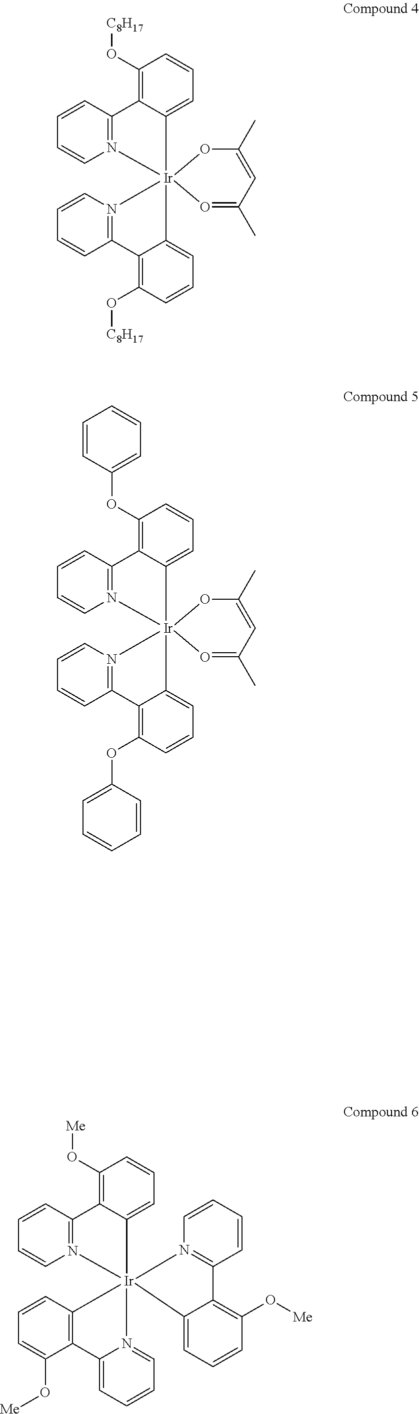

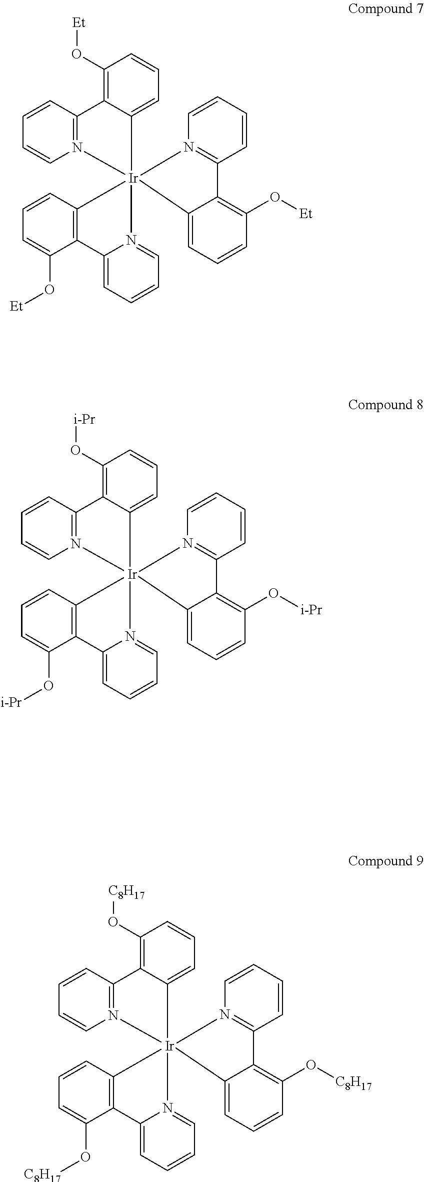

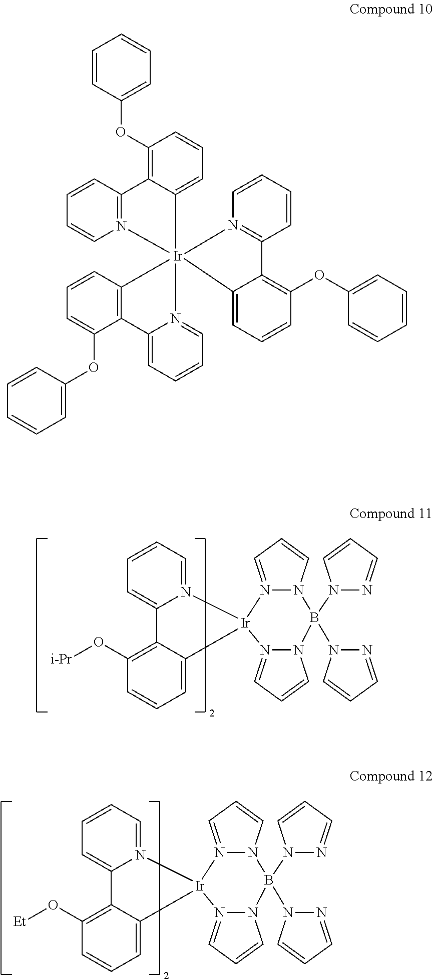

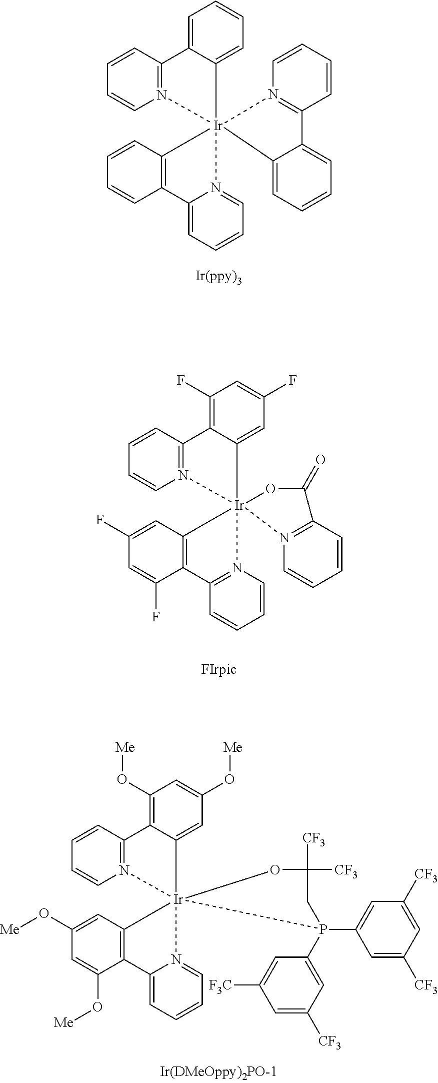

[Synthesis of Ligand]

In the following synthesis, a compound and ligand in each step was identified with reference to ¹H-NMR and MS spectra (FAB-MS).

### Synthetic Example 1

### Synthesis of Ligand 1

A ligand 1 was synthesized through the following route.

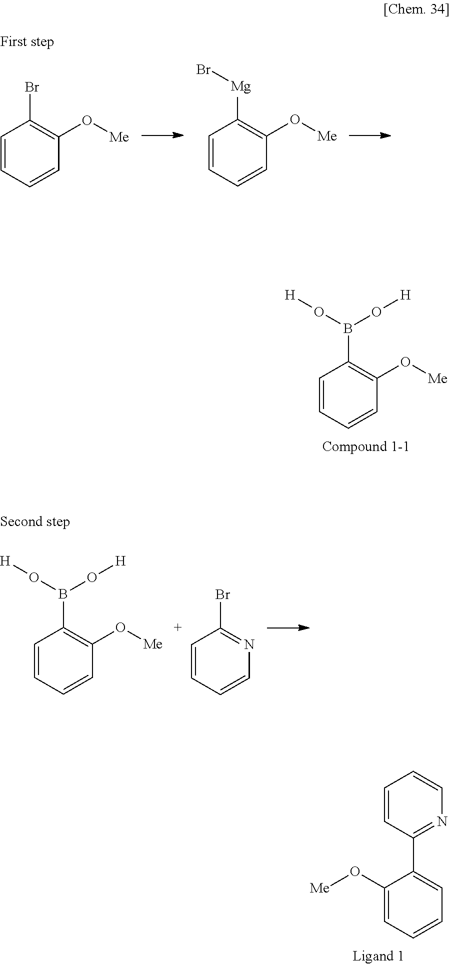

First Step:

Into a 500 mL three-necked flask, 2 g of 1-bromo-2-methoxybenzene, 10.1 g of magnesium, a slight amount of iodine, and THF (in an amount that enabled the magnesium to be covered) were put, the content was heated with a heat gun to induce a reaction, and a solution in which 73 g of 1-bromo-2-methoxybenzene had been dissolved in 200 ml of THF (tetrahydrofuran) was dropped at approximately 60° C. into the reaction solution after the termination of the initial reaction. After the dropping was finished, the reaction solution was stirred at approximately 65° C. for 50 minutes and then cooled to approximately 10° C.

Then, 83 g of trimethyl borate was dissolved in 150 mL of THF in another container, the solution was cooled to −9° C., and this solution was dropped at −9 to 0° C. into the cooled reaction solution. After the dropping was finished, the product was stirred for approximately an hour at 0° C. Then, 60 g of ammonium chloride was dissolved in 300 mL of water in another container and then cooled to approximately 0° C., and this solution was dropped into the reaction solution. After the dropping was finished, the product was stirred for two hours at room temperature. Then, the insoluble matter in the reaction solution was separated by filtration, the separated insoluble matter was washed with THF, and the filtrate and the washing liquid were mixed with each other and concentrated under reduced pressure. To the residue after the concentration, 200 mL of water was subsequently added for crystallization, and the crystal was collected by filtration and then washed with water. The wet crystal was dried under reduced pressure to produce 54.5 g of a compound 1-1. The yield was 89.5%.

Second Step:

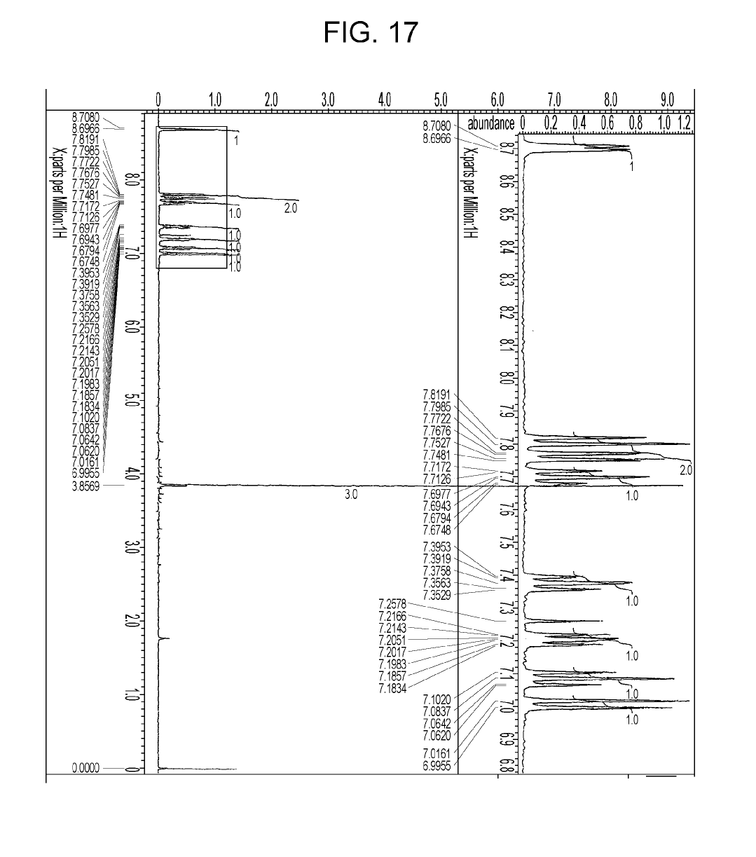

Into a 1000 mL three-necked flask, 40.0 g of the compound 1-1, 43.7 g of 2-bromopyridine, 400 mL of ethane dichloride, 200 mL of methanol, 72 g of potassium carbonate, 200 mL of water, and 4 g of a catalyst (bis(triphenylphosphine)palladium (II) chloride) were put, the content was heated for approximately 3 hours under reflux, a small amount of an insoluble matter in the reaction solution was subsequently separated by filtration, and the filtrate was subjected to separation. Then, the separated ethane dichloride layer was washed three times with 300 mL of water, the ethane dichloride layer was subsequently extracted with a solution in which 25.2 g of 35% hydrochloric acid had been dissolved in 200 mL of water, and the aqueous hydrochloric acid layer after the extraction was washed with 50 mL of ethane dichloride. Then, 40.0 g of 25% sodium hydroxide solution was added to the aqueous hydrochloric acid layer to adjust the pH to be alkaline, extraction with 100 mL of methylene chloride was carried out three times, and the methylene chloride layer was subsequently washed with 50 mL of a salt solution. The methylene chloride layer was dehydrated with magnesium sulfate, the magnesium sulfate was collected by filtration, and the filtrate was concentrated under reduced pressure to produce 42.7 g of the residue. The residue was subsequently distilled under reduced pressure to obtain 37.2 g of a main fraction, thereby yielding a ligand 1. The boiling point thereof was 120 to 122° C./300 Pa vacuum, and the yield was 87.3%. FAB-MS(+): m/z=185.0841 (100%) and 186.0874 (13.0%). FIG. 17 is a ¹H-NMR chart of the ligand 1. ¹H-NMR (400 MHz, deuterated chloroform (CDCl₃)): δ (ppm)=8.70 (1H, d), 7.80 (1H, d), 7.76 (1H, dd), 7.69 (1H, td), 7.38 (1H, td), 7.20 (1H, td), 7.08 (1H, t), 7.00 (1H, d), and 3.86 (3H, s).

### Synthetic Example 2

### Synthesis of Ligand 2

A ligand 2 was synthesized through the following route.

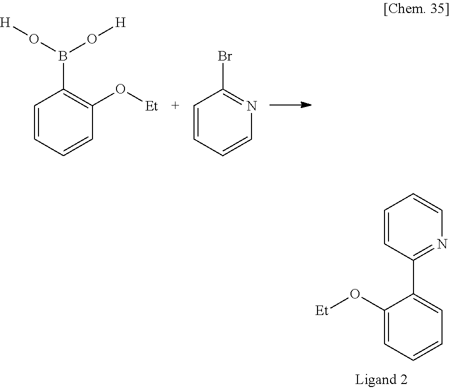

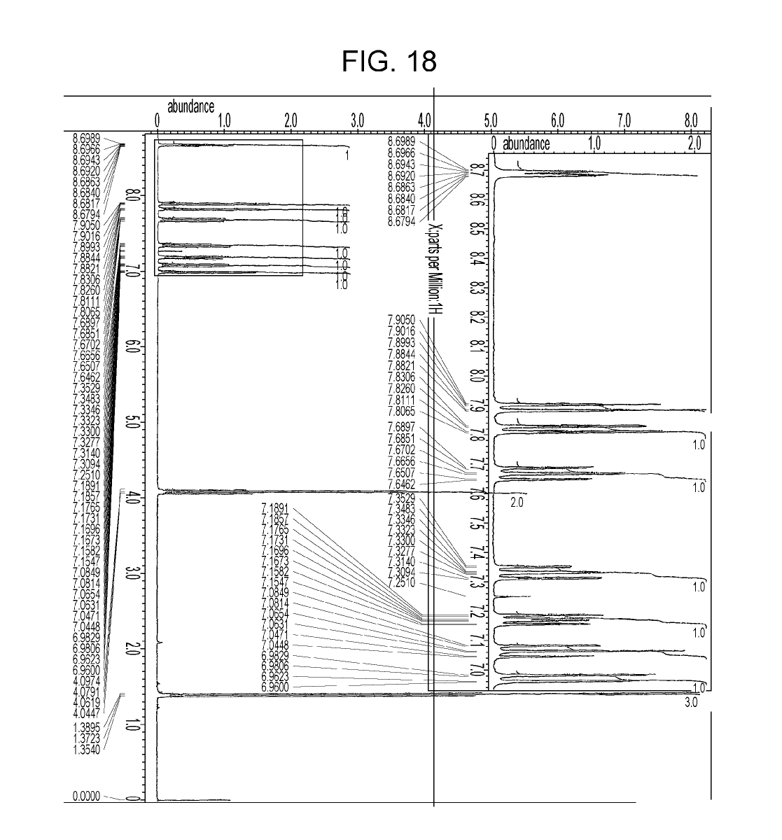

Into a 500 mL three-necked flask, 35.0 g of 2-ethoxyphenylboronic acid, 34.8 g of 2-bromopyridine, 350 mL of ethane dichloride, 180 mL of methanol, 58 g of potassium carbonate, 180 mL of water, and 4 g of a catalyst (bis(triphenylphosphine)palladium (II) chloride) were put, the content was heated for approximately 6.5 hours under reflux, a small amount of an insoluble matter in the reaction solution was separated by filtration, and the filtrate was subjected to separation. Then, the separated ethane dichloride layer was washed twice with 200 mL of water, the ethane dichloride layer was subsequently extracted with a solution in which 24.2 g of 35% hydrochloric acid had been dissolved in 200 mL of water, and the aqueous hydrochloric acid layer after the extraction was washed once with 20 mL of ethane dichloride. Then, 38.4 g of 25% sodium hydroxide solution was added to the aqueous hydrochloric acid layer to adjust the pH to be alkaline, the product was subjected to extraction three times with 100 mL of methylene chloride, and the methylene chloride layer was subsequently washed with 50 mL of a salt solution. The methylene chloride layer was dehydrated with magnesium sulfate, the magnesium sulfate was subsequently collected by filtration, and the filtrate was concentrated under reduced pressure to produce 38.3 g of the residue. The residue was distilled under reduced pressure to obtain 35.8 g of a main fraction, thereby yielding a ligand 2. The boiling point thereof was 115 to 116° C./200 Pa vacuum, and the yield was 81.4%. FAB-MS(+): m/z=199.0997 (100%) and 200.1031 (14.1%). FIG. 18 is a ¹H-NMR chart of the ligand 2. ¹H-NMR (400 MHz, deuterated chloroform (CDCl₃)): δ (ppm)=8.68 (1H, ddd), 7.90 (1H, dd), 7.81 (1H, dd), 7.67 (1H, td), 7.33 (1H, td), 7.17 (1H, td), 7.06 (1H, td), 6.97 (1H, dd), 4.07, (2H, q), and 1.37 (3H, t).

### Synthetic Example 3

### Synthesis of Ligand 3

A ligand 3 was synthesized through the following route.

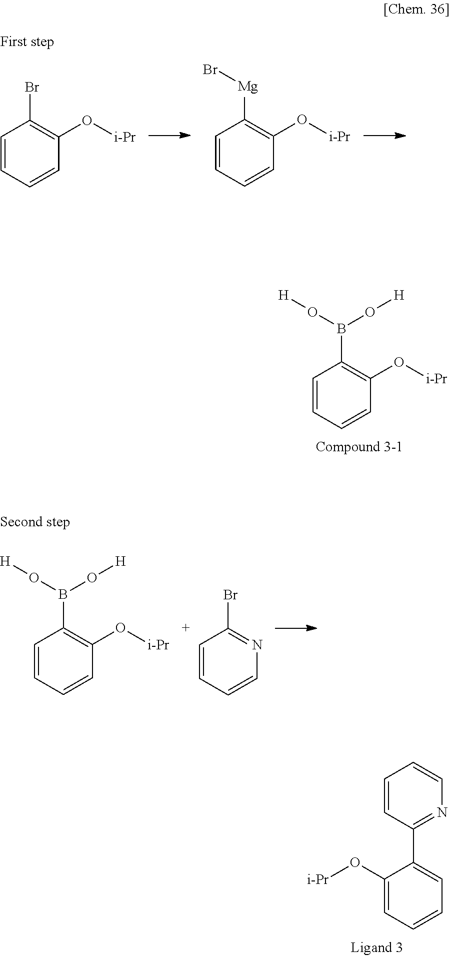

First Step:

Into a 500 mL three-necked flask, 2 g of 1-bromo-2-isopropoxybenzene, 6.1 g of magnesium, a slight amount of iodine, and THF (in an amount that enabled the magnesium to be covered) were put, the content was heated with a heat gun to induce a reaction, and a solution in which 48 g of 1-bromo-2-isopropoxybenzene had been dissolved in 150 ml of THF was dropped at approximately 60° C. into the reaction solution after the termination of the initial reaction. After the dropping was finished, the reaction solution was stirred at approximately 65° C. for 60 minutes and then cooled to approximately 2° C.

Then, 48.2 g of trimethyl borate was dissolved in 150 mL of THF in another container, the solution was cooled to −9° C., and this solution was dropped at −8 to −1° C. into the cooled reaction solution. After the dropping was finished, the product was stirred for approximately an hour at 0° C. Then, 50 g of ammonium chloride was dissolved in 300 mL of water in another container, the solution was cooled to approximately 0° C., and this solution was dropped into the reaction solution. After the dropping was finished, the product was stirred for two hours at room temperature. Then, the insoluble matter in the reaction solution was collected by filtration, the collected insoluble matter was washed with THF, and the filtrate and the washing liquid were mixed with each other and concentrated under reduced pressure. Then, 200 mL of water was added to the residue after the concentration, extraction with 100 mL of ethane dichloride was carried out twice, and then the ethane dichloride layer was washed with 100 mL of saturated salt solution. The ethane dichloride layer was concentrated under reduced pressure to produce 37.7 g of a compound 3-1. The yield was 90.4%.

Second Step:

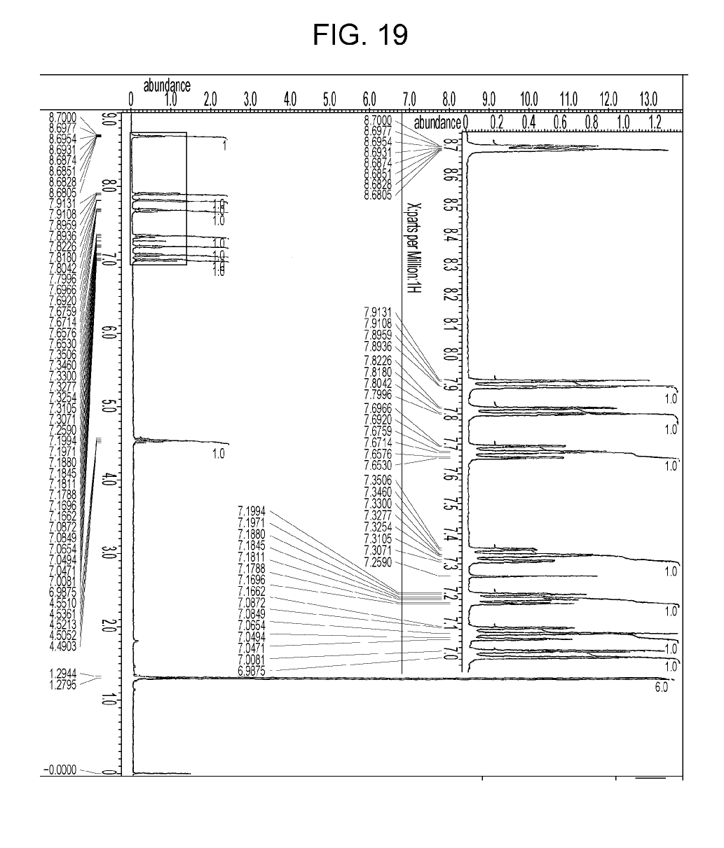

Into a 1000 mL three-necked flask, 36.4 g of the compound 3-1, 28.8 g of 2-bromopyridine, 350 mL of ethane dichloride, 180 mL of methanol, 57 g of potassium carbonate, 180 mL of water, and 4 g of a catalyst (bis(triphenylphosphine)palladium (II) chloride) were put, the content was heated for approximately 3 hours under reflux, a small amount of an insoluble matter in the reaction solution was separated by filtration, and the filtrate was subjected to separation. Then, the separated ethane dichloride layer was washed three times with 300 mL of water, the ethane dichloride layer was subsequently extracted with a solution in which 25.2 g of 35% hydrochloric acid had been dissolved in 200 mL of water, and then, the ethane dichloride layer was further extracted with a solution in which 3.8 g of 35% hydrochloric acid had been dissolved in 50 mL of water. Then, the aqueous hydrochloric acid layers after the extraction were mixed with each other and then washed with 50 mL of ethane dichloride, 46.5 g of 25% sodium hydroxide solution was added to the aqueous hydrochloric acid layer to adjust the pH to be alkaline, extraction with 100 mL of methylene chloride was carried out three times, and the methylene chloride layer was subsequently washed with 50 mL of a salt solution. The methylene chloride layer was dehydrated with magnesium sulfate, the magnesium sulfate was separated by filtration, and the filtrate was concentrated under reduced pressure to produce 33.4 g of the residue. The residue was distilled under reduced pressure to obtain 31.1 g of a main fraction, thereby yielding a ligand 3. The boiling point thereof was 105 to 110° C./300 Pa vacuum, and the yield was 80.0%. FAB-MS(+): m/z=213.1154 (100%), 214.1187 (15.1%), and 215.1221 (1.1%). FIG. 19 illustrates a ¹H-NMR chart of the ligand 3. ¹H-NMR (400 MHz, deuterated chloroform (CDCl₃)): δ (ppm)=8.69 (1H, ddd), 7.90 (1H, dd), 7.80 (1H, dd), 7.67 (1H, td), 7.33 (1H, td), 7.18 (1H, ddd), 7.07 (1H, td), 6.99 (1H, d), 4.52 (1H, sept), 1.29, and 1.28 (6H, 2s).

[Synthesis of Transition Metal Complex]

In each of the following synthetic examples, a compound in each step and the final compound (transition metal complex) were identified with reference to a MS spectrum (FAB-MS).

### Synthetic Example 4

### Synthesis of Compound 1 and Compound 6

A compound 1 and a compound 6 were synthesized through the following route.

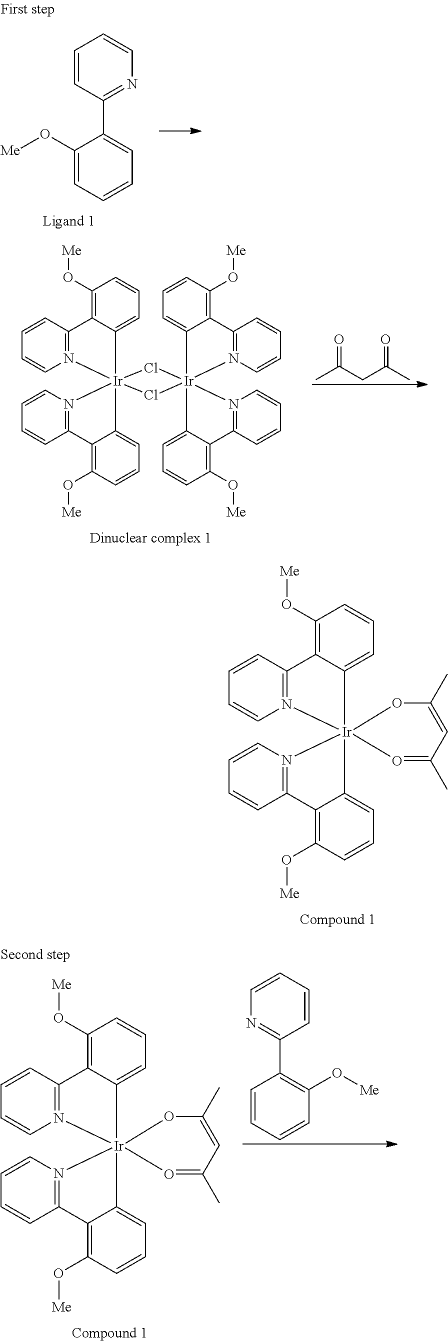

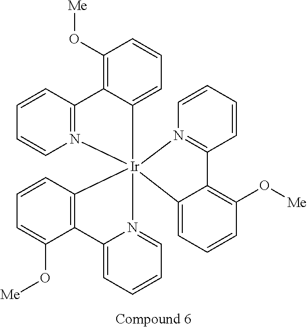

First Step (Synthesis of Compound 1)

Under a nitrogen atmosphere, IrCl₃.nH₂O (25.0 g, 83.7 mmol) and the ligand 1 (34.3 g, 185 mmol) in 2-ethoxyethanol (100 mL) and ion exchanged water (340 mL) were stirred at an oil bath temperature of 130° C. for 30 minutes, and the solid content in the reaction solution was separated by filtration, collected by filtration, and dried to obtain 39.9 g of a dinuclear complex 1. ¹H-NMR (400 MHz, deuterated chloroform (CDCl₃)): δ (ppm)=9.23-9.22 (4H, dd, J=6.0 Hz, 0.92 Hz, Pyr⁶), 8.52-8.51 (4H, dd, J=8.2 Hz, 0.92 Hz, Pyr³), 7.69-7.64 (4H, td, J=8.7 Hz, 1.4 Hz, Pyr⁴), 6.69-6.65 (4H, td, J=7.4 Hz, 1.4 Hz, Pyr⁵), 6.50-6.47 (4H, t, J=7.8 Hz, Ph⁴), 6.28 (4H, d, J=7.8 Hz, Ph⁵ or Ph³), 5.53-5.51 (4H, dd, J=7.8 Hz, 1.2 Hz, Ph³ or Ph⁵), and 3.85 (12H, s, CH₃O—); ¹³C-NMR (100 MHz, deuterated chloroform (CDCl₃)): δ (ppm)=167.51, 157.63, 151.59, 148.55, 135.90, 131.94, 129.10, 123.49, 123.23, 121.31, 104.06, and 54.79.

Then, under a nitrogen atmosphere, the dinuclear complex 1 (17.0 g, 14.2 mmol), acetylacetone (4.3 mL, 41.7 mmol), and NaHCO₃ (13.0 g, 155 mmol) in 2-ethoxyethanol (650 mL) were stirred at an oil bath temperature of 140° C. for an hour. The reaction solution was cooled to room temperature, and then the solid content in the reaction solution was separated by filtration and washed with ion exchanged water (500 mL) to produce a crude compound 1. Then, the crude compound 1 was dissolved in chloroform (1300 mL), the insoluble matter was removed by filtration, and the filtrate was concentrated to produce 13.28 g of a final compound 1. The yield was 69.4%. ¹H-NMR (400 MHz, deuterated chloroform (CDCl₃)): δ (ppm)=8.71-8.68 (3H, dt, J=8.7 Hz, 0.92 Hz, Pyr⁶), 8.52-8.50 (3H, dt, J=6.4 Hz, 0.92 Hz, Pyr³), 7.71-7.67 (3H, td, J=9.2 Hz, 1.8 Hz, Pyr⁴), 7.08-7.05 (3H, td, J=7.1 Hz, 1.4 Hz, Pyr⁵), 6.64-6.60 (3H, t, J=7.6 Hz, Ph⁴), 6.36-6.34 (3H, dd, J=8.3 Hz, 0.92 Hz, Ph⁵ or Ph³), 6.5.88-5.86 (3H, dd, J=7.8 Hz, 0.92 Hz, Ph³ or Ph⁵), 5.18 (1H, s, acac-CH), 3.88 (9H, s, CH₃O—), and 1.76 (6H, s, acac-CH₃); ¹³C-NMR (100 MHz, deuterated chloroform (CDCl₃)): δ (ppm)=184.45, 167.69, 158.09, 151.06, 147.80, 136.64, 132.71, 129.38, 125.81, 123.61, 120.47, 103.60, 100.23, 54.71, and 28.74; and FAB-MS(+): m/z=658.1577 (59.5%), 659.1610 (18.7%), 660.1600 (100%), 660.1644 (2.8%), 661.1634 (31.4%), and 662.1667 (4.7%).

Second Step (Synthesis of Compound 6)

Under a nitrogen atmosphere, the compound 1 (6.44 g, 9.56 mmol) and the ligand 1 (5.32 g, 28.7 mmol) in glycerol (400 mL) were stirred at an oil bath temperature of 150° C. for 4 days. The solid content in the reaction solution was separated by filtration, and the obtained solid was subjected to suspension wash with chloroform (50 mL) to obtain a solid that was a crude compound 6. The crude compound 6 was purified by sublimation to produce 4.7 g of a final compound 6. The yield was 66.2%. ¹H-NMR (400 MHz, deuterated chloroform (CDCl₃)): δ (ppm)=8.75 (3H, d, J=8.7 Hz, Pyr⁶), 7.55-7.51 (3H, td, J=8.7 Hz, 1.8 Hz, Pyr⁵), 7.47-7.45 (3H, dd, J=5.5 Hz, 0.92 Hz, Pyr³), 6.79-6.75 (6H, m, Pyr⁴ and Ph⁴), 6.54-6.52 (3H, dd, J=7.4 Hz, 0.92 Hz, Ph⁵ or Ph³), 6.45-6.43 (3H, dd, J=8.3 Hz, 0.92 Hz, Ph³ or Ph⁵), and 3.90 (9H, s, CH₃O—); ¹³C-NMR (100 MHz, deuterated chloroform (CDCl₃)): δ (ppm)=166.01, 165.71, 158.70, 146.67, 135.60, 131.75, 130.09, 129.97, 124.25, 120.96, 102.42, and 54.66; HRMS (ESI-TOF) calcd for ¹²C₃₆¹H₃¹⁹¹Ir₁¹⁴N₃¹⁶O₃ [M+H]⁺ 744.19713. found 744.19823; and FAB-MS(+): m/z=743.1893 (59.5%), 744.1927 (23.2%), 745.1916 (100%), 746.1887 (1.1%), 746.1950 (38.9%), and 747.1984 (7.4%). The compound 6 was subjected to analysis by ¹H-NMR; in terms of the geometrical isomer content, the fac isomer content was higher than the mer isomer content.

### Synthetic Example 5

### Synthesis of Compound 2 and Compound 7

A compound 2 and a compound 7 were synthesized through the following route.

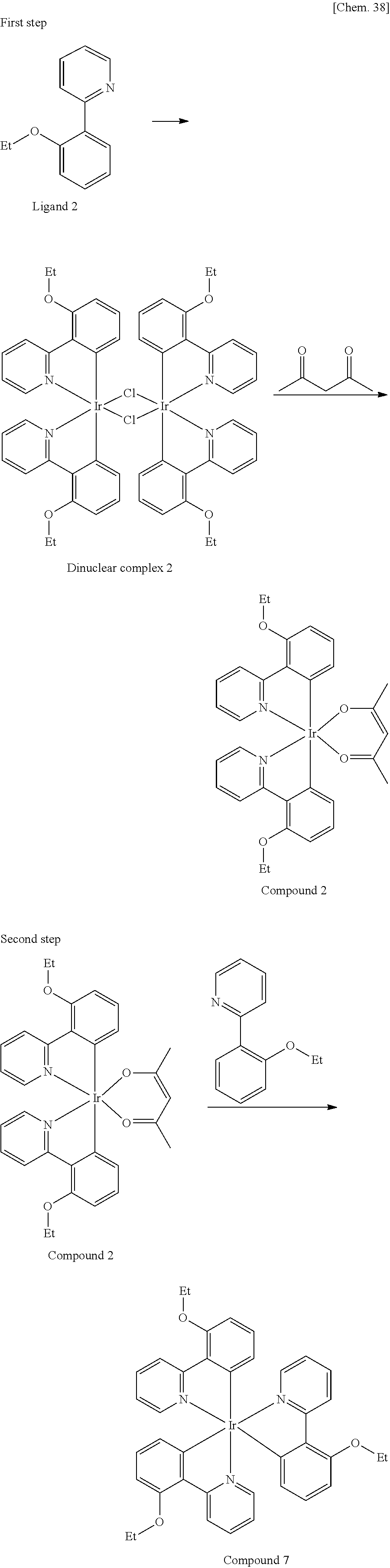

First Step (Synthesis of Compound 2)

Under a nitrogen atmosphere, IrCl₃.nH₂O (25.0 g, 83.7 mmol) and the ligand 2 (36.9 g, 185 mmol) in 2-ethoxyethanol (100 mL) and ion exchanged water (340 mL) were stirred at an oil bath temperature of 130° C. for 30 minutes, and then the solid content in the reaction solution was separated by filtration, collected by filtration, and dried to obtain 40.9 g of a dinuclear complex 2. ¹H-NMR (400 MHz, deuterated chloroform (CDCl₃)): δ (ppm)=9.22 (4H, d, J=5.0 Hz, Pyr⁶), 8.79 (4H, d, J=8.2 Hz, Pyr³), 7.69-7.65 (4H, t, J=7.3 Hz, Pyr⁴), 6.69-6.66 (4H, t, J=6.9 Hz, Pyr⁵), 6.48-6.44 (4H, t, J=7.8 Hz, Ph⁴), 6.26 (4H, d, J=7.8 Hz, Ph⁵ or Ph³), 5.51-5.49 (4H, d, J=7.8 Hz, Ph³ or Ph⁵), 4.07-4.04 (8H, q, J=4.84 Hz, —CH₂O—), and 1.53 (12H, t, J=6.9 Hz, CH₃—); and ¹³C-NMR (100 MHz, deuterated chloroform (CDCl₂)): δ (ppm)=167.59, 157.05, 151.61, 148.61, 135.84, 131.75, 129.06, 123.50, 123.17, 121.27, 104.69, 63.21, and 14.95.

Then, under a nitrogen atmosphere, the dinuclear complex 2 (17.8 g, 14.2 mmol), acetylacetone (4.3 mL, 41.7 mmol), and NaHCO₃ (13.0 g, 155 mmol) in 2-ethoxyethanol (650 mL) were stirred at an oil bath temperature of 140° C. for an hour. The reaction solution was cooled to room temperature, and then the solid content in the reaction solution was separated by filtration and washed with ion exchanged water (500 mL) to produce a crude compound 2. Then, the crude compound 2 was dissolved in chloroform (1300 mL), the insoluble matter was removed by filtration, and the filtrate was concentrated to produce 13.58 g of a final compound 2. The yield was 68.1%. ¹H-NMR (400 MHz, deuterated chloroform (CDCl₂)): δ (ppm)=8.78-8.76 (2H, dt, J=7.8 Hz, 0.8 Hz, Pyr⁶), 8.52-8.51 (2H, dt, J=5.5 Hz, 0.92 Hz, Pyr³), 7.71-7.67 (2H, td, J=8.3 Hz, 1.4 Hz, Pyr⁵), 7.08-7.04 (2H, td, J=6.9 Hz, 1.4 Hz, Pyr⁴), 6.61-6.57 (2H, t, J=7.8 Hz, Ph⁴), 6.32 (2H, d, J=7.8 Hz, Ph⁵ or Ph³), 5.87-5.84 (2H, dd, J=5.8 Hz, 0.92 Hz, Ph³ or Ph⁵), 5.18 (1H, s, acac-CH), 4.12-4.07 (4H, q, J=6.9 Hz, —CH₂O—), 1.76 (6H, s, acac-CH₃), and 1.53 (6H, t, J=6.9 Hz, CH₃—); ¹³C-NMR (100 MHz, deuterated chloroform (CDCl₂)): δ (ppm)=184.41, 167.76, 157.51, 150.98, 147.77, 136.60, 132.54, 129.34, 125.63, 123.61, 120.41, 104.29, 100.22, 63.12, 28.71, and 14.94; and FAB-MS(+): m/z=686.1890 (59.5%), 687.1923 (19.9%), 688.1913 (100%), 689.1947 (33.5%), 690.1980 (5.4%), and 688.1957 (3.2%).

Second Step (Synthesis of Compound 7)

Under a nitrogen atmosphere, the compound 2 (6.71 g, 9.56 mmol) and the ligand 2 (5.72 g, 28.7 mmol) in glycerol (400 mL) were stirred at an oil bath temperature of 150° C. for 4 days. The solid content in the reaction solution was separated by filtration, and the obtained solid was subjected to suspension wash with chloroform (50 mL) to obtain a solid that was a crude compound 7. The crude compound 7 was purified by sublimation to produce 4.3 g of a final compound 7. The yield was 57.2%. ¹H-NMR (400 MHz, deuterated chloroform (CDCl₂)): δ (ppm)=8.84 (3H, d, J=8.2 Hz, Pyr⁶), 7.55-7.51 (3H, td, J=7.3 Hz, 1.8 Hz, Pry⁵), 7.47-7.46 (3H, dt, J=5.5 Hz, 0.92 Hz, Pyr³), 6.79-6.72 (6H, m, Pyr⁴ and Ph⁴), 6.52-6.50 (3H, dd, J=7.3 Hz, 0.92 Hz, Ph⁵ or Ph³), 6.42-6.40 (3H, dd, J=8.2 Hz, 0.92 Hz, Ph³ or Ph⁵), 4.2-4.07 (6H, m), and 1.53 (9H, t, J=7.3 Hz, CH₃—); ¹³C-NMR (100 MHz, deuterated chloroform (CDCl₂)): δ (ppm)=166.11, 165.82, 158.13, 146.65, 135.52, 131.59, 130.08, 129.81, 124.28, 120.87, 103.13, 63.12, and 15.02; and FAB-MS(+): m/z=785.2363 (59.5%), 786.2396 (25.1%), 787.2386 (100%), 787.2430 (5.2%), 788.2356 (1.1%), 788.2419 (42.2%), 789.2453 (8.7%), and 790.2487 (1.2%). The compound 7 was subjected to analysis by ¹H-NMR; in terms of the geometrical isomer content, the fac isomer content was higher than the mer isomer content.

### Synthetic Example 6

### Synthesis of Compound 3 and Compound 8

A compound 3 and compound 8 were synthesized through the following route.

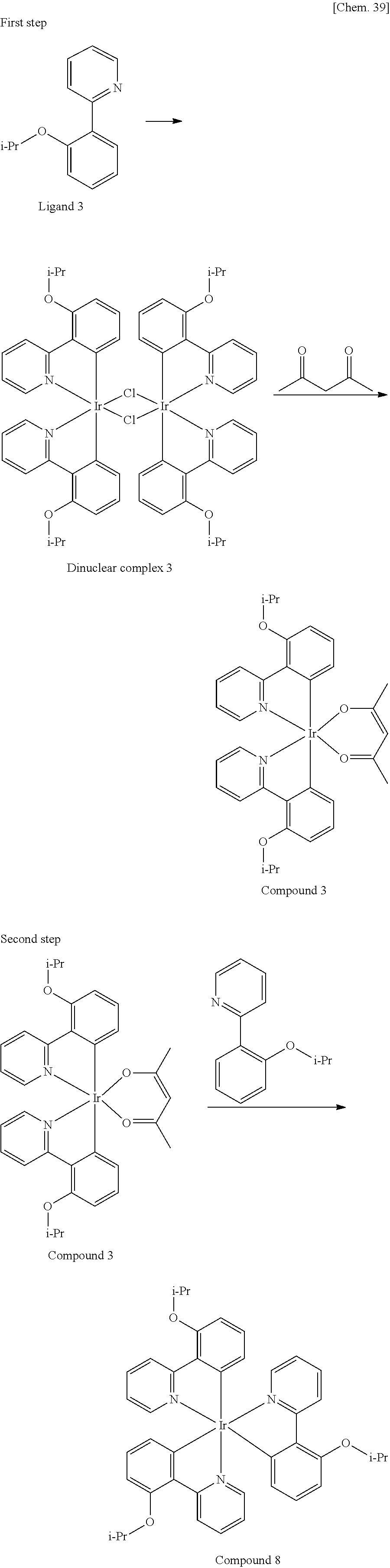

First Step (Synthesis of Compound 3)

Under a nitrogen atmosphere, IrCl₃.nH₂O (25.0 g, 83.7 mmol) and the ligand 3 (39.5 g, 185 mmol) in 2-ethoxyethanol (100 mL) and ion exchanged water (340 mL) were stirred at an oil bath temperature of 130° C. for 30 minutes, and the reaction solution was subjected to separation by filtration, collection by filtration, and drying to obtain 39.9 g of a dinuclear complex 3. ¹H-NMR (400 MHz, deuterated chloroform (CDCl₃)): δ (ppm)=9.21 (4H, dd, J=6.0 Hz, 0.92 Hz, Pyr⁶), 8.81-8.79 (4H, dd, J=7.8 Hz, 0.92 Hz, Pyr³), 7.67-7.63 (4H, td, J=8.5 Hz, 1.4 Hz, Pyr⁴), 6.69-6.65 (4H, td, J=8.5 Hz, 1.4 Hz, Pyr⁵), 6.46 (4H, t, J=8.2 Hz, Ph⁴), 6.26 (4H, d, J=7.8 Hz, Ph⁵ or Ph³), 5.51-5.49 (4H, dd, J=7.0 Hz, 0.88 Hz, Ph³ or Ph⁵), 4.60 (4H, sept, J=6.0 Hz, iPr—CH), 1.41 (24H, t, J=6.0 Hz, iPr—CH₃); and ¹³C-NMR (100 MHz, deuterated chloroform (CDCl₃)): δ (ppm)=167.68, 155.88, 151.66, 148.74, 135.70, 132.36, 128.90, 123.43, 122.80, 121.25, 105.68, 69.20, and 22.40.

Then, under a nitrogen atmosphere, the dinuclear complex 3 (18.6 g, 14.2 mmol), acetylacetone (4.3 mL, 41.7 mmol), and NaHCO₃ (13.0 g, 155 mmol) in 2-ethoxyethanol (650 mL) were stirred at an oil bath temperature of 140° C. for an hour. The reaction solution was cooled to room temperature, and then the solid content in the reaction solution was separated by filtration and washed with ion exchanged water (500 mL) to produce a crude compound 3. Then, the crude compound 3 was dissolved in chloroform (1300 mL), the insoluble matter was removed by filtration, and the filtrate was concentrated to produce 12.88 g of a final compound 3. The yield was 62.1%. ¹H-NMR (400 MHz, deuterated chloroform (CDCl₃)): δ (ppm)=8.78 (4H, d, J=8.7 Hz, Pyr⁶), 8.52-8.50 (4H, dt, J=6.4 Hz, 0.92 Hz, Pyr³), 7.69-7.65 (4H, td, J=8.7 Hz, 1.4 Hz, Pyr⁴), 7.06-7.02 (4H, td, J=6.4 Hz, 0.92 Hz, Pyr⁵), 6.59 (4H, t, J=7.8 Hz, Ph⁴), 6.33 (4H, d, J=8.7 Hz, Ph⁵ or Ph³), 5.84 (4H, d, J=7.4 Hz, Ph³ or Ph⁵), 5.17 (1H, s, acac-CH), 4.65 (2H, sept, J=6.0 Hz, iPr—CH), 1.76 (6H, s, acac-CH₃), and 1.43-1.42 (12H, 2d, J=5.9 Hz, iPr—CH₃); ¹³C-NMR (100 MHz, deuterated chloroform (CDCl₃)): δ (ppm)=184.38, 167.84, 156.38, 151.02, 147.74, 136.50, 133.26, 129.20, 125.32, 123.63, 120.34, 105.46, 100.23, 69.71, 28.72, 22.47, and 22.35; and FAB-MS(+): m/z=714.2203 (59.5%), 715.2236 (21.2%), 716.2226 (100%), 716.2270 (3.7%), 717.2260 (35.7%), and 718.2293 (6.2%).

Second Step (Synthesis of Compound 8)

Under a nitrogen atmosphere, the compound 3 (7.03 g, 9.56 mmol) and the ligand 3 (6.12 g, 28.7 mmol) in glycerol (400 mL) were stirred at an oil bath temperature of 150° C. for 4 days. The solid content in the reaction solution was separated by filtration, and the obtained solid was subjected to suspension wash with chloroform (50 mL) to obtain a solid that was a crude compound 8. The crude compound 8 was purified by sublimation to produce 3.8 g of a final compound 8. The yield was 47.9%. ¹H-NMR (400 MHz, deuterated chloroform (CDCl₃)): δ (ppm)=8.87 (3H, d, Pyr⁶), 7.54-7.49 (3H, td, J=9.2 Hz, 1.8 Hz, Pyr⁵), 7.44-7.43 (3H, dt, J=5.0 Hz, 0.92 Hz, Pyr³), 6.77-6.71 (6H, m, Pyr4 and Ph⁴), 6.49 (3H, d, J=7.4 Hz, Ph⁵ or Ph³), 6.42 (3H, d, J=7.8 Hz, Ph³ or Ph⁵), 4.69 (3H, sept, J=5.7 Hz, iPr—CH), and 1.42, 1.41 (9H, 2d, J=2.8 Hz, iPr—CH₃); ¹³C-NMR (100 MHz, deuterated chloroform (CDCl₃)): δ (ppm)=166.12, 166.00, 156.96, 146.58, 135.36, 132.75, 129.87, 129.69, 124.40, 120.84, 104.93, 70.05, 22.48, and 22.46; and FAB-MS(+): m/z=827.2832 (59.5%), 828.2866 (27.0%), 829.2855 (100%), 829.2899 (6.0%), 830.2826 (1.1%), 830.2889 (45.4%), 831.2923 (10.1%), and 832.2956 (1.5%). The geometrical isomer content of the compound 8 was analyzed, and an integrated intensity ratio obtained by ¹H-NMR showed that the fac isomer content was higher than the mer isomer content.

(Synthesis of Compound 4)

Except that 1-bromo-2-(octyloxy)benzene was used as a starting material, a compound 4 was synthesized as in the synthesis of the compound 1. The yield was 64.2%. FAB-MS(+): m/z=857.03 (32.8%), 856.02 (4.8%), and 758.13 (100%).

(Synthesis of Compound 5)

Except that 1-bromo-2-phenoxybenzene was used as a starting material, a compound 4 was synthesized as in the synthesis of the compound 1. The yield was 62.1%. FAB-MS(+): m/z=784.92 (42.1%), 783.88 (12.4%), and 685.74 (100%).

(Synthesis of Compound 9)

Except that the compound 4 and 1-bromo-2-(octyloxy)benzene were used as starting materials, a compound 4 was synthesized as in the synthesis of the compound 6. The yield was 58.2%. FAB-MS(+): m/z=1040.53 (68.4%), 1039.52 (3.4%), and 758.12 (100%). The geometrical isomer content of the compound 9 was analyzed, and an integrated intensity ratio obtained by ¹H-NMR showed that the fac isomer content was higher than the mer isomer content.

(Synthesis of Compound 10)

Except that the compound 5 and 1-bromo-2-phenoxybenzene were used as starting materials, a compound 4 was synthesized as in the synthesis of the compound 6. The yield was 55.2%. FAB-MS(+): m/z=932.14 (78.1%), 931.12 (10.4%), and 685.76 (100%). The geometrical isomer content of the compound 10 was analyzed, and an integrated intensity ratio obtained by ¹H-NMR showed that the fac isomer content was higher than the mer isomer content.

(Synthesis of Compound 11)

To a solution in which the dinuclear complex 3 [(iPrOppy)₂Ir(μ-Cl)]₂ (2.0 g, 1.5 mmol) had been dissolved in 50 mL of dichloromethane, 2.1 equivalents of silver trifluoromethanesulfonate (0.81 g, 3.2 mmol) dissolved in 50 mL of methanol was added to produce a cream-colored slurry. The slurry was stirred for two hours at room temperature and then subjected to centrifugal separation to remove the precipitate of silver chloride and a separated transparent supernatant solvent, thereby obtaining a residue that was in the form of oil. The residue was dissolved in 50 mL of acetonitrile, 3 equivalents of tetrakis(1-pyrazolyl)borate potassium salt K(pz₂Bpz₂) (1.4 g, 4.5 mmol) was added thereto, and the product was refluxed under a nitrogen atmosphere for 18 hours and then cooled to room temperature. The precipitate was collected by filtration, dissolved in 50 mL of dichloromethane, and then subjected to filtration again. Filtrate was distilled off, and drying was carried out to produce a crude product of (iPrOppy)₂Ir(pz₂Bpz₂). The crude product was recrystallized with methanol/dichloromethane and purified by sublimation to produce a compound 11. The amount thereof was 1.0 g, and the yield was 73%. FAB-MS(+): m/z=213.1154 (100%), 214.1187 (15.1%), and 215.1221 (1.1%); and ¹H-NMR (400 MHz, deuterated chloroform (CDCl₃)): δ (ppm)=8.80 (2H, d), 7.68 (2H, td), 7.58 (2H, td), 7.52 (2H, td), 7.50 (2H, td), 7.43 (2H, dd), 7.28 (2H, td), 6.75 (4H, td), 6.48 (2H, d), 6.43 (2H, d), 6.07 (2H, s), 5.99 (2H, s), 4.70 (2H, sept), 1.42, and 1.40 (12H, 2s).

(Synthesis of Compound 12)

To a solution in which the dinuclear complex 2 [(EtOppY)₂Ir(μ-Cl)]₂(1.24 g, 1.0 mmol) had been dissolved in 50 mL of dichloromethane, 1.05 equivalents of silver trifluoromethanesulfonate (0.54 g, 2.1 mmol) dissolved in 50 mL of methanol was added to produce a cream-colored slurry. The slurry was stirred for two hours at room temperature and then subjected to centrifugal separation to remove the precipitate of silver chloride and a separated transparent supernatant solvent, thereby obtaining a residue that was in the form of oil. The residue was dissolved in 50 mL of acetonitrile, 3 equivalents of tetrakis(1-pyrazolyl)borate potassium salt K(pz₂Bpz₂) (2.0 g, 6.3 mmol) was added thereto, and the product was refluxed under a nitrogen atmosphere for 18 hours and then cooled to room temperature. The precipitate was collected by filtration, dissolved in 70 mL of dichloromethane, and then subjected to filtration again. Filtrate was distilled off, and drying was carried out to produce a crude product of (EtOppy)₂Ir(pz₂Bpz₂). The crude product was recrystallized with methanol/dichloromethane and purified by sublimation to produce a compound 12. The amount thereof was 1.04 g, and the yield was 60%. FAB-MS (+): m/z=868.27 (100.0%), 866.27 (59.5%), 867.28 (50.6%), 869.28 (44.6%), 868.28 (16.4%), 865.28 (14.6%), 870.28 (8.9%), 866.28 (6.1%), 869.27 (3.7%), 867.27 (2.2%), 870.27 (1.6%), and 871.28 (1.6%); and ¹H-NMR (CDCl₃, 400 MHz): δ (ppm)=8.69 (2H, d), 7.70 (2H, d), 7.51 (2H, td), 7.34 (2H, dd), 7.26 (2H, s), 7.11 (2H, d), 6.90 (2H, t), 6.71 (2H, t), 6.62 (2H, td), 6.45 (2H, d), 6.17 (2H, dd), 5.75 (2H, d), 4.17-4.08 (4H, m), and 1.53 (6H, t).

[Evaluation of Luminescence Properties]

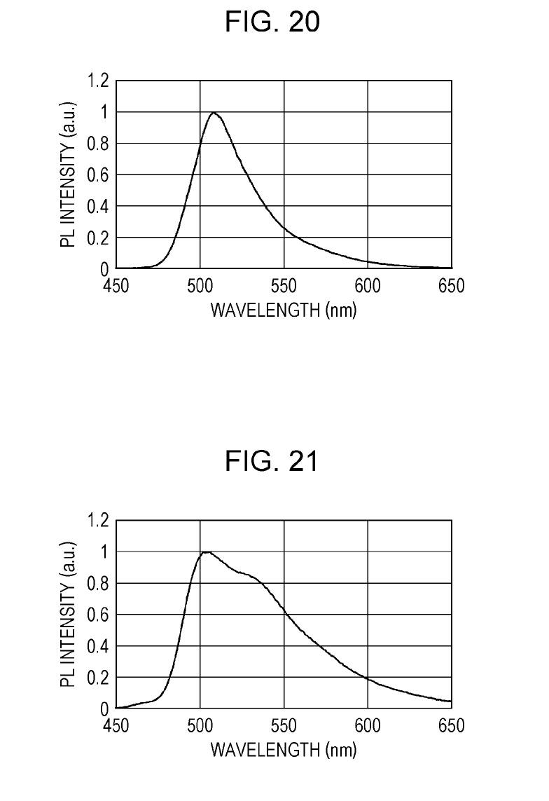

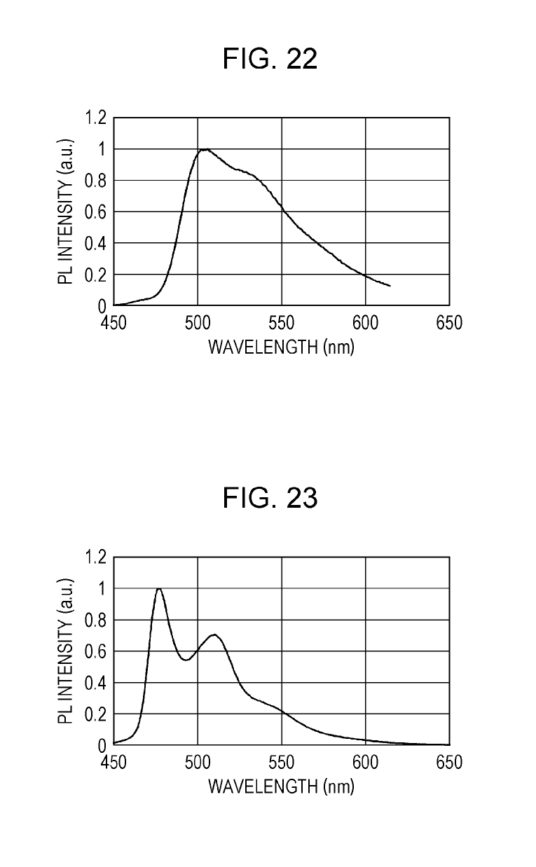

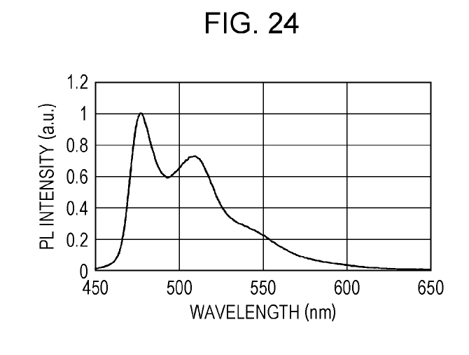

In 2-methyl-THF, 1 wt % of the compounds 6, 7, 8, 11, and 12 were dissolved, and analysis was carried out with a quantum efficiency measurement system (QE-1100) manufactured by Otsuka Electronics Co., Ltd. to obtain photoluminescence (PL) spectra and measure quantum yields at an excitation wavelength of 300 nm. FIGS. 20 to 24 illustrate PL spectra, and Table 1 shows the resulting quantum yields.

TABLE 1

| | Com- | Com- | Com- | Com- | Com- |
|---|---|---|---|---|---|
| | pound | pound | pound | pound | pound |
| | 6 | 7 | 8 | 11 | 12 |
| Quantum | 92% | 77% | 85% | 98% | 99% |
| yield | | | | | |

[Production of Organic Light-emitting Device and Evaluation of Organic EL Properties]

### Example 1

An indium tin oxide (ITO) electrode was formed as an anode on a glass substrate. Then, the ITO was processed into a pattern having a width of 2 mm, another pattern was formed of a polyimide resin so as to surround the periphery of the ITO electrode, and the substrate on which the ITO electrode had been formed was subjected to ultrasonic cleaning and baked under reduced pressure at 200° C. for 3 hours.

Then, N,N′-diphenyl-N,N′-bis[4-(phenyl-m-tolyl-amino)-phenyl]-biphenyl-4,4′-diamine (DNTPD) was deposited on the anode by vacuum deposition at a deposition rate of 1 Å/sec to form a hole injection layer having a thickness of 60 nm on the anode.

Then, 4,4′-bis[N-(1-naphthyl)-N-phenyl-amino]biphenyl (α-NPD) was deposited on the hole injection layer by vacuum deposition at a deposition rate of 1 Å/sec to form a hole transport layer having a thickness of 20 nm on the hole injection layer.

Then, N,N-dicarbazoyl-3,5-benzene (mCP) was deposited on the hole transport layer by vacuum deposition at a deposition rate of 1 Å/sec to form an exciton-blocking layer having a thickness of 10 nm on the hole transport layer.

Then, mCP and the compound 1 were co-deposited on the exciton-blocking layer by vacuum deposition to form an organic light-emitting layer having a thickness of 30 nm. The mCP that was the host material was doped with the compound 1 such that the compound 1 content therein was approximately 7.5%.

Then, diphenylphosphine oxide-4-(triphenylsilyl)phenyl (TSPO1) was deposited on the organic light-emitting layer by vacuum deposition to form an electron transport layer having a thickness of 30 nm on the organic light-emitting layer.

Then, lithium fluoride (LiF) was deposited on the electron transport layer by vacuum deposition at a deposition rate of 1 Å/sec to form a LiF film having a thickness of 0.5 nm. Then, aluminum (Al) was used to form an Al film having a thickness of 100 nm on the LiF film. The multilayer film of LiF and Al had been formed as a cathode in this manner to complete production of an organic EL device (organic light-emitting device).

The current efficiency (luminous efficiency) and emission wavelength of the organic EL device at 1000 cd/m² were measured. Tables 2 and 3 show results of the measurement.

### Example 2

Except that the dopant (luminescent material) with which the organic light-emitting layer was to be doped was changed to the compound 2, an organic EL device (organic light-emitting device) was produced as in Example 1, and the current efficiency (luminous efficiency) and emission wavelength of the organic EL device at 1000 cd/m² were measured. Table 2 shows results of the measurement.

### Example 3

Except that the dopant (luminescent material) with which the organic light-emitting layer was to be doped was changed to the compound 3, an organic EL device (organic light-emitting device) was produced as in Example 1, and the current efficiency (luminous efficiency) and emission wavelength of the organic EL device at 1000 cd/m² were measured. Table 2 shows results of the measurement.

### Example 4

After an anode was formed as in Example 1, an aqueous solution of poly(3,4-ethylenedioxythiophene):poly(styrenesulfonate) (PEDOT:PSS) was applied onto the anode by spin coating and heated with a hot plate at 200° C. for 30 minutes to form the hole injection layer having a thickness of 45 nm on the anode.

Then, a solution in which CFL (4,4′-bis(N-carbazoyl)-9,9′-spirobifluorene) and the compound 4 (T1 level: 3.2 eV) had been dissolved in dichloroethane was applied onto the hole injection layer by spin coating and then dried to form an organic light-emitting layer having a thickness of 50 nm. The CFL that was the host material was doped with the compound 4 such that the compound 4 content therein was approximately 7.5%. Then, a hole-block layer (hole-blocking layer) having a thickness of 5 nm was formed of UGH2 (1,4-bis triphenylsilyl benzene) on the organic light-emitting layer, and 1,3,5-tris(N-phenylbenzimidazol-2-yl)benzene (TPBI) was deposited on the hole-blocking layer by vacuum deposition to form an electron transport layer having a thickness of 30 nm on the hole-blocking layer.

Then, a multilayer film of LiF and Al was formed as a cathode on the electron transport layer as in Example 1 to complete production of an organic EL device (organic light-emitting device), and the current efficiency (luminous efficiency) and emission wavelength of the organic EL device at 1000 cd/m² were measured. Table 2 shows results of the measurement.

### Example 5

Except that the dopant (luminescent material) with which the organic light-emitting layer was to be doped was changed to the compound 5, an organic EL device (organic light-emitting device) was produced as in Example 1, and the current efficiency (luminous efficiency) and emission wavelength of the organic EL device at 1000 cd/m² were measured. Table 2 shows results of the measurement.

### Example 6

Except that the dopant (luminescent material) with which the organic light-emitting layer was to be doped was changed to the compound 6, an organic EL device (organic light-emitting device) was produced as in Example 1, and the current efficiency (luminous efficiency) and emission wavelength of the organic EL device at 1000 cd/m² were measured. Table 2 shows results of the measurement.

### Example 7

Except that the dopant (luminescent material) with which the organic light-emitting layer was to be doped was changed to the compound 7, an organic EL device (organic light-emitting device) was produced as in Example 1, and the current efficiency (luminous efficiency) and emission wavelength of the organic EL device at 1000 cd/m² were measured. Table 2 shows results of the measurement.

### Example 8

Except that the dopant (luminescent material) with which the organic light-emitting layer was to be doped was changed to the compound 8, an organic EL device (organic light-emitting device) was produced as in Example 1, and the current efficiency (luminous efficiency) and emission wavelength of the organic EL device at 1000 cd/m² were measured. Table 2 shows results of the measurement.

### Example 9

Except that the dopant (luminescent material) with which the organic light-emitting layer was to be doped was changed to the compound 9, an organic EL device (organic light-emitting device) was produced as in Example 4, and the current efficiency (luminous efficiency) and emission wavelength of the organic EL device at 1000 cd/m² were measured. Table 2 shows results of the measurement.

### Example 10

Except that the dopant (luminescent material) with which the organic light-emitting layer was to be doped was changed to the compound 10, an organic EL device (organic light-emitting device) was produced as in Example 1, and the current efficiency (luminous efficiency) and emission wavelength of the organic EL device at 1000 cd/m² were measured. Table 2 shows results of the measurement.

### Example 11

Except that the dopant (luminescent material) with which the organic light-emitting layer was to be doped was changed to the compound 11, an organic EL device (organic light-emitting device) was produced as in Example 1, and the current efficiency (luminous efficiency) and emission wavelength of the organic EL device at 1000 cd/m² were measured. Table 2 shows results of the measurement.

### Comparative Example 1

Except that the dopant (luminescent material) with which the organic light-emitting layer was to be doped was changed to a typical material that was (tris(2-phenylpyridinato)iridium(III): Ir(ppy)₃), an organic EL device (organic light-emitting device) was produced as in Example 1, and the current efficiency (luminous efficiency) and emission wavelength of the organic EL device at 1000 cd/m² were measured. Table 2 shows results of the measurement.

### Comparative Example 2

Except that the dopant (luminescent material) with which the organic light-emitting layer was to be doped was changed to a typical material that was bis[(4,6-difluorophenyl)-pyridinato-N,C2′]picolinate iridium(III) (FIrPic), an organic EL device (organic light-emitting device) was produced as in Example 1, and the current efficiency (luminous efficiency) and emission wavelength of the organic EL device at 1000 cd/m² were measured. Table 2 shows results of the measurement.

### Comparative Example 3

Except that the dopant (luminescent material) with which the organic light-emitting layer was to be doped was changed to Ir(DMeOppy)₂PO-1, an organic EL device (organic light-emitting device) was produced as in Example 1, and the current efficiency (luminous efficiency) and emission wavelength of the organic EL device at 1000 cd/m² were measured. Table 2 shows results of the measurement.

TABLE 2

| | Organic light-emitting layer | | Luminous | Maximum |
|---|---|---|---|---|
| | | Dopant (luminescent | efficiency | luminous point |
| | Host | material) | (od/A) | (nm) |
| Example 1 | mCP | Compound 1 | 34.2 | 506 |
| Example 2 | mCP | Compound 2 | 34.3 | 507 |
| Example 3 | mCP | Compound 3 | 34.5 | 505 |
| Example 4 | CFL | Compound 4 | 34.0 | 504 |
| Example 5 | mCP | Compound 5 | 34.6 | 506 |
| Example 6 | mCP | Compound 6 | 34.8 | 507 |
| Example 7 | mCP | Compound 7 | 34.7 | 504 |
| Example 8 | mCP | Compound 8 | 34.8 | 503 |
| Example 9 | CFL | Compound 9 | 33.6 | 505 |
| Example 10 | mCP | Compound 10 | 34.5 | 505 |
| Example 11 | mCP | Compound 11 | 11.3 | 478 |
| Comparative | mCP | Ir(ppy)₃ | 20.0 | 520 |
| Example 1 | | | | |
| Comparative | mCP | FIrpic | 9.0 | 483 |
| Example 2 | | | | |
| Comparative | mCP | Ir(DMeOppy)₂(PO-1) | 7.5 | 483 |
| Example 3 | | | | |

From the results shown in Table 2, the luminous efficiency and color purity of emitted light were higher in the organic EL devices of Examples 1 to 10 in which the compounds 1 to 10 as the transition metal complexes according to aspects of the present invention had been used as dopants (luminescent materials), respectively, than in the organic EL device of Comparative Example 1 in which a typical compound (Ir(ppy)₃) had been used as a luminescent material and the organic EL device of Comparative Example 2 in which Ir(DMeOppy)₂PO-1 had been used as a luminescent material.

The luminous efficiency of emitted light was higher in the organic EL device of Example 12 in which the compound 11 that was the transition metal complex according to an aspect of the present invention had been used as a dopant (luminescent material) than in the organic EL device of Comparative Example 2 in which a typical compound (FIrpic) had been used as a luminescent material.

### Example 12

Except that the compound 9 was used in place of mCP to form the exciton-blocking layer, an organic EL device (organic light-emitting device) was produced as in Example 1, and the emission wavelength of the organic EL device at 1000 cd/m² was measured. Table 3 shows result of the measurement.

### Example 13

An anode, a hole injection layer, a hole transport layer, and an exciton-blocking layer were formed on a glass substrate in sequence as in Example 1. Then, the compound 1 as the host material and bis[1-(9,9-dimethyl-9H-fluorene-2-yl)-isoquinoline](acetyl acetonate)iridium (III) (Ir(fliq)₂(acac)) as the dopant were co-deposited on the exciton-blocking layer by vacuum deposition to form an organic light-emitting layer having a thickness of 30 nm. The compound 1 as the host material was doped with the Ir(fliq)₂(acac) such that the Ir(fliq)₂(acac) content therein was approximately 0.5%. Then, an electron transport layer and a cathode that was a multilayer film of LiF and Al were formed so as to overlie the organic light-emitting layer as in Example 1 to complete production of an organic EL device (organic light-emitting device), and the emission wavelength of the organic EL device at 1000 cd/m² was measured. Table 3 shows result of the measurement.

### Comparative Example 4

Except that a typical material that was mCP was used as the host material in place of the compound 1, an organic EL device (organic light-emitting device) was produced as in Example 13, and the emission wavelength of the organic EL device at 1000 cd/m² was measured. Table 3 shows result of the measurement.

TABLE 3

| | Organic light-emitting layer | | | | Maximum |
|---|---|---|---|---|---|
| | | Dopant | Exciton- | Luminous | luminous |
| | | (luminescent | blocking | efficiency | point |
| | Host | material) | layer | (od/A) | (nm) |
| Example 1 | mCP | Compound 1 | mCP | 34.2 | 506 |
| Example 12 | mCP | Compound 1 | Compound 9 | 40.3 | 507 |
| Example 13 | Compound 1 | Ir(fliq)₂(acac) | mCP | 12.0 | 653 |
| Comparative | mCP | Ir(fliq)₂(acac) | mCP | 8.5 | 650 |
| Example 4 | | | | | |

From the results shown in Table 3, the luminous efficiency was further higher in the device of Example 12 in which the compound 9 that was the transition metal complex according to an aspect of the present invention had been used as the exciton-blocking material to form the exciton-blocking layer between the hole injection layer and the organic light-emitting layer than in the device of Example 1.

Furthermore, the luminous efficiency was further higher in the device of Example 13 in which the compound 1 that was the transition metal complex according to an aspect of the present invention had been used as the host material than in the device of Comparative Example 3 in which mCP that was a typical material had been used as the host material.

[Production of Color Conversion Light-Emitting Device]

### Example 14

In this Example, an organic light-emitting device (organic EL device) in which the transition metal complex according to an aspect of the present invention was used and which emitted blue light was utilized to produce a color conversion light-emitting device which served to convert light emitted from the organic light-emitting device into red light and another color conversion light-emitting device which served to convert light emitted from the organic light-emitting device into green light.

<Formation of Organic EL Substrate>

A silver film was formed on a glass substrate having a thickness of 0.7 mm by sputtering so as to have a thickness of 100 nm, thereby forming a reflecting electrode; then, an indium-tin oxide (ITO) film was formed thereon by sputtering so as to have a thickness of 20 nm, thereby forming a first electrode that was a reflecting electrode (anode). Then, the first electrode was processed by typical photolithography into a striped pattern with 90 lines each having a width of 2 mm.

Then, a SiO₂ film was formed by sputtering on the first electrode (reflecting electrode) so as to have a thickness of 200 nm and then patterned by typical photolithography so as to cover the edge of the first electrode (reflecting electrode), thereby forming an edge cover. The SiO₂ edge cover covered part of the short side of the reflecting electrode in a length of 10 μm from the edge thereof. The product was washed with water; subsequently subjected to ultrasonic cleaning with pure water for 10 minutes, ultrasonic cleaning with acetone for 10 minutes, and steam cleaning with isopropyl alcohol for 5 minutes; and then dried for an hour at 100° C.

Then, N,N′-diphenyl-N,N′-bis[4-(phenyl-m-tolyl-amino)-phenyl]-biphenyl-4,4′-diamine (DNTPD) was deposited on the first electrode as the anode by vacuum deposition at a deposition rate of 1 Å/sec to form a hole injection layer having a thickness of 60 nm on the anode.

Then, 4,4′-bis[N-(1-naphthyl)-N-phenyl-amino]biphenyl (α-NPD) was deposited on the hole injection layer by vacuum deposition at a deposition rate of 1 Å/sec to form a hole transport layer having a thickness of 20 nm on the hole injection layer.

Then, N,N-dicarbazoyl-3,5-benzene (mCP) was deposited on the hole transport layer by vacuum deposition at a deposition rate of 1 Å/sec to form an exciton-blocking layer having a thickness of 10 nm on the hole transport layer.

Then, mCP and the compound 8 were co-deposited on the exciton-blocking layer by vacuum deposition to form an organic light-emitting layer having a thickness of 30 nm. The mCP that was the host material was doped with the compound 8 such that the compound 8 content therein was approximately 7.5%.

Then, diphenylphosphine oxide-4-(triphenylsilyl)phenyl (TSPO1) was deposited on the organic light-emitting layer by vacuum deposition to form an electron transport layer having a thickness of 30 nm on the organic light-emitting layer.

Then, an electron injection layer (thickness: 0.5 nm) was formed of lithium fluoride (LiF) on the electron transport layer.

Through these processes, the organic layers included in the organic EL layer had been formed.

Then, a semitransparent electrode was formed as a second electrode on the electron injection layer. In the formation of the second electrode, the above-mentioned substrate after the formation of the electron injection layer was finished was fixed to a chamber used for metal deposition, and the substrate was aligned with a shadow mask used for forming the semitransparent electrode (second electrode). The shadow mask used had an opening which enabled the semitransparent electrode (second electrode) to be formed so as to have a striped pattern having a width of 2 mm and facing the striped pattern of the reflecting electrode (first electrode). Then, magnesium and silver were co-deposited on the surface of the electron injection layer of the organic EL layer by vacuum deposition at deposition rates of 0.1 Å/sec and 0.9 Å/sec, respectively, to form an intended pattern of magnesium and silver (thickness: 1 nm). Silver was further deposited thereon at a deposition rate of 1 Å/sec in an intended pattern (thickness: 19 nm) to emphasize an interference effect and prevent voltage drop in the second electrode due to interconnection resistance. Through this process, the semitransparent electrode (second electrode) had been formed. A microcavity effect (interference effect) was developed between the reflecting electrode (first electrode) and the semitransparent electrode (second electrode), which enabled an enhancement in brightness on the front side.

Through these processes, the organic EL substrate having the organic EL portion had been produced.

<Formation of Fluorescent Substrate>

A red fluorescent layer and a green fluorescent layer were formed on a 0.7-mm-thick glass substrate having a red color filter and on a 0.7-mm-thick glass substrate having a green color filter, respectively.

The red fluorescent layer was formed as follows. To 0.16 g of aerosol having an average particle size of 5 nm, 15 g of ethanol and 0.22 g of γ-glycidoxypropyltriethoxysilane were added, and the product was stirred for an hour at room temperature in an open system. This mixture and 20 g of a red fluorescent material (pigment)K₅Eu_{2.5}(WO₄)_{6.25} were placed in a mortar, thoroughly mixed with each other, heated with an oven at 70° C. for 2 hours, and further heated with an oven at 120° C. for 2 hours to produce a surface-modified K₅Eu_{2.5}(WO₄)_{6.25}. Then, 30 g of polyvinyl alcohol dissolved in a 1/1 mixed liquid of water and dimethyl sulfoxide (300 g) was added to 10 g of the surface-modified K₅Eu_{2.5}(WO₄)_{6.25}, and the product was stirred with a disperser to produce a coating liquid used for forming a red fluorescent layer. The coating liquid used for forming a red fluorescent layer was applied to a red pixel position of a CF-formed glass substrate by screen printing in a width of 3 mm. Then, the product was dried under heating with a vacuum oven (conditions: 200° C. and 10 mmHg) for 4 hours to form a red fluorescent layer having a thickness of 90 μm.

The green fluorescent layer was formed as follows. To 0.16 g of aerosol having an average particle size of 5 nm, 15 g of ethanol and 0.22 g of γ-glycidoxypropyltriethoxysilane were added, and the product was stirred for an hour at room temperature in an open system. This mixture and 20 g of a green fluorescent material (pigment) Ba₂SiO₄:Eu²⁺ were placed in a mortar, thoroughly mixed with each other, heated with an oven at 70° C. for 2 hours, and further heated with an oven at 120° C. for 2 hours to produce a surface-modified Ba₂SiO₄:Eu². Then, 30 g of polyvinyl alcohol (resin) dissolved in a 1/1 mixed liquid of water and dimethyl sulfoxide (300 g: solvent) was added to 10 g of the surface-modified Ba₂SiO₄:Eu², and the product was stirred with a disperser to produce a coating liquid used for forming a green fluorescent layer. The coating liquid used for forming a green fluorescent layer was applied to a green pixel position of a CF-formed glass substrate 16 by screen printing in a width of 3 mm. Then, the product was dried under heating with a vacuum oven (conditions: 200° C. and 10 mmHg) for 4 hours to form a green fluorescent layer having a thickness of 60 μm.

Through such a process, the fluorescent substrate having the red fluorescent layer and the fluorescent substrate having the green fluorescent layer had been formed.

<Fabrication of Color Conversion Light-Emitting Device>

In order to produce a red color conversion light-emitting device and a green color conversion light-emitting device, the organic EL substrate and fluorescent substrates formed as described above were aligned with each other on the basis of alignment markers formed outside the positions at which the pixels were to be arrayed. In advance of the alignment, a thermosetting resin was applied to the fluorescent substrates.

After the alignment, those substrates were tightly attached to each other with the thermosetting resin interposed therebetween, and the product was heated at 90° C. for 2 hours for curing. The attachment of the substrates was carried out under a dry air environment (moisture content: −80° C.) to prevent degradation of the organic EL layer due to moisture.

A terminal formed at the periphery of each of the color conversion light-emitting devices was connected to an external power source. Good green light emission and red light emission were enabled.

[Production of Display System]

### Example 15

A silicon semiconductor film was formed on a glass substrate by plasma chemical vapor deposition (plasma CVD), subjected to crystallization, and then formed into a polycrystalline semiconductor film (polycrystalline silicon thin film). Then, the polycrystalline silicon thin film was etched to form a pattern having multiple islands. A gate insulating film was subsequently formed of silicon nitride (SiN) on each island of polycrystalline silicon thin film. Then, a multilayer film of titanium (Ti)-aluminum (Al)-titanium (Ti) was sequentially formed to serve as a gate electrode and etched into a pattern. A source electrode and a drain electrode were formed of Ti—Al—Ti so as to overlie the gate electrode, thereby forming multiple thin film transistors (thin TFTs).

Then, an interlayer insulating film having through-holes was formed on the thin film transistors for planarization. Indium tin oxide (ITO) electrodes were formed as anodes through the through-holes. Monolayers were formed of a polyimide resin in a pattern surrounding the peripheries of the ITO electrodes, and then the substrate having the ITO electrodes was subjected to ultrasonic cleaning and baked under reduced pressure at 200° C. for 3 hours.

Then, N,N′-diphenyl-N,N′-bis[4-(phenyl-m-tolyl-amino)-phenyl]-biphenyl-4,4′-diamine (DNTPD) was deposited on each of the anodes by vacuum deposition at a deposition rate of 1 Å/sec to form a hole injection layer having a thickness of 60 nm on the anodes.

Then, 4,4′-bis[N-(1-naphthyl)-N-phenyl-amino]biphenyl (α-NPD) was deposited thereon by vacuum deposition at a deposition rate of 1 Å/sec to form a hole transport layer having a thickness of 20 nm above each of the anodes.

Then, N,N-dicarbazoyl-3,5-benzene (mCP) was deposited on the hole transport layer by vacuum deposition at a deposition rate of 1 Å/sec to form an exciton-blocking layer having a thickness of 10 nm on the hole transport layer.

Then, mCP and the compound 8 were co-deposited on the exciton-blocking layer by vacuum deposition to form an organic light-emitting layer having a thickness of 30 nm. The mCP that was the host material was doped with the compound 8 such that the compound 8 content therein was approximately 7.5%.

Then, diphenylphosphine oxide-4-(triphenylsilyl)phenyl (TSPO1) was deposited on the organic light-emitting layer by vacuum deposition to form an electron transport layer having a thickness of 30 nm on the organic light-emitting layer.

Then, lithium fluoride (LiF) was deposited on the electron transport layer by vacuum deposition at a deposition rate of 1 Å/sec to form an LiF film having a thickness of 0.5 nm. Aluminum (Al) was subsequently used to form an Al film having a thickness of 100 nm on the LiF film. In this manner, the multilayer film of LiF and Al had been formed as a cathode to complete production of an organic EL device (organic light-emitting device).

A display system in which the above-mentioned organic light-emitting devices (organic EL devices) were arrayed in the matrix of 100×100 was produced, and a movie was displayed thereon. The display system included an image signal output unit used for generating an image signal, a driver used for generating the image signal output from the image signal output unit and having a scanning electrode driving circuit and signal driving circuit, and a light-emitting unit having the organic light-emitting devices (organic EL devices) arrayed in the matrix of 100×100. The display system enabled high-quality images having high color purity to be displayed. In the case where such a display system was repeatedly produced, each display system had uniform quality, and the display system had good in-plane uniformity.

[Production of Lighting System]

### Example 16

Lighting system including a driver used for generating electric current and a light-emitting unit used for emitting light on the basis of the electric current generated in the driver was produced.

A hole injection layer that was a copper phthalocyanine (CuPc) film having a thickness of 30 nm, a hole transport layer that was a 4′-bis[N-(1-naphthyl)-N-phenyl-amino]biphenyl (α-NPD) film having a thickness of 20 nm, and an electron-blocking layer that was a 4,4′-bis-[N,N′-(3-tolyl)amino-3,3′-dimethylbiphenyl (HMTPD) film having a thickness of 10 nm were formed on a film substrate in sequence.

Then, α-NPD (hole transport material), 2-(4-biphenylyl)-5-(4-t-butylphenyl)-1,3,4-oxadiazole (PBD) and 3-(4-biphenylyl)-4-phenyl-5-(4-t-butylphenyl)-1,2,4-triazole (TAZ) (electron transport materials), and bis(2-(2′-benzo[4,5-α]thienyl)pyridinato-N,C3′)iridium(acetylacetonate) (btp₂Ir(acac)) (red light-emitting dopant) were co-deposited at controlled deposition rates of 0.6:1.4:0.15 to form a red light-emitting layer capable of transporting both holes and electrons and having a thickness of 20 nm. Then, on the red light-emitting layer capable of transporting both holes and electrons, α-NPD (hole transport material), TAZ (electron transport material), and Ir(ppy)₃ (green light-emitting dopant) were co-deposited at controlled deposition rates of 1.0:1.0:0.1 to form a green light-emitting layer capable of transporting both holes and electrons and having a thickness of 10 nm. Then, on the green light-emitting layer capable of transporting both holes and electrons, α-NPD (hole transport material), TAZ (electron transport material), and the compound 11 (blue light-emitting dopant) were co-deposited at controlled deposition rates of 1.5:0.5:0.2 to form a blue light-emitting layer capable of transporting both holes and electrons and having a thickness of 10 nm, thereby forming a white light-emitting layer.

Then, 2,9-dimethyl-4,7-diphenyl-1,10-phenanthroline (BCP) film having a thickness of 10 nm was formed as a hole-blocking layer on the white light-emitting layer, tris(8-hydroxyquinoline)aluminum (Alq3) film having a thickness of 30 nm was subsequently formed as an electron transport layer thereon, and then lithium fluoride (LiF) film having a thickness of 1 nm was formed as an electron injection layer thereon. Then, aluminum (Al) was used to form an Al film having a thickness of 100 nm on the LiF film. In this manner, the multilayer film of LiF and Al had been formed as a cathode to complete production of a white-light-emitting organic EL device (organic light-emitting device), and the organic light-emitting device served as a light-emitting unit.

Voltage was applied to the organic light-emitting system (organic light-emitting device) to light up, and a lighting system performed uniform plane emission on a curved surface without use of indirect illumination leading to the loss of brightness. The lighting system was also able to be used as the back light of a liquid crystal display panel.

[Production of Light Conversion Light-Emitting Device]

### Example 17

The light conversion light-emitting device illustrated in FIG. 5 was produced.

The light conversion light-emitting device was produced as follows. The process of Example 9 was similarly carried out until the step for forming the electron transport layer, and then a photoelectric material layer was formed of NTCDA (naphthalenetetracarboxylic acid) on the electron transport layer so as to have a thickness of 500 nm. Then, an Au electrode that was a thin Au film having a thickness of 20 nm was formed on the NTCDA layer. In this case, part of the Au electrode was configured so as to lead to an end of the device substrate via wiring and connected to the negative electrode of a driving power source, the wiring being formed of the same material as the Au electrode in a predetermined pattern so as to be integral therewith. Similarly, part of the ITO electrode was configured so as to lead to an end of the device substrate via wiring and connected to the positive electrode of the driving power source, the wiring being formed of the same material as the ITO electrode in a predetermined pattern so as to be integral therewith. A predetermined voltage was applied between a pair of such electrodes (ITO electrode and Au electrode).

In the light conversion light-emitting device produced though such process, voltage was applied such that the ITO electrode served as the anode, and the Au electrode was irradiated with monochromatic light having a wavelength of 335 nm; on the irradiation with monochromatic light, the photoelectric current at room temperature and illuminance of light emitted from the compound 8 (wavelength: 463 nm) were measured for each applied voltage. In the result of the measurement, a photocurrent multiplication effect was observed in driving at a voltage of 20 V.

[Production of Dye Laser]

### Example 18

The dye laser illustrated in FIG. 7 was produced.

The dye laser was produced, in which the compound 1 served as a laser dye (in a degassed acetonitrile solution: concentration 1×10⁻⁴ M) in an XeCl excimer (excitation wavelength: 308 nm). The oscillation wavelength was in the range of 430 nm to 450 nm, and a phenomenon in which the intensity was enhanced around a wavelength of 440 nm was observed.

[Production of Organic Laser Diode Light-Emitting Device]

### Example 19

With reference to H. Yamamoto et al., Appl. Phys. Lett., 2004, 84, 1401, an organic laser diode light-emitting device having the structure illustrated in FIG. 6 was produced.

The organic laser diode light-emitting device was produced as follows. The process of Example 1 was similarly carried out until the step for forming the anode.

Then, N,N′-diphenyl-N,N′-bis[4-(phenyl-m-tolyl-amino)-phenyl]-biphenyl-4,4′-diamine (DNTPD) was deposited on the anode by vacuum deposition at a deposition rate of 1 Å/sec to form a hole injection layer having a thickness of 60 nm on the anode.

Then, 4,4′-bis[N-(1-naphthyl)-N-phenyl-amino]biphenyl (α-NPD) was deposited thereon by vacuum deposition at a deposition rate of 1 Å/sec to form a hole transport layer having a thickness of 20 nm above the anode.

Then, N,N-dicarbazoyl-3,5-benzene (mCP) was deposited on the hole transport layer by vacuum deposition at a deposition rate of 1 Å/sec to form an exciton-blocking layer having a thickness of 10 nm on the hole transport layer.

Then, mCP and the compound 1 were co-deposited on the exciton-blocking layer by vacuum deposition to form an organic light-emitting layer having a thickness of 30 nm. The mCP that was the host material was doped with the compound 1 such that the compound 1 content therein was approximately 7.5%.

Then, diphenylphosphine oxide-4-(triphenylsilyl)phenyl (TSPO1) was deposited on the organic light-emitting layer by vacuum deposition to form an electron transport layer having a thickness of 30 nm on the organic light-emitting layer.

Then, MgAg (9:1, film thickness: 2.5 nm) was deposited on the electron transport layer by vacuum deposition, and an ITO film was formed by sputtering so as to have a thickness of 20 nm, thereby producing the organic laser diode light-emitting device.

The organic laser diode light-emitting device was irradiated with a laser beam (Nd: YAG laser SHG, 532 nm, 10 Hz, and 0.5 ns) from the anode side to analyze ASE oscillation characteristics. The irradiation with a laser beam was carried out such that the excitation intensity of the laser beam was changed, the oscillation started at 1.0 μJ/cm², and ASE oscillation in which the peak brightness was enhanced in proportion to the excitation intensity was observed.

### INDUSTRIAL APPLICABILITY

The transition metal complex according to aspects of the present invention can be used as a luminescent material, host material, charge transport material, and exciton-blocking material in an organic EL (electroluminescence) device. Furthermore, the transition metal complex can be utilized in, for example, an organic electroluminescence device (organic EL device), a color conversion light-emitting device, a light conversion light-emitting device, a dye used in a laser, and an organic laser diode device; can be also utilized in a display system and lighting system including any of these light-emitting devices; and can be also utilized in electronic equipment including such a display system.

### REFERENCE SIGNS LIST

1 . . . Substrate, 2 . . . TFT circuit, 2a and 2b . . . Wiring, 3 . . . Interlayer insulating film, 4 . . . Planarization film, 5 . . . Organic sealing film, 6 . . . Sealing member, 7 . . . Black matrix, 8R . . . Red color filter, 8G . . . Green color filter, 8B . . . Blue color filter, 9 . . . Sealing substrate, 8B . . . Blue fluorescence conversion layer, 10 and 20 . . . Organic light-emitting device (organic EL device, light source), 11 . . . Reflecting electrode, 12 . . . First electrode (reflecting electrode), 13 . . . Hole transport layer, 14 . . . Organic light-emitting layer, 15 . . . Electron transport layer, 16 . . . Second electrode (reflecting electrode), 17 . . . Organic EL layer (organic layer), 18R . . . Red fluorescent layer, 18G . . . Green fluorescent layer, 19 . . . Edge cover, 30 . . . Color conversion light-emitting device, 31 . . . Scattering layer, 40 . . . Light conversion light-emitting device, 50 . . . Organic laser diode device, 60 . . . Dye laser, 70 . . . Lighting system, 210 . . . Mobile phone (electronic equipment), 220 . . . Thin television set (electronic equipment), 230 . . . Portable game machine (electronic equipment), 240 . . . Laptop (electronic equipment), 250 . . . Ceiling light (lighting system), 260 . . . Stand light (lighting system)

1. (canceled)

2. A transition metal complex having an alkoxy group, wherein the transition metal complex is represented by Formula (2) 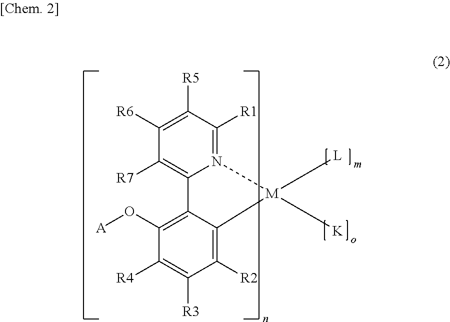
(where M represents a transition metal element belonging to Groups 8 to 12 on the periodic table, and the oxidation state of the transition metal element represented by M is not limited; K represents an uncharged monodentate or bidentate ligand; L represents a monoanionic or dianionic monodentate or bidentate ligand; m represents an integer from 0 to 5; o represents an integer from 0 to 5; n represents an integer from 1 to 3; m, o, and n depend on the oxidation state and coordination number of the transition metal element represented by M;
R1 represents a hydrogen atom, an alkyl group, a cycloalkyl group, a heterocycloalkyl group, an aryl group, an aralkyl group, a heteroaryl group, an alkenyl group, an alkynyl group, or an alkoxy group, and these groups are optionally substituted or unsubstituted;
R2, R3, R4, and R6 each independently represent a hydrogen atom, an alkyl group, a cycloalkyl group, a heterocycloalkyl group, an aryl group, an aralkyl group, a heteroaryl group, an alkenyl group, or an alkynyl group, and these groups are optionally substituted or unsubstituted;
R5 and R7 each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these groups are optionally substituted or unsubstituted; R1, R5, R6, R2, and R3 are optionally independently combined with R5, R6, R7, R3, and R4 by connection of parts thereof, respectively, to form saturated or unsaturated ring structures, at least one atom of each ring structure is optionally substituted with an alkyl group or an aryl group (the substituent is optionally further substituted or unsubstituted), and each ring structure optionally has one or more ring structures; and
A represents an alkyl group, a cycloalkyl group, a heterocycloalkyl group, an aryl group, a heteroaryl group, an aralkyl group, an alkenyl group, an alkynyl group, or an alkoxy group.

3. The transition metal complex having an alkoxy group according to claim 2, wherein L represents a ligand having a structure represented by any of Formulae (3) to (7).

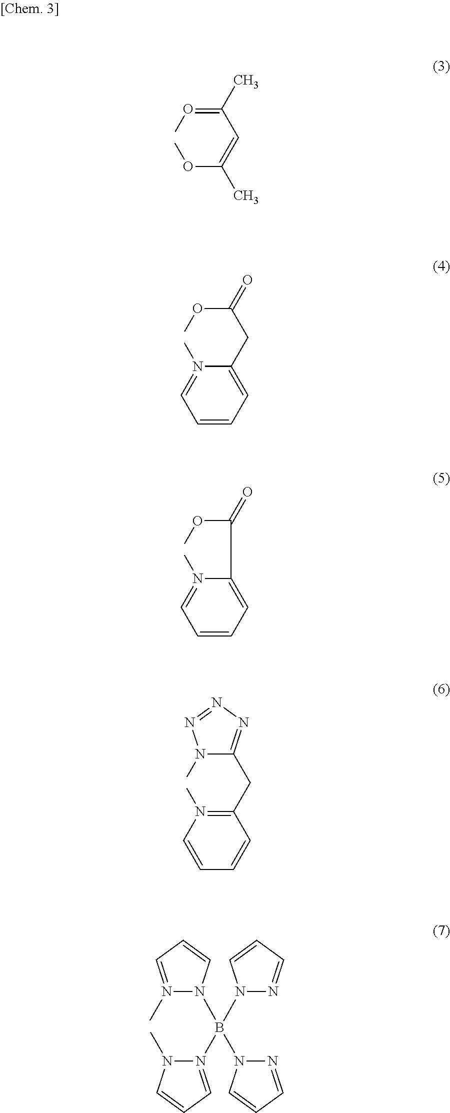

4. The transition metal complex having an alkoxy group according to claim 2, wherein the transition metal complex is represented by Formula (8) 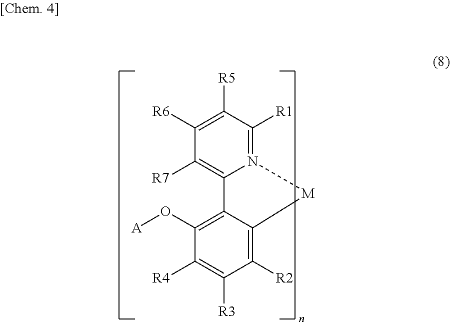
(where R5 and R7 each independently represent a hydrogen atom, an alkyl group, a cycloalkyl group, a heterocycloalkyl group, an aryl group, a heteroaryl group, an aralkyl group, an alkenyl group, an alkynyl group, or an alkoxy group, and these groups are optionally substituted or unsubstituted; R6 represents a hydrogen atom, an alkyl group, a cycloalkyl group, a heterocycloalkyl group, an aryl group, a heteroaryl group, an aralkyl group, an alkenyl group, or an alkynyl group, and these groups are optionally substituted or unsubstituted; R1, R5, R6, R2, and R3 are optionally independently combined with R5, R6, R7, R3, and R4 by connection of parts thereof, respectively, to form saturated or unsaturated ring structures, at least one atom of each ring structure is optionally substituted with an alkyl group or an aryl group (the substituent is optionally further substituted or unsubstituted), and each ring structure optionally has one or more ring structures; and
R1 to R4, A, M, and n represent the same as R1 to R4, A, M, and n in Formula (2), respectively.

5. The transition metal complex having an alkoxy group according to claim 2, wherein R1 to R7 each independently represent a hydrogen atom, a methyl group, or a phenyl group.

6. The transition metal complex having an alkoxy group according to claim 2, wherein A represents a methyl group, an ethyl group, an isopropyl group, a phenyl group, or an n-octyl group.

7. The transition metal complex having an alkoxy group according to claim 2, wherein M represents iridium, osmium, or platinum.

8. The transition metal complex having an alkoxy group according to claim 4, wherein the transition metal complex is a tris-complex in which three bidentate ligands are coordinated where n represents 3 and where m and o represent 0, and the fac (facial) isomer content is higher than the mer (meridional) isomer content.

9. An organic light-emitting device comprising an organic layer having a mono- or multilayer structure including a light-emitting layer and a pair of electrodes placed such that the organic layer is disposed between the electrodes, wherein at least part of the organic layer contains the transition metal complex having an alkoxy group according to claim 2.

10. The organic light-emitting device according to claim 9, wherein the transition metal complex having an alkoxy group is used as a luminescent material.

11. The organic light-emitting device according to claim 9, wherein the transition metal complex having an alkoxy group is used as a host material.

12. (canceled)

13. A color conversion light-emitting device comprising the organic light-emitting device according to claim 9 and a fluorescent layer disposed so as to face the light-extracted side of the organic light-emitting device, the fluorescent layer absorbing light emitted from the organic light-emitting device to emit light having a color different from the color of the absorbed light.

14. A color conversion light-emitting device comprising a light-emitting device and a fluorescent layer disposed so as to face the light-extracted side of the light-emitting device, the fluorescent layer absorbing light emitted from the light-emitting device to emit light having a color different from the color of the absorbed light, wherein the fluorescent layer contains the transition metal complex having an alkoxy group according to claim 2.

15. A light conversion light-emitting device comprising an organic layer having a mono- or multilayer structure including a light-emitting layer, a layer that amplifies electric current, and a pair of electrodes placed such that the organic layer and the layer that amplifies electric current are disposed between the electrodes, wherein the light-emitting layer contains the transition metal complex having an alkoxy group according to claim 2.

16. (canceled)

17. A dye laser comprising a laser medium containing the transition metal complex having an alkoxy group according to claim 2 and an excitation light source that causes stimulated emission of phosphorescence from the transition metal complex contained in the laser medium for laser oscillation.

18. A display system comprising an image signal output unit that generates an image signal, a driver that generates electric current or voltage on the basis of the signal generated in the image signal output unit, and a light-emitting unit that emits light on the basis of the electric current or voltage generated in the driver, wherein the light-emitting unit is the organic light-emitting device according to claim 9.

19. A display system comprising an image signal output unit that generates an image signal, a driver that generates electric current or voltage on the basis of the signal generated in the image signal output unit, and a light-emitting unit that emits light on the basis of the electric current or voltage generated in the driver, wherein the light-emitting unit is the color conversion light-emitting device according to claim 13.

20. The display system according to any one of claim 18, wherein the light-emitting unit is driven by a thin film transistor, and an anode and cathode of the light-emitting unit are arrayed in the form of a matrix.

21. (canceled)

22. A lighting system comprising a driver that generates electric current or voltage and a light-emitting unit that emits light on the basis of the electric current or voltage generated in the driver, wherein the light-emitting unit is the organic light-emitting device according to claim 9.

23. A lighting system comprising a driver that generates electric current or voltage and a light-emitting unit that emits light on the basis of the electric current or voltage generated in the driver, wherein the light-emitting unit is the color conversion light-emitting device according to claim 13.

24. Electronic equipment comprising a display that is the display system according to claim 18.
